(19) United States
(12) Patent Application Publication
(10) Pub. No.: US 2010/0308928 A1
(43) Pub. Date: Dec. 9, 2010

(54) PIEZOELECTRIC VIBRATOR MANUFACTURING METHOD, PIEZOELECTRIC VIBRATOR, OSCILLATOR, ELECTRONIC DEVICE, AND RADIO-CONTROLLED WATCH

(76) Inventors: Kiyoshi ARATAKE, Chiba-shi (JP); Masashi NUMATA, Chiba-shi (JP)

Correspondence Address: Brinks Hofer Gilson & Lione/Seiko Instruments Inc., P.O. Box 10395, Chicago, IL, 60611, US

(21) Appl. No.: 12/856,365

(22) Filed: Aug. 13, 2010

Related U.S. Application Data
(63) Continuation of application No. PCT/JP2008/070941, filed on Nov. 18, 2008.

(30) Foreign Application Priority Data
Feb. 18, 2008 (JP) 2008-035508
Feb. 18, 2008 (JP) 2008-035512
Feb. 18, 2008 (JP) 2008-036419

(51) Int. Cl. H01L 41/22; H01L 41/053; H03B 5/36

(52) U.S. Cl. 331/116 R; 29/25.35; 310/344

(57) ABSTRACT

The piezoelectric vibrator comprises a base substrate of which the two faces are polished; a lid substrate in which cavity recesses are formed and which is bonded to the base substrate in such a state that the recesses face the base substrate; a piezoelectric vibration member bonded to the upper face of the base substrate in such a state that it is housed in the cavity formed of the recess between the base substrate and the lid substrate; an external electrode formed on the lower face of the base substrate; a through-electrode formed in and through the base substrate and electrically connected with the external electrode with keeping the airtightness inside the cavity; and a routing electrode formed on the upper face of the base substrate to electrically connect the through-electrode to the bonded piezoelectric vibration member. The through-electrode is formed by hardening of a paste containing a plurality of metal fine particles.

### RELATED APPLICATIONS

This application is a continuation of PCT/JP2008/070941 filed on Nov. 18, 2008, which claims priority to Japanese Application Nos. 2008-035508, 2008-036419, and 2008-035512, all filed on Feb. 18, 2008. The entire contents of these applications are incorporated herein by reference.

### BACKGROUND OF THE INVENTION

1. Field of the Invention

The present invention relates to a surface mount device-type (SMD) piezoelectric vibrator in which a piezoelectric vibration member is sealed up in a cavity formed between two bonded substrates, to a piezoelectric vibrator manufacturing method for manufacturing the piezoelectric vibrator, and to an oscillator, an electronic device and a radio-controlled watch comprising a piezoelectric vibrator.

The present application is based on basic applications of Japanese Patent Application No. 2008-35508, Japanese Patent Application No. 2008-36419 and Japanese Patent Application No. 2008-35511, the entire contents thereof being hereby incorporated.

2. Description of the Related Art

In recent years, mobile telephones and portable information terminal devices employ a piezoelectric vibrator using quartz crystal or the like as a time source, a timing source of control signals or the like, a reference signal source, etc. As this type of piezoelectric vibrator, various ones are offered. As one of them, a surface mount device-type piezoelectric vibrator is known. As the piezoelectric vibrator of the type, generally known is a three-layer structure type one in which a piezoelectric substrate with a piezoelectric vibration member formed thereon is sandwiched between a base substrate and a lid substrate and bonded all together. In this case, the piezoelectric vibrator is housed in the cavity (sealed unit) formed between the base substrate and the lid substrate. Recently, not only the above-mentioned three-layer structure type one but also a two-layer structure type one has been developed.

The piezoelectric vibrator of the type has a two-layer structure in which the base substrate and the lid substrate are directly bonded to each other; and a piezoelectric vibration member is housed in the cavity formed between the two substrates. As compared with a three-layer structure one, the two-layer structure type piezoelectric vibrator is excellent in that it can be thinned, and is therefore favorably used. As one of such two-layer structure type piezoelectric vibrators, a piezoelectric vibrator is known, in which the piezoelectric vibration member is electrically connected to the external electrode formed on the base substrate using the electroconductive member formed to run through the base substrate (see Patent Reference 1 and Patent Reference 2).

The piezoelectric vibrator 600 comprises, as shown in FIG. 70 and FIG. 71, a base substrate 601 and a lid substrate 602 anodically-bonded to each other via a bonding film 607, and a piezoelectric vibration member 603 sealed up in the cavity C formed between the two substrates 601 and 602.

The piezoelectric vibration member 603 is, for example, a tuning fork-type vibration member, and this is mounted on the upper face of the base substrate 601 via an electroconductive adhesive E in the cavity C. The base substrate 601 and the lid substrate 602 are, for example, insulating substrates of ceramics, glass or the like. Of the two substrates 601 and 602, the base substrate 601 has through-holes 604 running through the substrate 601. The through-hole 604 is filled with an electroconductive member 605 to seal up the through-hole 604. The electroconductive member 605 is electrically connected to the outer electrode 606 formed on the lower face of the base substrate 601, and is electrically connected to the piezoelectric vibration member 603 mounted in the cavity C.

Patent Reference 1: JP-A 2002-124845

Patent Reference 2: JP-A 2006-279872

In the above-mentioned, two-layer structure type piezoelectric vibrator, the electroconductive member 605 plays important two roles of blocking the through-hole 604 to thereby airtightly seal up the cavity C, and electrically connecting the piezoelectric vibration member 603 to the external electrode 606. In particular, in case where the adhesion to the through-hole 604 is insufficient, then the airtight sealing inside the cavity C may be lost; and in case where the contact with the electroconductive adhesive E or the external electrode 606 is insufficient, then the piezoelectric vibration member 603 may work erroneously. Accordingly, for evading such failures, the electroconductive member 605 must be formed in such a state that it completely blocks the through-hole 604 while kept in firm contact with the inner face of the through-hole 604 and it has no depression on the surface thereof.

However, Patent Reference 1 and Patent Reference 2 describe formation of the electroconductive member 605 with an electroconductive paste (Ag paste, Au—Sn paste, etc.), but have no description relating to a concrete manufacturing method of how to practically form it.

In general, in case where an electroconductive paste is used, it must be fired and hardened. In other words, after the through-hole 604 is filled with an electroconductive paste, it must be fired and hardened. When fired, however, the organic matter in the electroconductive paste may be lost through evaporation; and therefore, in general, the volume after firing decreases as compared with that before firing (for example, in case where an Ag paste is used as the electroconductive paste, the volume may decrease by about 20% or so). Accordingly, even when the electroconductive member 605 is formed with an electroconductive paste, the surface may have depressions formed thereon or, in some serious cases, there may be a risk of forming through-holes in the center.

As a result, the cavity C may lose its airtightness, or there is a possibility that the electric connection between the piezoelectric vibration member 603 and the external electrode 606 may be lost.

### SUMMARY OF THE INVENTION

The present invention has been made in consideration of the situation as above, and its object is to provide a high-quality two-layer structure-type, surface-mount piezoelectric vibrator that surely maintains the airtightness inside the cavity and secures stable electric connection between the piezoelectric vibration member and the external electrode. The invention is also to provide a piezoelectric vibrator manufacturing method of efficiently manufacturing many such piezoelectric vibrators all at a time, and to provide an oscillator, an electronic device and a radio-controlled watch comprising the piezoelectric vibrator.

### Means for Solving the Problems

To solve the above-mentioned problems and to attain the objects, the invention provides the following means:

(1) The piezoelectric vibrator manufacturing method of the invention is a method for manufacturing a plurality of piezoelectric vibrators in which a piezoelectric vibration member is sealed up in a cavity formed between a base substrate and a lid substrate bonded to each other, all at once by utilizing a base substrate wafer and a lid substrate wafer, and the method comprises a recess forming step of forming, in the lid substrate wafer, a plurality of cavity recesses for forming cavities when the two wafers are overlaid; a through-electrode forming step of forming a plurality of through-electrodes in and through the base substrate wafer by utilizing a paste containing a plurality of metal fine particles; a routing electrode forming step of forming a plurality of routing electrodes connected electrically with the through-electrodes, on the upper face of the base substrate wafer; a mounting step of bonding the plural piezoelectric vibration members to the upper face of the base substrate wafer via the routing electrodes; an overlaying step of overlaying the base substrate wafer and the lid substrate wafer thereby to house the piezoelectric vibration members in the cavities surrounded by the recesses and the two wafers; a bonding step of bonding the base substrate wafer and the lid substrate wafer thereby to seal up the piezoelectric vibration members in the cavities; an external electrode forming step of forming a plurality of external electrodes connected electrically with the through-electrodes, on the lower face of the base substrate wafer; and a cutting step of cutting the two bonded wafers thereby to shred them into the plural piezoelectric vibrators; wherein the through-electrode forming step includes a holding hole forming step of forming a plurality of holding holes for holding the paste, in the base substrate water; a filling step of implanting the paste in the plural holding holes to block up the holding holes; a firing step of pre-firing the implanted paste and finally firing and hardening it; and a polishing step of, after the pre-firing or the final firing, polishing the two faces of the base substrate wafer by a predetermined thickness; and in case where the polishing step is attained after the final firing, the pre-fired paste is supplemented with a fresh paste in an amount corresponding to the paste amount reduced by the pre-firing, in the firing step, and thereafter the entire paste is again pre-fired and then finally fired.

According to the piezoelectric vibrator manufacturing method of the invention, first attained is the recess forming step of forming a plurality of cavity recesses in the lid substrate wafer. These recesses are to be cavities when the two wafers are overlaid later. At the same time or in a timing of before or after the step, the through-electrode forming step is attained for forming a plurality of through-electrodes in the base substrate wafer. In this stage, plural through-electrodes are formed so as to be housed in the recesses formed in the lid substrate wafer when the two wafers are overlaid later.

The through-electrode forming step may be divided into two different working sequences, depending on the timing of the polishing step of polishing the base substrate wafer. Here, first described is a case of attaining the polishing step after the paste containing plural metal fine particles is finally fired.

First, the holding hole forming step is attained for forming a plurality of holding holes for holding the paste therein, in the base substrate wafer. Subsequently, the filling step is attained for implanting the paste into the plural holding holed with no space remaining therein, to thereby block up the holding holes. Subsequently, the firing step is attained for pre-firing the filled paste and then finally firing and hardening it. Concretely, first, the implanted paste is pre-fired. In the paste hardened by the pre-firing, most organic matter evaporates away, and therefore, the volume of the paste decreases as compared with the volume thereof in the filling step. Accordingly, the paste surface inevitably has depressions. Therefore, the pre-fired paste is supplemented with a fresh paste in an amount corresponding to the paste amount decreased by the pre-firing. As a result, the fresh paste is filled in the depressions, and the surface becomes flat.

After the paste supplementation is finished, the entire paste is again pre-fired for the purpose of preventing the inorganic matter in the supplemented paste from rapidly evaporating away during the final firing. After the pre-firing, the entire paste is finally fired. Accordingly, the paste implanted in the filling step and the newly added paste are completely hardened to be in an integrated state, and in a state firmly sticking to the inner face of the holding hole. After the pre-firing and the final firing of the paste, the firing step is finished.

Of the finally fired paste, the paste implanted in the filling step loses most organic matter that evaporates away in the initial pre-firing, and therefore its volume decreases little in the subsequent pre-firing and final firing after the paste supplementation. On the other hand, the volume of the fresh paste added through supplementation after the first pre-firing decreases by the pre-firing and the final firing after the paste supplementation; however, the amount of the paste itself is extremely small as compared with the entire volume of the paste in the holding hole. Accordingly, the influence of the volume reduction in the pre-firing and the final firing of the additional paste on the entire paste volume is small to an ignorable degree. Therefore, even through the reduction in the volume of the newly-added paste is taken into consideration, the surface of the paste hardened by the final firing is not greatly depressed. Specifically, the surface of the base substrate wafer can be substantially in a flat condition relative to the surface of the paste hardened by the final firing.

After the firing step, the polishing step is attained for polishing the two faces of the base substrate wafer by a predetermined thickness. In this step, the two faces of the paste hardened by the final firing are also polished at the same time, and therefore, the peripheries of any slight depressions can be cut off. In other words, the surface of the hardened paste can be planarized more. Accordingly, the surface of the base substrate wafer and the hardened paste surface can be in a flatter condition. After the polishing step, the through-hole forming step in the case of attaining the polishing step after the final firing is finished. The plural metal fine particles in the paste are kept in contact with each other, therefore securing the electric conductivity of the through-electrodes. In the above-mentioned through-electrode forming step, the polished amount in the polishing step is extremely small, and therefore, the time for the polishing step may be shortened.

On the other hand, the through-hole forming step in the other case of attaining the polishing step before the final firing is described below.

The process to the pre-firing of the paste implanted in the filling step is the same as in the above. After the paste implanted in the filling step is pre-fired, the paste surface has depressions as mentioned above. Accordingly, immediately after the pre-firing, the polishing step is attained for polishing the two faces of the base substrate wafer each by a predetermined thickness. Accordingly, the peripheries around the depressions can be cut off, and therefore, the surface of the base substrate wafer can be in a substantially flat condition relative to the surface of the pre-fired paste.

The reduction in the volume of the paste in the pre-firing is small, as compared with a case of directly attaining only one final firing with no pre-firing. Accordingly, the paste surface depressions to form in the pre-firing are smaller as compared with the depressions to occur in the case of directly attaining only one final firing with no pre-firing of the same amount of the paste. Therefore, by attaining the polishing step just after the pre-firing of the paste, the amount to be polished may be reduced and the time for the polishing step may be shortened.

After the polishing step, the final firing is attained to thereby completely harden the paste. Accordingly, the paste firmly stick to the inner face of the holding hole, and the paste functions as a through-electrode. In addition, since most organic matter in the paste has already evaporated away during the pre-firing, the volume reduction in the final firing is only slight. Therefore, the surface of the base substrate wafer and the surface of the hardened paste keep a substantially flat condition to each other like that before the final firing. After the final firing, the through-electrode forming step is finished.

The above is the through-hole forming step in the invention; and as so mentioned in the above, the polishing step may be attained in any timing to make the surface of the base substrate wafer and the surface of the hardened paste substantially in a flat condition to each other.

Next, the routing electrode forming step is attained for forming a plurality of routing electrodes connected electrically with the through-electrodes by patterning an electroconductive material on the upper face of the base substrate wafer. In this stage, the routing electrode is so formed that it can be housed in the recess formed in the lid substrate wafer when the two wafers are overlaid later.

In particular, the through-electrode is substantially in a flat condition relative to the upper face of the base substrate wafer as so mentioned in the above. Accordingly, the routing electrode as patterned on the upper face of the base substrate wafer is kept in airtight contact with the through-electrode with no space therebetween. This secures the electric connection between the routing electrode and the through-electrode.

Next, the mounting step is attained for bonding a plurality of piezoelectric vibration members to the upper face of the base substrate wafer each via the routing electrode. Accordingly, the bonded piezoelectric vibration members are electrically connected to the through-electrodes via the routing electrodes. After the mounting operation, the overlaying step is attained for overlaying the base substrate wafer and the lid substrate wafer. Accordingly, the bonded plural piezoelectric vibration members are kept housed in the cavities surrounded by the recesses and the two wafers. Next, the bonding step is attained for bonding the overlaid two wafers to each other. Accordingly, the two wafers adhere firmly to each other and therefore the piezoelectric vibration members can be sealed up in the cavities.

Next, the external electrode forming step is attained for forming a plurality of external electrodes electrically connected with the respective through-electrodes by patterning an electroconductive material on the lower face of the base substrate wafer. Also in this case, the through-electrodes are kept substantially in a flat condition relative to the lower face of the base substrate wafer like in the formation of the routing electrodes, and therefore, the patterned external electrodes are kept in airtight contact with the through-electrodes with no space therebetween. Accordingly, the electric connection between the external electrode and the through-electrode can be secured. As a result of this step, the piezoelectric vibration members sealed up in the cavities can be activated as utilizing the external electrodes.

Finally, the cutting step is attained for cutting the base substrate wafer and the lid substrate wafer bonded to each other, to thereby shred them into a plurality of piezoelectric vibrators.

As a result, a plurality of two-layer structure-type surface-mount piezoelectric vibrators with piezoelectric vibration members sealed up in cavities formed between a base substrate and a lid substrate bonded to each other can be manufactured all at once.

In particular, since the through-electrodes can be formed substantially in a flat condition relative to the base substrate, the through-electrodes can be surely kept in airtight contact with the routing electrodes and the external electrodes. As a result, stable electric connection between the piezoelectric vibration members and the external electrodes can be secured, and the reliability of operation performance can be enhanced to attain high-quality devices. Further, since the airtightness inside the cavities is surely kept, the high quality of the devices is secured in this respect. In addition, since the through-electrodes can be formed according to the simple method of using a paste, the process can be simplified.

(2) In the filling step, the paste may be defoamed and then implanted in the holding hole.

In this case, since the paste is previously processed for defoaming, the paste containing few foams can be filled. Therefore, the paste volume reduction can be prevented as much as possible in the firing step. Accordingly, the amount to be polished in the subsequent polishing step may be reduced, and the time necessary for the step may be reduced, and therefore the piezoelectric vibrators can be produced more efficiently.

(3) In the holding hole forming step, the holding hole may be formed to be a bottomed hole from the upper face side of the base substrate wafer; and the polishing step may include an upper face polishing step of polishing the upper face of the base substrate wafer by a predetermined thickness, and a lower face polishing step of polishing the lower face of the base substrate wafer until the holding hole runs through the wafer and the hardened paste is at least exposed out.

In this case, in the holding hole forming step, the holding hole is formed to be a bottomed hole from the upper face side of the base substrate wafer. Accordingly, in the filling step, the paste implanting operation is easy, and the process may be simplified. In addition, there is no risk of wasting the paste.

The polishing step includes an upper face polishing step and a lower face polishing step. In particular, in the lower face polishing step, the amount to be polished may be determined based on the thickness of the base substrate wafer and the depth of the holding hole, irrespective of the paste volume reduction in the firing. Accordingly, the lower face polishing step does not require the confirmation of the paste condition before polishing, and in the step, the predetermined amount may be polished. Accordingly, under-polishing or over-polishing may be prevented.

(4) The piezoelectric vibrator manufacturing method of the invention is a method for manufacturing a plurality of piezoelectric vibrators in which a piezoelectric vibration member is sealed up in a cavity formed between a base substrate and a lid substrate bonded to each other, all at once by utilizing a base substrate wafer and a lid substrate wafer, and the method comprises a recess forming step of forming, in the lid substrate wafer, a plurality of cavity recesses for forming cavities when the two wafers are overlaid; a through-electrode forming step of forming a plurality of through-electrodes in and through the base substrate wafer by utilizing a paste containing a plurality of metal fine particles; a routing electrode forming step of forming a plurality of routing electrodes connected electrically with the through-electrodes, on the upper face of the base substrate wafer; a mounting step of bonding the plural piezoelectric vibration members to the upper face of the base substrate wafer via the routing electrodes; an overlaying step of overlaying the base substrate wafer and the lid substrate wafer thereby to house the piezoelectric vibration members in the cavities surrounded by the recesses and the two wafers; a bonding step of bonding the base substrate wafer and the lid substrate wafer thereby to seal up the piezoelectric vibration members in the cavities; an external electrode forming step of forming a plurality of external electrodes connected electrically with the through-electrodes, on the lower face of the base substrate wafer; and a cutting step of cutting the two bonded wafers thereby to shred them into the plural piezoelectric vibrators; wherein the through-electrode forming step includes a hole forming step of forming a plurality of holes in the upper face of the base substrate wafer; a filling step of implanting the paste in these plural holes to block up the holes, and a firing step of firing the implanted paste at a predetermined temperature to harden the paste; an upper face polishing step of polishing, after the firing, the upper face of the base substrate wafer by a predetermined thickness; and a lower face polishing step of polishing, after the firing, the lower face of the base substrate wafer until the holes run through the wafer and the hardened paste is at least exposed out.

According to the piezoelectric vibrator manufacturing method of the invention, first attained is the recess forming step of forming a plurality of cavity recesses in the lid substrate wafer. The recesses are to be cavities when the two wafers are overlaid later. At the same time or in a timing of before or after the step, the through-electrode forming step is attained for forming a plurality of through-electrodes in the base substrate wafer. In this stage, plural through-electrodes are formed so as to be housed in the recesses formed in the lid substrate wafer when the two wafers are overlaid later.

The through-electrode forming step is described in detail. First attained is the hole forming step of forming a plurality of holes in the upper face of the base substrate wafer. Subsequently, the filling step is attained for implanting a paste containing fine metal particles in these plural holes with no space remaining therein to block up the holes. Subsequently, the firing step is attained for firing and hardening the filled paste at a predetermined temperature. Accordingly, the paste firmly sticks to the inner face of the hole.

Most organic matter in the paste evaporates away during the firing, and therefore, the volume of the hardened paste decreases as compared with the volume thereof in the filling step. Accordingly, the paste surface inevitably has depressions. Therefore, after the firing, the upper face polishing step is attained for polishing the upper face of the base substrate wafer by a predetermined thickness. In this step, in the upper face of the base substrate wafer, the paste hardened by the firing is also polished, and therefore the peripheries around the depressions can be cut off In other words, the surface of the hardened paste can be planarized. Therefore, in the upper face of the base substrate water, the surface of the base substrate wafer and the surface of the hardened paste can be substantially in a flat condition to each other.

At the same time or in a timing of before or after the upper face polishing step, the lower face polishing step is attained for polishing, after the firing, the lower face of the base substrate wafer until the holes run through the wafer and the hardened paste is at least exposed out. Accordingly, the paste hardened in the hole is exposed out to the lower face. By attaining the lower face polishing step, the holes formed in the base substrate wafer become through-holes that run through the base substrate wafer after the step, and the hardened paste becomes the through-electrode. In addition, like in the upper face polishing step, the surface of the base substrate wafer and the surface of the hardened paste can be substantially in a flat condition, also in the lower face of the base substrate.

After the upper face polishing step and the lower face polishing step, the through-hole forming step is finished. Since the plural metal fine particles in the paste are kept in contact with each other, the electric conductivity of the through-electrode is secured.

Next, the routing electrode forming step is attained for forming a plurality of routing electrodes connected electrically with the through-electrodes by patterning an electroconductive material on the upper face of the base substrate wafer. In this stage, the routing electrode is so formed that it can be housed in the recess formed in the lid substrate wafer when the two wafers are overlaid later.

In particular, the through-electrode is substantially in a flat condition relative to the upper face of the base substrate wafer with no surface depression, as so mentioned in the above. Accordingly, the routing electrode as patterned on the upper face of the base substrate wafer is kept in airtight contact with the through-electrode with no space therebetween. This secures the electric connection between the routing electrode and the through-electrode.

Next, the mounting step is attained for bonding a plurality of piezoelectric vibration members to the upper face of the base substrate wafer each via the routing electrode. Accordingly, the bonded piezoelectric vibration members are electrically connected to the through-electrodes via the routing electrodes. After the mounting operation, the overlaying step is attained for overlaying the base substrate wafer and the lid substrate wafer. Accordingly, the bonded plural piezoelectric vibration members are kept housed in the cavities surrounded by the recesses and the two wafers.

Next, the bonding step is attained for bonding the overlaid two wafers to each other. Accordingly, the two wafers adhere firmly to each other and therefore the piezoelectric vibration members can be sealed up in the cavities. In this stage, the through-holes formed in the base substrate wafer are blocked up with the through-electrodes, and therefore the airtightness inside the cavities is not broken through the through-holes. In particular, the paste to constitute the through-electrode firmly adheres to the inner face of the through-hole, therefore surely securing the airtightness inside the cavities.

Next, the external electrode forming step is attained for forming a plurality of external electrodes electrically connected with the respective through-electrodes by patterning an electroconductive material on the lower face of the base substrate wafer. Also in this case, the through-electrodes are kept substantially in a flat condition relative to the lower face of the base substrate wafer like in the formation of the routing electrodes, and therefore, the patterned external electrodes are kept in airtight contact with the through-electrodes with no space therebetween. Accordingly, the electric connection between the external electrode and the through-electrode can be secured. As a result of this step, the piezoelectric vibration members sealed up in the cavities can be activated as utilizing the external electrodes.

Finally, the cutting step is attained for cutting the base substrate wafer and the lid substrate wafer bonded to each other, to thereby shred them into a plurality of piezoelectric vibrators.

As a result, a plurality of two-layer structure-type surface-mount piezoelectric vibrators with piezoelectric vibration members sealed up in cavities formed between a base substrate and a lid substrate bonded to each other can be manufactured all at once.

In particular, since the through-electrodes can be formed substantially in a flat condition relative to the base substrate, the through-electrodes can be surely kept in airtight contact with the routing electrodes and the external electrodes. As a result, stable electric connection between the piezoelectric vibration members and the external electrodes can be secured, and the reliability of operation performance can be enhanced to attain high-quality devices. In addition, since the airtightness inside the cavities is surely kept, the high quality of the devices is secured in this respect.

Further, in the lower face polishing step, the amount to be polished may be determined based on the thickness of the base substrate wafer and the depth of the hole, irrespective of the paste volume reduction in the firing. Accordingly, the lower face polishing step does not require the confirmation of the paste condition before polishing, and in the step, the predetermined amount may be polished. Accordingly, under-polishing or over-polishing may be prevented.

In addition, the through-electrodes can be formed according to the simple method of using a paste, and the process may be simplified. Further, since the pates is implanted in the bottomed holes, the paste implantation operation is easy, and the process may be thereby simplified. In addition, there is no risk of wasting the paste.

(5) In the filling step, the paste may be defoamed and then implanted in the hole.

In this case, since the paste is previously processed for defoaming, the paste containing few foams can be filled. Therefore, the paste volume reduction can be prevented as much as possible in the firing step. Accordingly, the amount to be polished in the subsequent polishing step may be reduced, and the time necessary for the step may be reduced, and therefore the piezoelectric vibrators can be produced more efficiently.

(6) Or again, the piezoelectric vibrator manufacturing method of the invention is a method for manufacturing a plurality of piezoelectric vibrators in which a piezoelectric vibration member is sealed up in a cavity formed between a base substrate and a lid substrate bonded to each other, all at once by utilizing a base substrate wafer and a lid substrate wafer, and the method comprises a recess forming step of forming, in the lid substrate wafer, a plurality of cavity recesses for forming cavities when the two wafers are overlaid; a through-electrode forming step of forming a plurality of through-electrodes in and through the base substrate wafer by utilizing a paste containing a plurality of metal fine particles; a routing electrode forming step of forming a plurality of routing electrodes connected electrically with the through-electrodes, on the upper face of the base substrate wafer; a mounting step of bonding the plural piezoelectric vibration members to the upper face of the base substrate wafer via the routing electrodes; an overlaying step of overlaying the base substrate wafer and the lid substrate wafer thereby to house the piezoelectric vibration members in the cavities surrounded by the recesses and the two wafers; a bonding step of bonding the base substrate wafer and the lid substrate wafer thereby to seal up the piezoelectric vibration members in the cavities; an external electrode forming step of forming a plurality of external electrodes connected electrically with the through-electrodes, on the lower face of the base substrate wafer; and a cutting step of cutting the two bonded wafers thereby to shred them into the plural piezoelectric vibrators; wherein the through-electrode forming step includes a through-hole forming step of forming a plurality of through-holes in and through the base substrate water; a filling step of implanting the paste in the plural through-holes to block up the through-holes; a firing step of firing the implanted paste at a predetermined temperature to harden it; and a polishing step of polishing, after the firing, the two faces of the base substrate wafer each by a predetermined thickness.

According to the piezoelectric vibrator manufacturing method of the invention, first attained is the recess forming step of forming a plurality of cavity recesses in the lid substrate wafer. These recesses are to be cavities when the two wafers are overlaid later. At the same time or in a timing of before or after the step, the through-electrode forming step is attained for forming a plurality of through-electrodes in the base substrate wafer. In this stage, plural through-electrodes are formed so as to be housed in the recesses formed in the lid substrate wafer when the two wafers are overlaid later.

The through-electrode forming step is described in detail. First, the through-hole forming step is attained for forming a plurality of through-holes in and through the base substrate wafer. Subsequently, the filling step is attained for implanting a paste containing metal fine particles in these plural through-holes to block up the through-holes with no space remaining therein. Subsequently, the firing step is attained for firing the implanted paste at a predetermined temperature to harden it. Accordingly, the paste firmly sticks to the inner face of the through-holes. The volume of the hardened paste decreases as compared with the volume thereof in the filling step since the organic matter in the paste evaporates away in firing. Accordingly, the paste surface inevitably has depressions.

Therefore, the polishing step is attained after the firing, for polishing the two faces of the base substrate wafer by a predetermined thickness. In the step, the both faces of the paste hardened by the firing can also be polished, and therefore the peripheries of the depressions can be cut off. In other words, the surface of the hardened paste can be planarized. Accordingly, the surface of the base substrate wafer and the surface of the through-electrodes can be substantially in a flat condition. After the polishing step, the through-electrode forming step is finished. The plural metal fine particles in the paste are kept in contact with each other, therefore securing the electric conductivity of the through-electrodes.

Next, the routing electrode forming step is attained for forming a plurality of routing electrodes connected electrically with the through-electrodes by patterning an electroconductive material on the upper face of the base substrate wafer. In this stage, the routing electrode is so formed that it can be housed in the recess formed in the lid substrate wafer when the two wafers are overlaid later.

In particular, the through-electrode has no depression in the surface thereof and is substantially in a flat condition relative to the upper face of the base substrate wafer as so mentioned in the above. Accordingly, the routing electrode as patterned on the upper face of the base substrate wafer is kept in airtight contact with the through-electrode with no space therebetween. This secures the electric connection between the routing electrode and the through-electrode.

Next, the mounting step is attained for bonding a plurality of piezoelectric vibration members to the upper face of the base substrate wafer each via the routing electrode. Accordingly, the bonded piezoelectric vibration members are electrically connected to the through-electrodes via the routing electrodes. After the mounting operation, the overlaying step is attained for overlaying the base substrate wafer and the lid substrate wafer. Accordingly, the bonded plural piezoelectric vibration members are kept housed in the cavities surrounded by the recesses and the two wafers.

Next, the bonding step is attained for bonding the overlaid two wafers to each other. Accordingly, the two wafers adhere firmly to each other and therefore the piezoelectric vibration members can be sealed up in the cavities. In this stage, the through-holes formed in the base substrate wafer are blocked up by the through-electrodes, and the airtightness inside the cavity is not broken by the through-holes. In particular, the paste to constitute the through-electrode firmly sticks to the inner face of the through-hole, and therefore, the airtightness inside the cavity is surely secured.

Next, the external electrode forming step is attained for forming a plurality of external electrodes electrically connected with the respective through-electrodes by patterning an electroconductive material on the lower face of the base substrate wafer. Also in this case, the through-electrodes are kept substantially in a flat condition relative to the lower face of the base substrate wafer like in the formation of the routing electrodes, and therefore, the patterned external electrodes are kept in airtight contact with the through-electrodes with no space therebetween. Accordingly, the electric connection between the external electrode and the through-electrode can be secured. As a result of this step, the piezoelectric vibration members sealed up in the cavities can be activated as utilizing the external electrodes.

Finally, the cutting step is attained for cutting the base substrate wafer and the lid substrate wafer bonded to each other, to thereby shred them into a plurality of piezoelectric vibrators.

As a result, a plurality of two-layer structure-type surface-mount piezoelectric vibrators with piezoelectric vibration members sealed up in cavities formed between a base substrate and a lid substrate bonded to each other can be manufactured all at once.

In particular, since the through-electrodes can be formed, not having depressions in the surface thereof and kept substantially in a flat condition relative to the base substrate, the through-electrodes can be surely kept in airtight contact with the routing electrodes and the external electrodes. As a result, stable electric connection between the piezoelectric vibration members and the external electrodes can be secured, and the reliability of operation performance can be enhanced to attain high-quality devices. Further, since the airtightness inside the cavities is surely kept, the high quality of the devices is secured in this respect. In addition, since the through-electrodes can be formed according to the simple method of using a paste, the process can be simplified.

(7) In the filling step, the paste may be defoamed and then implanted in the through-hole.

In this case, since the paste is previously processed for defoaming, the paste containing few foams can be filled. Therefore, the paste volume reduction can be prevented as much as possible in the firing step. Accordingly, the amount to be polished in the subsequent polishing step may be reduced, and the time necessary for the step may be reduced, and therefore the piezoelectric vibrators can be produced more efficiently.

(8) Prior to the mounting step, the method may comprise a bonding film forming step of forming, on the upper face of the base substrate wafer, a bonding film to surround the periphery of the recesses when the base substrate wafer and the lid substrate wafer are overlaid; and in the bonding step, the two wafers may be anodically bonded via the bonding film.

In this case, since the base substrate wafer and the lid substrate wafer are anodically bonded via a bonding film, the two wafers can be more tightly bonded to each other to increase the airtightness inside the cavities. Accordingly, the piezoelectric vibration members can be vibrated with a higher degree of accuracy, and the devices can have further higher quality.

(9) In the mounting step, the piezoelectric vibration members may be bump-bonded with an electroconductive bump.

In this case, since the piezoelectric vibration members are bump-bonded, the piezoelectric vibration members can be spaced above from the upper face of the base substrate by the thickness of the bump. Accordingly, the required minimum vibration gap necessary for vibration of the piezoelectric vibration members can be naturally secured. Therefore, the reliability of the operation performance of the piezoelectric vibrators can be further enhanced.

(10) In the filling step, a paste containing non-spherical metal fine particles may be implanted.

In this case, the metal fine particles in the paste are not spherical but are non-spherical, and for example, they are shaped like thin and long fibers or are shaped to have a star-like cross section; and therefore, when they are kept in contact with each other, they may be readily in a line contact but not in a point contact. Accordingly, the electric conductivity of the through-electrodes can be further increased.

(11) In the filling step, a paste mixed with a granular material of which the thermal expansion coefficient is substantially equal to that of the base substrate wafer may be implanted.

In this case, since the paste is mixed with a granular material of which the thermal expansion coefficient is substantially equal to that of the base substrate wafer, the thermal expansion of the paste can be near to the thermal expansion of the base substrate wafer in firing. Accordingly, a space is hardly formed between the two owing to the thermal expansion difference therebetween, and the two can be kept in more airtight contact with each other. As a result, through-electrodes having a higher degree of airtightness can be formed, and long-term airtightness reliability can be enhanced.

(12) The piezoelectric vibrator of the invention comprises a base substrate of which the two faces are polished; a lid substrate in which cavity recesses are formed and which is bonded to the base substrate in such a state that the recesses face the base substrate; a piezoelectric vibration member bonded to the upper face of the base substrate in such a state that it is housed in the cavity formed of the recess between the base substrate and the lid substrate; an external electrode formed on the lower face of the base substrate; a through-electrode formed in and through the base substrate and electrically connected with the external electrode with keeping the airtightness inside the cavity; and a routing electrode formed on the upper face of the base substrate to electrically connect the through-electrode to the bonded piezoelectric vibration member; wherein the through-electrode is formed by hardening of a paste containing a plurality of metal fine particles.

The piezoelectric vibrator of the invention can be a high-quality two-layer structure-type, surface-mount piezoelectric vibrator that surely secures airtightness inside the cavity and secures stable electric connection between the piezoelectric vibration member and the external electrode therein.

(13) The base substrate and the lid substrate may be anodically bonded via a bonding film formed between the two substrates to surround the periphery of the recesses.

In this case, the same advantage and effect as those of the piezoelectric vibrator manufacturing method of the above (8) can be exhibited.

(14) The piezoelectric vibration member may be bump-bonded with an electroconductive bump.

In this case, the same advantage and effect as those of the piezoelectric vibrator manufacturing method of the above (9) can be exhibited.

(15) The metal fine particles may be non-spherical.

In this case, the same advantage and effect as those of the piezoelectric vibrator manufacturing method of the above (10) can be exhibited.

(16) The paste may be mixed with a granular material of which the thermal expansion coefficient is substantially equal to that of the base substrate.

In this case, the same advantage and effect as those of the piezoelectric vibrator manufacturing method of the above (11) can be exhibited.

(17) The oscillator of the invention comprises, as the oscillation member therein, the piezoelectric vibrator of any one of the above (12) to (16) as electrically connected to the integrated circuit therein.

(18) The electronic device of the invention comprises the piezoelectric vibrator of any one of the above (12) to (16) as electrically connected to the timer part therein.

(19) The radio-controlled watch of the invention comprises the piezoelectric vibrator of any one of the above (12) to (16) as electrically connected to the filter part therein.

The oscillator, the electronic device and the radio-controlled watch of the invention comprise a high-quality piezoelectric vibrator in which the cavity is surely airtightly sealed up and of which the reliability of the operation performance is enhanced, and therefore the reliability of the operation performance thereof can be enhanced and the quality thereof can be thereby increased.

The piezoelectric vibrator of the invention is a high-quality two-layer structure-type, surface-mount piezoelectric vibrator in which the airtightness inside the cavity is secured and the stable electric connection between the piezoelectric vibration member and the external electrode is secured.

According to the piezoelectric vibrator manufacturing method of the invention, the above-mentioned piezoelectric vibrators can be efficiently manufactured all at once, and the cost thereof can be thereby reduced.

The oscillator, the electronic device and the radio-controlled watch of the invention comprise the above-mentioned piezoelectric vibrator, and similarly the operation reliability thereof can be enhanced and the quality thereof can be thereby increased.

### BRIEF DESCRIPTION OF THE DRAWINGS

FIG. 1 is a perspective outline view showing the first embodiment of the piezoelectric vibrator of the invention.

FIG. 2 is an internal configuration view of the piezoelectric vibrator shown in FIG. 1, and is a top view of the piezoelectric vibrator from which the lid substrate was removed.

FIG. 3 is a cross-sectional view of the piezoelectric vibrator cut along the line A-A in FIG. 2.

FIG. 4 is a perspective exploded view of the piezoelectric vibrator shown in FIG. 1.

FIG. 5 is a top view of the piezoelectric vibration member constituting the piezoelectric vibrator shown in FIG. 1.

FIG. 6 is a bottom view of the piezoelectric vibration member shown in FIG. 5.

FIG. 7 is a cross-sectional outline view of B-B shown in FIG. 5.

FIG. 8 is an enlarged view of the through-electrode shown in FIG. 3, and is a view showing a paste containing plural metal fine particles.

FIG. 9 is a flowchart showing the flow in manufacturing the piezoelectric vibrator shown in FIG. 1.

FIG. 10 is a view showing one step in manufacturing piezoelectric vibrators according to the flowchart shown in FIG. 9, and is a view showing the condition where a plurality of recesses are formed in a lid substrate wafer which is an original to be a lid substrate.

FIG. 11 is a view showing one step in manufacturing piezoelectric vibrators according to the flowchart shown in FIG. 9, and is a view showing the condition where a plurality of holding holes are formed in a base substrate wafer which is an original to be a base substrate.

FIG. 12 is a cross-sectional view of the base substrate wafer in the condition shown in FIG. 11.

FIG. 13 is a view showing one step in manufacturing piezoelectric vibrators according to the flowchart shown in FIG. 9, and is a view showing the condition where, after the state shown in FIG. 12, a paste is filled in the holding hole.

FIG. 14 is a view showing one step in manufacturing piezoelectric vibrators according to the flowchart shown in FIG. 9, and is a view showing the condition where, after the state shown in FIG. 13, the paste is pre-fired.

FIG. 15 is a view showing one step in manufacturing piezoelectric vibrators according to the flowchart shown in FIG. 9, and is a view showing the condition where, after the state shown in FIG. 14, the holding hole is supplemented with a paste.

FIG. 16 is a view showing one step in manufacturing piezoelectric vibrators according to the flowchart shown in FIG. 9, and is a view showing the condition where, after the state shown in FIG. 15, the paste is finally fired.

FIG. 17 is a view showing one step in manufacturing piezoelectric vibrators according to the flowchart shown in FIG. 9, and is a view showing the condition where, after the state shown in FIG. 16, the two faces of the base substrate wafer are polished.

FIG. 18 is a view showing one step in manufacturing piezoelectric vibrators according to the flowchart shown in FIG. 9, and is a view showing the condition where, after the state shown in FIG. 17, the depression is removed and the through-electrode is in a flat condition relative to the surface of the base substrate wafer.

FIG. 19 is a view showing one step in manufacturing piezoelectric vibrators according to the flowchart shown in FIG. 9, and is a view showing the condition where, after the state shown in FIG. 18, a bonding film and a routing electrode are patterned on the upper face of the base substrate wafer.

FIG. 20 is an entire view of the base substrate wafer in the state shown in FIG. 19.

FIG. 21 is a view showing one step in manufacturing piezoelectric vibrators according to the flowchart shown in FIG. 9, and is a perspective exploded view of the wafer body in which the base substrate wafer and the lid substrate wafer are anodically-bonded and the piezoelectric vibration member is housed in the cavity.

FIG. 22 is a flowchart showing the flow in manufacturing the piezoelectric vibrator shown in FIG. 1, in the second embodiment of the invention.

FIG. 23 is a view showing one step in manufacturing piezoelectric vibrators according to the flowchart shown in FIG. 22, and is a view showing the condition where, after the state shown in FIG. 14, the two faces of the base substrate wafer are polished.

FIG. 24 is a view showing one step in manufacturing piezoelectric vibrators according to the flowchart shown in FIG. 22, and is a view showing the condition after the state shown in FIG. 23.

FIG. 25 is a view showing one step in manufacturing piezoelectric vibrators according to the flowchart shown in FIG. 22, and is a view showing the condition where, after the state shown in FIG. 24, the paste is finally fired.

FIG. 26 is a perspective exploded view showing the third embodiment of the piezoelectric vibrator of the invention.

FIG. 27 is an internal configuration view of the piezoelectric vibrator shown in FIG. 26, and is a top view of the piezoelectric vibrator from which the lid substrate was removed.

FIG. 28 is a cross-sectional view of the piezoelectric vibrator cut along the line A-A in FIG. 27.

FIG. 29 is a perspective exploded view of the piezoelectric vibrator shown in FIG. 26.

FIG. 30 is a top view of the piezoelectric vibration member constituting the piezoelectric vibrator shown in FIG. 26.

FIG. 31 is a bottom view of the piezoelectric vibration member shown in FIG. 30.

FIG. 32 is a cross-sectional outline view of B-B shown in FIG. 30.

FIG. 33 is an enlarged view of the through-electrode shown in FIG. 28, and is a view showing a paste containing plural metal fine particles.

FIG. 34 is a flowchart showing the flow in manufacturing the piezoelectric vibrator shown in FIG. 26.

FIG. 35 is a view showing one step in manufacturing piezoelectric vibrators according to the flowchart shown in FIG. 34, and is a view showing the condition where a plurality of recesses are formed in a lid substrate wafer which is an original to be a lid substrate.

FIG. 36 is a view showing one step in manufacturing piezoelectric vibrators according to the flowchart shown in FIG. 34, and is a view showing the condition where a plurality of holes are formed in a base substrate wafer which is an original to be a base substrate.

FIG. 37 is a cross-sectional view of the base substrate wafer in the condition shown in FIG. 36.

FIG. 38 is a view showing one step in manufacturing piezoelectric vibrators according to the flowchart shown in FIG. 34, and is a view showing the condition where, after the state shown in FIG. 37, a paste is filled in the hole.

FIG. 39 is a view showing one step in manufacturing piezoelectric vibrators according to the flowchart shown in FIG. 34, and is a view showing the condition where, after the state shown in FIG. 38, the paste is fired and hardened.

FIG. 40 is a view showing one step in manufacturing piezoelectric vibrators according to the flowchart shown in FIG. 34, and is a view showing the condition where, after the state shown in FIG. 39, the two faces of the base substrate wafer are polished.

FIG. 41 is a view showing one step in manufacturing piezoelectric vibrators according to the flowchart shown in FIG. 34, and is a view showing the condition where, after the state shown in FIG. 40, the depression is removed and the through-electrode is in a flat condition relative to the surface of the base substrate wafer.

FIG. 42 is a view showing one step in manufacturing piezoelectric vibrators according to the flowchart shown in FIG. 34, and is a view showing the condition where, after the state shown in FIG. 41, a bonding film and a routing electrode are patterned on the upper face of the base substrate wafer.

FIG. 43 is an entire view of the base substrate wafer in the state shown in FIG. 42.

FIG. 44 is a view showing one step in manufacturing piezoelectric vibrators according to the flowchart shown in FIG. 34, and is a perspective exploded view of the wafer body in which the base substrate wafer and the lid substrate wafer are anodically-bonded and the piezoelectric vibration member is housed in the cavity.

FIG. 45 is a perspective outline view showing the fourth embodiment of the piezoelectric vibrator of the invention.

FIG. 46 is an internal configuration view of the piezoelectric vibrator shown in FIG. 45, and is a top view of the piezoelectric vibrator from which the lid substrate was removed.

FIG. 47 is a cross-sectional view of the piezoelectric vibrator cut along the line A-A in FIG. 46.

FIG. 48 is a perspective exploded view of the piezoelectric vibrator shown in FIG. 45.

FIG. 49 is a top view of the piezoelectric vibration member constituting the piezoelectric vibrator shown in FIG. 45.

FIG. 50 is a bottom view of the piezoelectric vibration member shown in FIG. 49.

FIG. 51 is a cross-sectional outline view of B-B shown in FIG. 49.

FIG. 52 is an enlarged view of the through-electrode shown in FIG. 47, and is a view showing a paste containing plural metal fine particles.

FIG. 53 is a flowchart showing the flow in manufacturing the piezoelectric vibrator shown in FIG. 45.

FIG. 54 is a view showing one step in manufacturing piezoelectric vibrators according to the flowchart shown in FIG. 53, and is a view showing the condition where a plurality of recesses are formed in a lid substrate wafer which is an original to be a lid substrate.

FIG. 55 is a view showing one step in manufacturing piezoelectric vibrators according to the flowchart shown in FIG. 53, and is a view showing the condition where a pair of through-holes are formed in a base substrate wafer which is an original to be a base substrate.

FIG. 56 is a cross-sectional view of the base substrate wafer in the condition shown in FIG. 55.

FIG. 57 is a view showing one step in manufacturing piezoelectric vibrators according to the flowchart shown in FIG. 53, and is a view showing the condition where, after the state shown in FIG. 56, a paste is filled in the through-hole.

FIG. 58 is a view showing one step in manufacturing piezoelectric vibrators according to the flowchart shown in FIG. 53, and is a view showing the condition where, after the state shown in FIG. 57, the paste is fired and hardened to form a through-hole.

FIG. 59 is a view showing one step in manufacturing piezoelectric vibrators according to the flowchart shown in FIG. 53, and is a view showing the condition where, after the state shown in FIG. 58, the two faces of the base substrate wafer are polished.

FIG. 60 is a view showing one step in manufacturing piezoelectric vibrators according to the flowchart shown in FIG. 53, and is a view showing the condition where, after the state shown in FIG. 59, the depression is removed and the through-electrode is in a flat condition relative to the surface of the base substrate wafer.

FIG. 61 is a view showing one step in manufacturing piezoelectric vibrators according to the flowchart shown in FIG. 53, and is a view showing the condition where, after the state shown in FIG. 60, a bonding film and a routing electrode are patterned on the upper face of the base substrate wafer.

FIG. 62 is an entire view of the base substrate wafer in the state shown in FIG. 61.

FIG. 63 is a view showing one step in manufacturing piezoelectric vibrators according to the flowchart shown in FIG. 53, and is a perspective exploded view of the wafer body in which the base substrate wafer and the lid substrate wafer are anodically-bonded and the piezoelectric vibration member is housed in the cavity.

FIG. 64 is a configuration view showing one embodiment of the oscillator of the invention.

FIG. 65 is a constitutive view showing one embodiment of the electronic device of the invention.

FIG. 66 is a constitutive view showing one embodiment of the radio-controlled watch of the invention.

FIG. 67 is an enlarged view showing a modification of the paste in the invention.

FIG. 68A is a view showing a modification of the metal fine particle in the invention, which is formed to be a strip-like one.

FIG. 68B is a view showing a modification of the metal fine particle in the invention, which is formed to be a waved one.

FIG. 68C is a view showing a modification of the metal fine particle in the invention, which is formed to have a star-shaped cross section.

FIG. 68D is a view showing a modification of the metal fine particle in the invention, which is formed to have a crisscross section.

FIG. 69 is a cross-sectional view of a modification of the piezoelectric vibrator of the invention.

FIG. 70 is an internal configuration view of a conventional piezoelectric vibrator, and is a top view of the piezoelectric vibration member thereof from which the lid substrate was removed.

FIG. 71 is a cross-sectional view of the piezoelectric vibrator shown in FIG. 70.

### DETAILED DESCRIPTION OF THE PREFERRED EMBODIMENTS

### First Embodiment

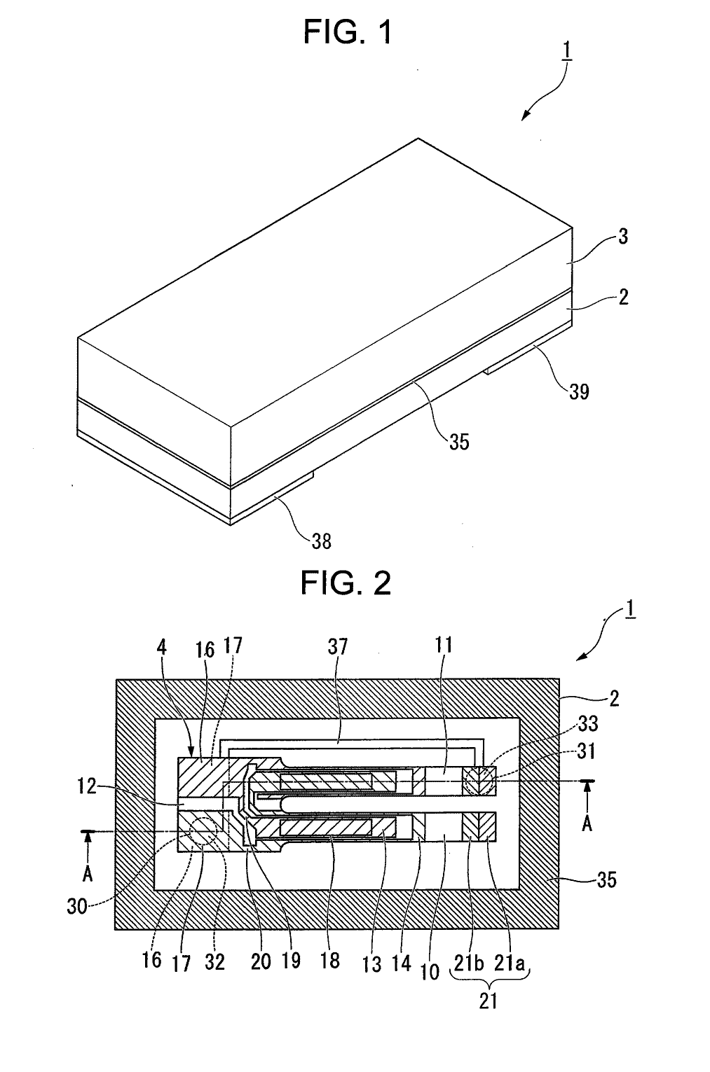

The first embodiment of the invention is described below with reference to FIG. 1 to FIG. 21.

The piezoelectric vibrator 1 of this embodiment is, as shown in FIG. 1 to FIG. 4, a surface-mount piezoelectric vibrator 1 that is formed to have a two-layer laminate boxy shape composed of a base substrate 2 and a lid substrate 3, in which a piezoelectric vibration member 4 is housed in the cavity C inside it.

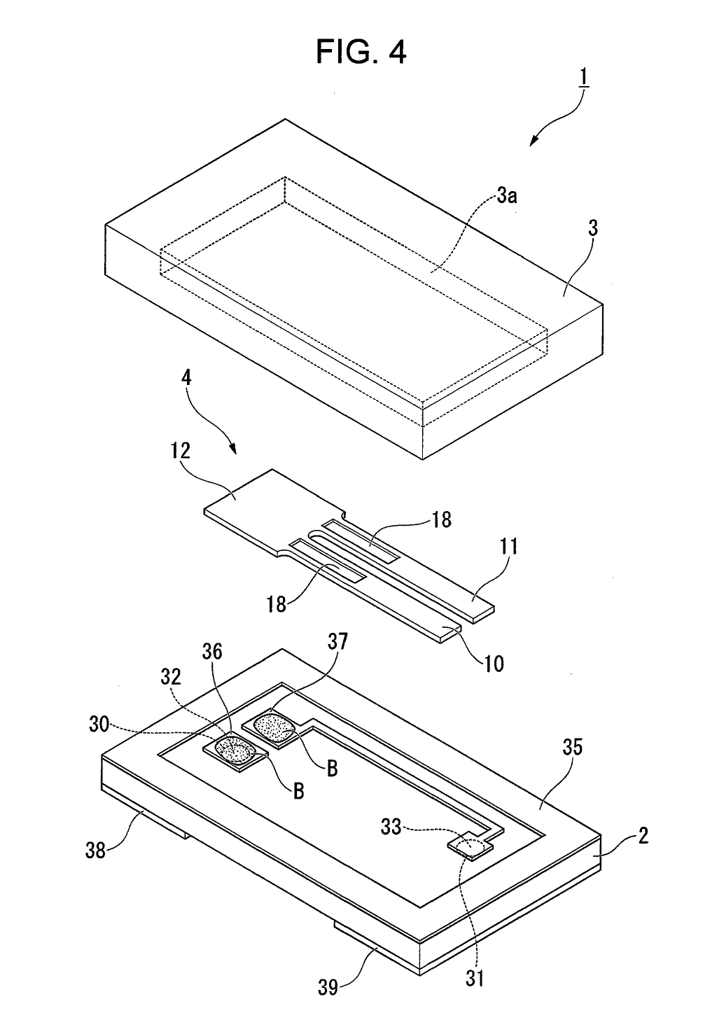

In FIG. 4, an excitation electrode 15, routing electrodes 19 and 20, mount electrodes 16 and 17, and a weight metal film 21 to be mentioned below are omitted for facilitating the understating of the view.

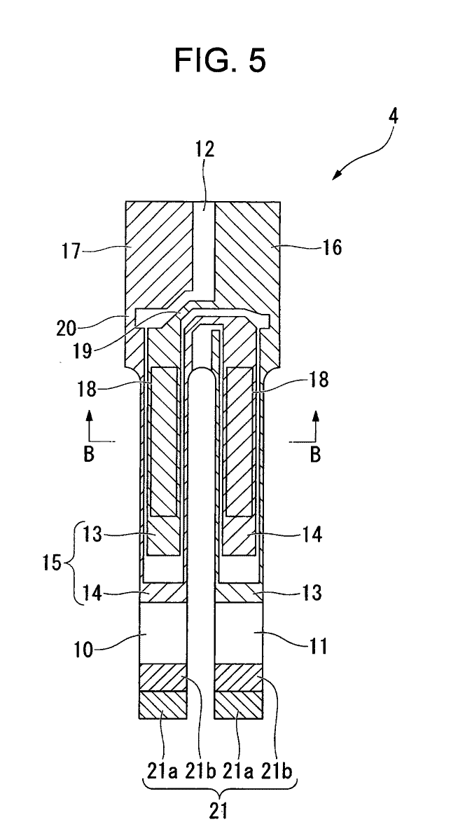

As shown in FIG. 5 to FIG. 7, the piezoelectric vibration member 4 is a tuning fork-like vibration member formed of a piezoelectric material such as crystal, lithium tantalate, lithium niobate or the like, and this vibrates when a predetermined voltage is applied thereto.

The piezoelectric vibration member 4 has a pair of vibration arms 10 and 11 disposed in parallel to each other, a base 12 to integrally fix the base side of the pair of vibration arms 10 and 11, an excitation electrode 15 composed of a first excitation electrode 13 and a second excitation electrode 14 for vibrating the pair of the vibration arms 10 and 11, as formed on the outer surface of the pair of the vibration arms 10 and 11, and mount electrodes 16 and 17 electrically connected with the first excitation electrode 13 and the second excitation electrode 14.

The piezoelectric vibration member 4 in this embodiment comprises, on both the two main faces of the pair of vibration arms 10 and 11, a groove 18 formed along the longitudinal direction of the vibration arms 10 and 11. The groove 18 is formed from the base side to around the intermediate part of the vibration arms 10 and 11.

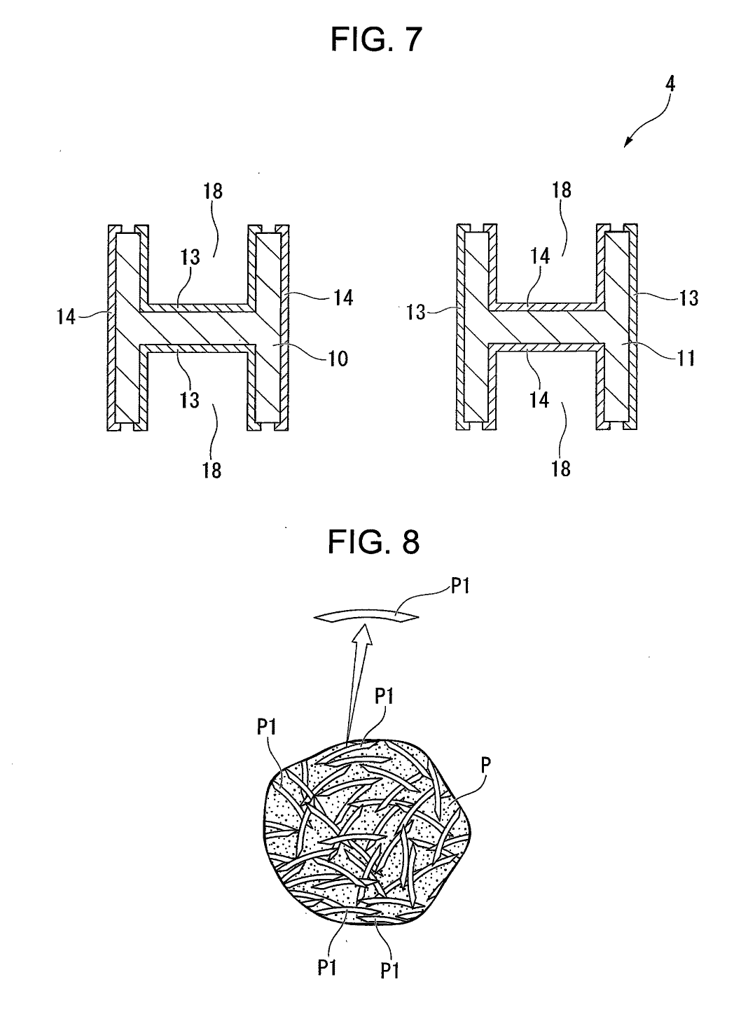

The excitation electrode 15 composed of the first excitation electrode 13 and the second excitation electrode 14 is an electrode to vibrate the pair of vibration arms 10 and 11 in the direction in which they come near to and get away from each other, at a predetermined resonance frequency, and this is patterned on the outer surface of the pair of vibration arms 10 and 11, as electrically insulated from each other. Concretely, as shown in FIG. 7, the first excitation electrode 13 is formed mainly on the groove 18 of one vibration arm 10 and on the two side faces of the other vibration arm 11; while the second excitation electrode 14 is formed mainly on the two side faces of one vibration arm 10 and on the groove 18 of the other vibration arm 11.

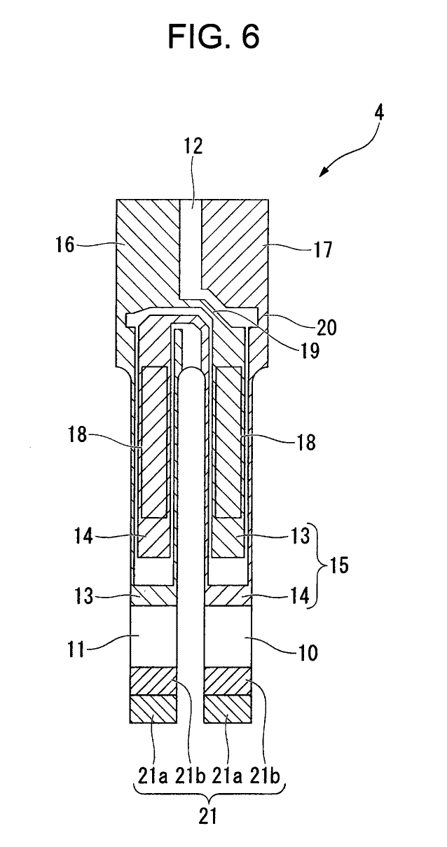

The first excitation electrode 13 and the second excitation electrode 14 are, as shown in FIG. 5 and FIG. 6, electrically connected to the mount electrodes 16 and 17 via the routing electrodes 19 and 20, respectively, on the two main faces of the base 12. The piezoelectric vibration member 4 is given a voltage via the mount electrodes 16 and 17.

The above-mentioned excitation electrode 15, mount electrodes 16 and 17 and routing electrodes 19 and 20 are, for example, formed of a coating film of an electroconductive film of chromium (Cr), nickel (Ni), aluminum (Al), titanium (Ti) or the like.

The top of the pair of vibration arms 10 and 11 is coated with a weight metal film 21 for tuning the vibration condition of the arms themselves within a predetermined frequency range (frequency tuning). The weight metal film 21 is divided into two, a rough-tuning film 21a for use in roughly tuning the frequency and a fine-tuning film 21b for use in finely tuning it. With these rough-tuning film 21a and fine-tuning film 21b, the frequency is tuned, whereby the frequency of the pair of vibration arms 10 and 11 can be controlled to fall within a range of the nominal frequency of the device.

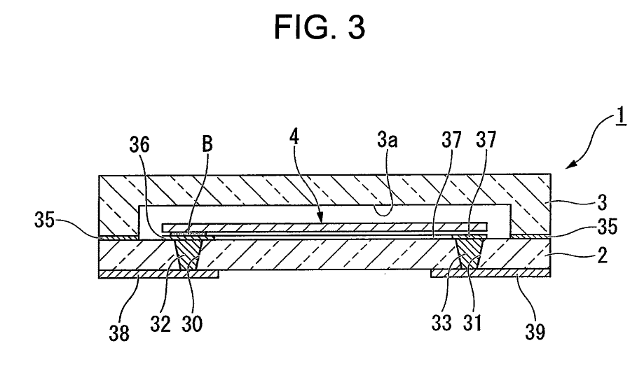

The thus-constituted piezoelectric vibration member 4 is, as shown in FIG. 3 and FIG. 4, bump-bonded to the upper face of the base substrate 2 with a bump B of gold or the like. More concretely, on the two bumps B formed on the routing electrodes 36 and 37, as patterned on the upper face of the base substrate 2, a pair of mount electrodes 16 and 17 are bump-bonded as kept in contact with each other. Accordingly, the piezoelectric vibration member 4 is supported as spaced above from the upper face of the base substrate 2, and the mount electrodes 16 and 17 are electrically connected to the routing electrodes 36 and 37, respectively.

The lid substrate 3 is a transparent insulating substrate formed of a glass material, for example, soda lime glass; and as shown in FIG. 1, FIG. 3 and FIG. 4, this is shaped to be tabular. On the bonding face side to which the base substrate 2 is bonded, formed is a rectangular recess 3a in which the piezoelectric vibration member 4 is housed. The recess 3a is a cavity recess 3a to be a cavity C to house the piezoelectric vibration member 4 therein when the two substrates 2 and 3 are overlaid. The lid substrate 3 is anodically bonded to the base substrate 2 with the recess 3a kept facing the side of the base substrate 2.

The base substrate 2 is, like the lid substrate 3, a transparent insulating substrate formed of a glass material, for example, soda lime glass; and as shown in FIG. 1 to FIG. 4, this is formed to be tabular and have a size capable of being overlaid on the lid substrate 3.

The base substrate 2 is formed to have a pair of through-holes 30 and 31 in and through the base substrate 2. In this case, the pair of through-holes 30 and 31 are so formed as to be housed inside the cavity C. More precisely, the through-holes 30 and 31 in this embodiment are so formed that one through-hole 30 is positioned on the side of the base 12 of the mounted piezoelectric vibration member 4 and the other through-hole 31 is positioned on the top side of the vibration arms 10 and 11. In this embodiment, a tapered through-hole of which the diameter of the cross section gradually decreases toward the lower face of the base substrate 2 is described as one example; but not limited to this case, the through-hole may also be a straight through-hole that runs straightly through the base substrate 2. Anyhow, the through-hole may be any one that runs through the base substrate 2.

In the pair of through-holes 30 and 31, provided are a pair of through-electrodes 32 and 33 that are so formed as to fill up the through-holes 30 and 31. These through-electrodes 32 and 33 are, as shown in FIG. 8, formed by hardening of the paste P containing plural metal fine particles P1; and these play a role of completely blocking up the through-holes 30 and 31 and keeping the airtightness inside the cavity C, and electrically connecting the external electrodes 38 and 39 with the routing electrodes 36 and 37 as described below.

The through-electrodes 32 and 33 secure the electroconductivity thereof as the plural metal fine particles P1 are kept in contact with each other in the paste P. The metal fine particles P1 in this embodiment are described with reference to a case where the particles are in the form of thin and long fibrous (non-spherical) particles of copper or the like.

On the upper face side of the base substrate 2 (the bonding face side thereof to which a lid substrate 3 is bonded), an anodic-bonding film 35 and a pair of routing electrodes 36 and 37 are patterned with an electroconductive material (for example, aluminum), as shown in FIG. 1 to FIG. 4. Of those, the bonding film 35 is formed along the peripheral edge of the base substrate 2 so as to surround the periphery of the recess 3a formed in the lid substrate 3.

The pair of routing electrodes 36 and 37 are so patterned as to electrically connect one through-hole 32 of the pair of through-holes 32 and 33, with one mount electrode 16 of the piezoelectric vibration member 4, and to electrically connect the other through-electrode 33 with the other mount electrode 17 of the piezoelectric vibration member 4. More precisely, one routing electrode 36 is formed just above one through-electrode 32 so as to be positioned just below the base 12 of the piezoelectric vibration member 4; and the other routing electrode 37 is so formed as to be positioned just above the other through-electrode 33 after drawn from the position adjacent to one routing electrode 36 to the top of the vibration arms 10 and 11 along the vibration arms 10 and 11.

A bump B is formed on the pair of routing electrodes 36 and 37, and via the bump B, the piezoelectric vibration member 4 is mounted. Accordingly, one mount electrode 16 of the piezoelectric vibration member 4 is electrically connected to one through-electrode 32 via one routing electrode 36, and the other mount electrode 17 is electrically connected to the other through-electrode 33 via the other routing electrode 37.

On the lower face of the base substrate 2, formed are external electrodes 38 and 39 to be electrically connected to the pair of through-electrodes 32 and 33, respectively, as shown in FIG. 1, FIG. 3 and FIG. 4. In other words, one external electrode 38 is electrically connected to the first excitation 13 of the piezoelectric vibration member 4 via one through-electrode 32 and one routing electrode 36. The other external electrode 39 is electrically connected to the second excitation electrode 14 of the piezoelectric vibration member 4 via the other through-electrode 33 and the other routing electrode 37.

To operate the thus-constituted piezoelectric vibrator 1, a predetermined driving voltage is applied to the external electrodes 38 and 39 formed on the base substrate 2. Accordingly, a current is applied to the excitation electrode 15 composed of the first excitation electrode 13 and the second excitation electrode 14 of the piezoelectric vibration member 4, whereby the pair of vibration arms 10 and 11 are vibrated at a predetermined frequency in the direction in which they come near to and get away from each other. Based on the vibration of the pair of vibration arms 10 and 11, the vibrator can be used as a time source, a timing source of control signals or the like, a reference signal source, etc.

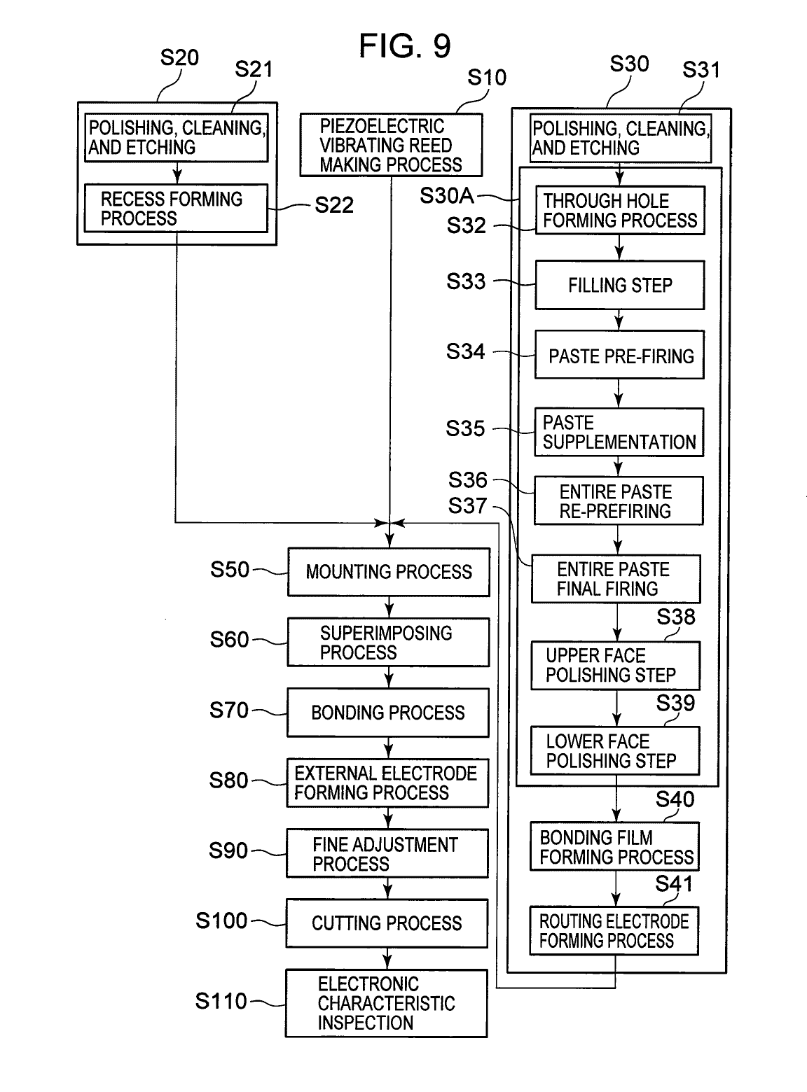

Next described is a method for manufacturing a plurality of piezoelectric vibrators 1 mentioned above all at once, by utilizing the base substrate wafer 40 and the lid substrate wafer 50, with reference to the flowchart shown in FIG. 9.

First, a piezoelectric vibration member forming step is attained to form the piezoelectric vibration member 4 shown in FIG. 5 to FIG. 7 (S10). Concretely, first, a rough Lambertian quartz is sliced at a predetermined angle to give a wafer having a predetermined thickness. Subsequently, the wafer is roughly worked by lapping, then the work-affected layer is removed by etching, and thereafter this is mirror-finished by polishing or the like to give a wafer having a predetermined thickness. Subsequently, the wafer is suitably processed by washing or the like, and then the wafer is patterned into an external shape of the piezoelectric vibration member 4 through photolithography, and a metal film is formed and patterned to thereby form the excitation electrode 15, the routing electrodes 19 and 20, the mount electrodes 16 and 17, and the weight metal film 21. Accordingly, a plurality of piezoelectric vibration members 4 are formed.

After the piezoelectric vibration members 4 are formed, they are processed for rough-tuning of resonance frequency. This is attained by irradiating the rough-tuning film 21a of the weight metal film 21 with a laser light to partly evaporate it, thereby changing the weight thereof. Regarding the fine tuning for resonance frequency, the members are processed after mounting. This is described later.

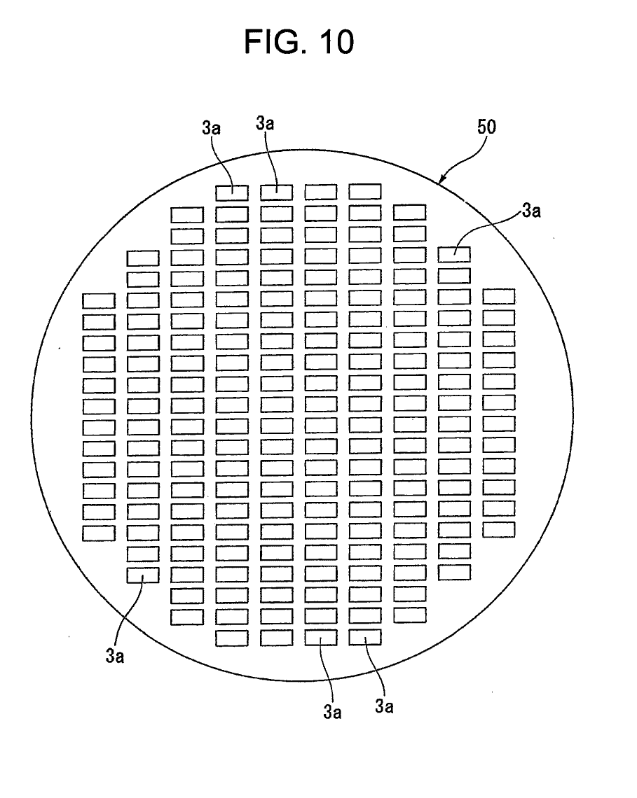

Next, a first wafer forming step is attained for forming a lid substrate wafer 50 to be the lid substrate 3 later up to the state just before anodic bonding (S20). First, soda lime glass is polished to have a predetermined thickness and washed, and then, as shown in FIG. 10, the work-affected layer of the outermost surface is removed by etching or the like to give a disc-like lid substrate wafer 50 (S21). Next, a recess forming step is attained for forming a plurality of cavity recesses 3a in the line direction by etching or the like in the bonding face of the lid substrate wafer 50 (S22). At this stage, the first wafer forming step is finished.

Next, at the same time or in a timing of before or after the above step, a second wafer forming step is attained for forming a base substrate wafer 40 to be the base substrate 2 later up to the state just before anodic bonding (S30). First, soda lime glass is polished to have a predetermined thickness and washed, and then, the work-affected layer of the outermost surface is removed by etching or the like to give a disc-like base substrate wafer 40 (S31). Next, a through-electrode forming step is attained for forming a plurality of pairs of through-electrodes 32 and 33 in the base substrate wafer 40, using a paste P containing plural metal fine particles P1 (S30A). Here, the through-electrode forming step is described in detail.

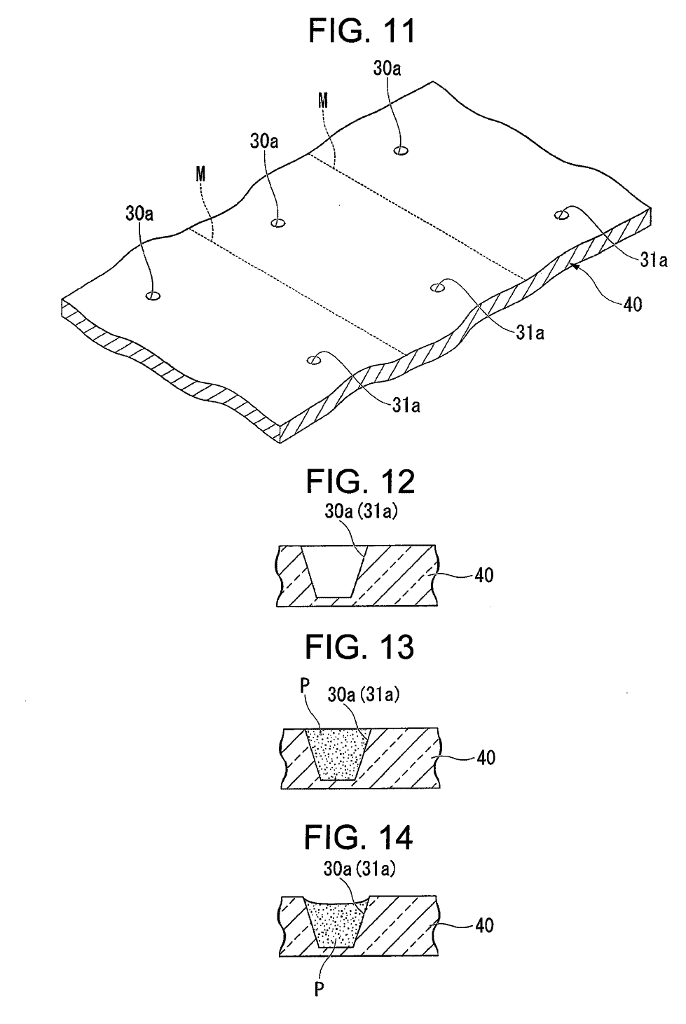

First, as shown in FIG. 11, for holding the paste P, a holding hole forming step (S32) is attained for forming a plurality of pairs of bottomed holding holes 30a and 31a in the upper face of the base substrate wafer 40. The dotted line M shown in FIG. 11 means a section line for cutting in the subsequent cutting step. In this step, the upper face of the base substrate wafer 40 is processed, for example, according to a sand-blasting method. Accordingly, as shown in FIG. 12, tapered bottomed holding holes 30a and 31a are formed, which are bottomed on the lower face side and of which the hole diameter of the cross section gradually decreases toward the lower face of the base substrate wafer 40. A plurality of pairs of holding holes 30a and 31a are so formed as to be housed in the recesses 3a formed in the lid substrate wafer 50, when the two wafers 40 and 50 are overlaid later. Further, they are so positioned that one holding hole 30a can be positioned on the side of the base 12 of the piezoelectric vibration member 4 and the other holding hole 31a can be on the top side of the vibration arms 10 and 11.

In this embodiment, an illustrative case is referred to, in which the hole diameter of the tapered holding holes decreases toward the lower face of the base substrate wafer 40; however, not limited to this case, the holding holes may have a uniform hole diameter. Anyhow, the bottomed holding holes may be any ones having a bottom on the lower face side of the base substrate wafer 40.

Subsequently, as shown in FIG. 13, a filling step is attained for implanting a paste into these plural holding holes 30a and 31a with no space left therein to block up the holding holes 30a and 31a (S33). In this stage, since the holding holes 30a and 31a are bottomed, the operation of implanting the paste P into them is easy, and the process can be simplified. In addition, there is no risk of wasting the paste P. Subsequently, a firing step is attained for pre-firing, then finally firing and hardening the filled paste P. Concretely, first, the implanted paste P is pre-fired (S34). The heating condition for pre-firing is, for example, preferably at 80° C. and for around 30 minutes.

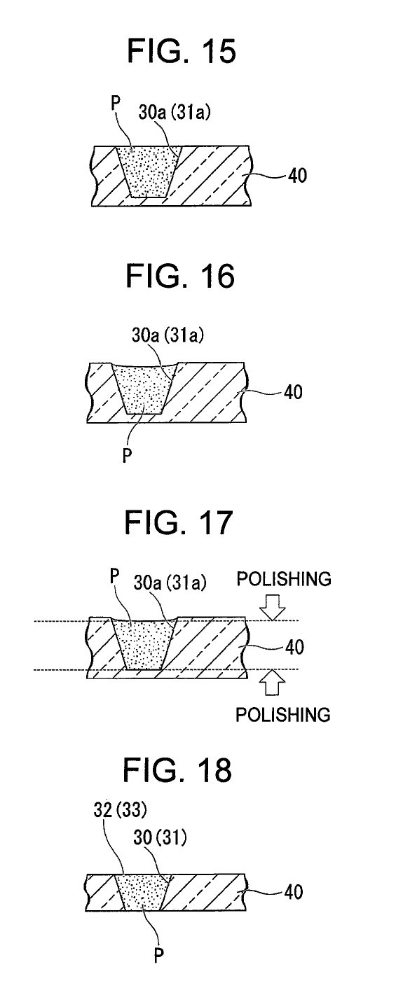

Regarding the paste P hardened by the pre-firing, most organic matter in the paste P (not shown) evaporates away during the pre-firing, and therefore, the volume of the hardened paste decreases as compared with the volume thereof in the filling step as shown in FIG. 14. Accordingly, the surface of the paste P inevitably has depressions. Therefore, prior to final firing, the pre-fired paste P is supplemented with a fresh paste P in an amount corresponding to the paste amount decreased by the pre-firing (S35). As a result, the fresh paste P is filled in the depressions, and therefore the surface becomes flat as in FIG. 15.

After the supplementation with the paste P is finished, the entire paste P is again pre-fired for the purpose of preventing the inorganic matter in the supplemented paste P from rapidly evaporating away during the final firing (S36). After the pre-firing, the entire paste P is finally fired (S37). The heating temperature in the final firing is, for example, preferably from 400° C. to 500° C. or so. Accordingly, the pre-fired paste P and the newly added paste P are completely hardened to be in an integrated state, and in a state firmly sticking to the inner face of the holding holes 30a and 31a. After the pre-firing and the final firing of the paste P, the firing step is finished.

Of the finally fired paste P, the paste P implanted in the filling step loses most organic matter that evaporates away in the initial pre-firing, and therefore its volume decreases little in the subsequent pre-firing and final firing after the supplementation with the paste P. On the other hand, the volume of the fresh paste P added through supplementation after the first pre-firing decreases by the pre-firing and the final firing after the supplementation with the paste P; however, the amount of the paste P itself is extremely small as compared with the entire volume of the paste P in the holding holes 30a and 31a. Accordingly, the influence of the volume reduction in the pre-firing and the final firing of the additional paste P on the volume of the entire paste P is small to an ignorable degree. Therefore, even through the reduction in the volume of the newly-added paste P is taken into consideration, the surface of the paste P hardened by the final firing is not greatly depressed. Specifically, on the upper face of the base substrate wafer 40, the surface of the base substrate wafer 40 can be substantially in a flat condition relative to the surface of the hardened paste P, as in FIG. 16.

After the firing step, a polishing step is attained for polishing the two faces of the base substrate wafer 40 by a predetermined thickness. More concretely, as shown in FIG. 17, an upper face polishing step is attained for polishing the upper face of the base substrate wafer 40 by a predetermined thickness (S38). In this step, on the upper face of the base substrate wafer 40, the paste P hardened by the final firing can also be polished simultaneously. Accordingly, the peripheries of any slight depressions of the paste P can be cut off. In other words, the surface of the hardened paste P can be planarized more as shown in FIG. 18. Accordingly, the surface of the base substrate wafer 40 and the surface of the hardened paste P can be in a flatter condition.

At the same time or in a timing of before or after the upper face polishing step, as shown in FIG. 17, a lower face polishing step is attained for polishing the lower face of the base substrate wafer 40 until it reaches the bottom of the holding holes 30a and 31a (S39). Accordingly, as shown in FIG. 18, the paste P hardened in the holding holes 30a and 31a is exposed out through the lower face. As a result of the lower face polishing step, the pair of holding holds 30a and 31a formed in the base substrate wafer 40 become, after this, through-holes 30 and 31 running through the base substrate wafer 40, and the hardened paste P becomes a pair of through-electrodes 32 and 33. In addition, on the lower face of the base substrate wafer 40, the surface of the base substrate wafer 40 can be substantially in a flat condition relative to the surface of the hardened paste P. After the upper face polishing step and the lower face polishing step, the polishing step is finished. After the polishing step, the through-electrode forming step is finished.

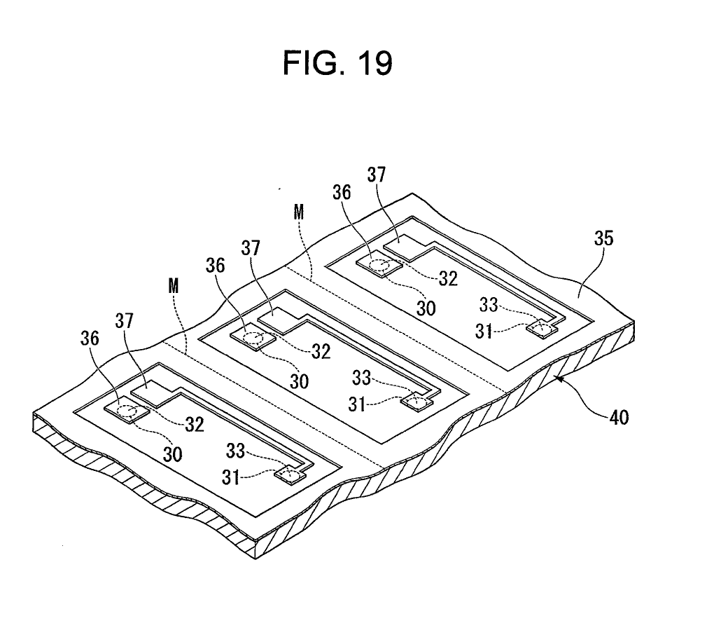

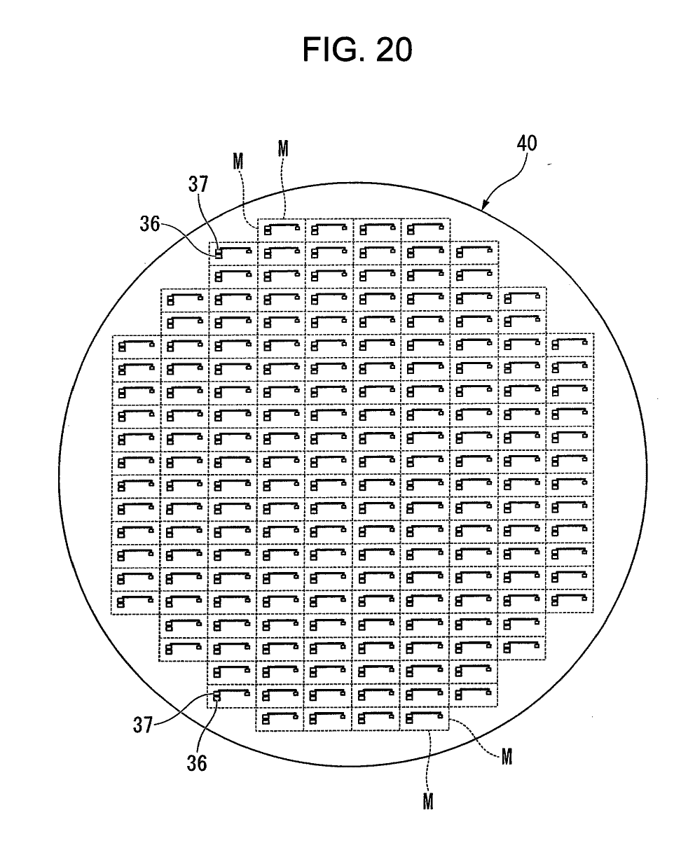

Next, a bonding film forming step is attained for forming a bonding film 35 by patterning an electroconductive material on the upper face of the base substrate wafer 40, as shown in FIG. 19 and FIG. 20 (S40); and at the same time, a routing electrode forming step is attained for forming a plurality of routing electrodes 36 and 37 connected electrically with the pair of through-electrodes 32 and 33 (S41). The dotted line M shown in FIG. 19 and FIG. 20 means a section line for cutting in the subsequent cutting step.

In particular, as so mentioned in the above, the through-electrodes 32 and 33 are substantially in a flat condition relative to the upper face of the base substrate wafer 40. Accordingly, the routing electrodes 36 and 37 as patterned on the upper face of the base substrate wafer 40 are kept in airtight contact with the through-electrodes 32 and 33 with no space therebetween. This secures the electric connection between one routing electrode 36 and one through-electrode 32 and the electric connection between the other routing electrode 37 and the other through-electrode 33. At this time, the second wafer forming step is finished.

In FIG. 9, the bonding film forming step (S40) is followed by the routing electrode forming step (S41) as the process sequence; however, in an opposite manner, the routing electrode forming step (S41) may be followed by the bonding film forming step (S40), or the two steps may be attained at the same time. In any process sequence, the same advantage and effect can be exhibited. Accordingly, the process sequence may be optionally changed or modified in any desired order.

Next, a mounting step is attained for bonding the formed, plural piezoelectric vibration members 4 onto the upper face of the base substrate wafer 40 via the routing electrodes 36 and 37 (S50). First, a bump B of gold or the like is formed on the pair of routing electrodes 36 and 37. After the base 12 of the piezoelectric vibration member 4 is put on the bump B, the piezoelectric vibration member 4 is pressed against the bump B while the bump B is heated at a predetermined temperature. Accordingly, the piezoelectric vibration member 4 is mechanically supported by the bump B, and the mount electrodes 16 and 17 are electrically connected with the routing electrodes 36 and 37. Therefore, at this time, the pair of excitation electrodes 15 of the piezoelectric vibration member 4 are electrically connected to the pair of through-electrodes 32 and 33, respectively.

In particular, the piezoelectric vibration member 4 is bump-bonded, and therefore it is supported as spaced above from the upper face of the base substrate wafer 40.

After the mounting of the piezoelectric vibration member 4 is finished, an overlaying step is attained for overlaying the base substrate wafer 40 and the lid substrate wafer 50 (S60). Concretely, the two wafers 40 and 50 are aligned in a correct position based on a reference mark or the like (not shown) as an index. Accordingly, the mounted piezoelectric vibration member 4 is kept housed in the cavity C surrounded by the recess 3a formed in the base substrate wafer 40 and the two wafers 40 and 50.

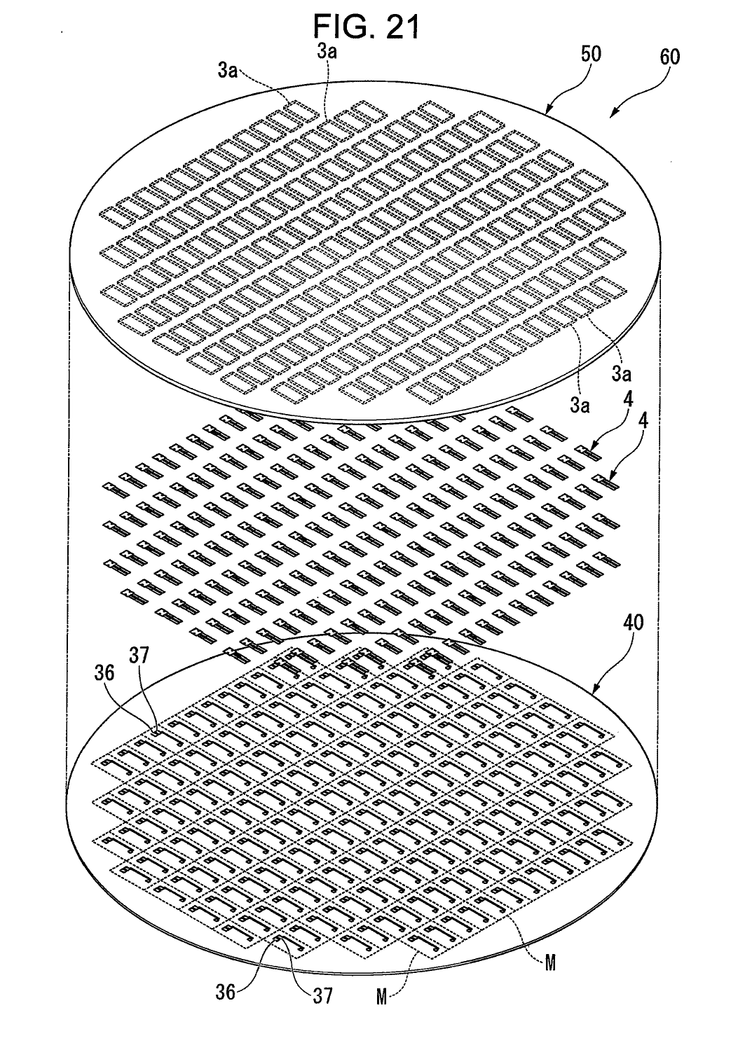

After the overlaying step, a bonding step is attained for anodically bonding the overlaid two wafers 40 and 50 by putting them in an anodic bonding apparatus (not shown) and applying a predetermined voltage thereto in a predetermined temperature atmosphere (S70). Concretely, a predetermined voltage is applied between the bonding film 35 and the lid substrate wafer 50. With that, there occurs electrochemical reaction in the interface between the bonding film 35 and the lid substrate wafer 50, whereby the two firmly stick to each other to attain anodic bonding therebetween. Accordingly, the piezoelectric vibration member 4 can be sealed up in the cavity C, and a wafer body 60 as shown in FIG. 21 can be obtained in which the base substrate wafer 40 and the lid substrate wafer 50 are bonded to each other. FIG. 21 illustrates an exploded state of the wafer body 60 for facilitating the understating of the view, in which the illustrative constitution of from the base substrate wafer 40 to the bonding film 35 is omitted. The dotted line M shown in FIG. 21 means a section line for cutting in the subsequent cutting step.

In anodic bonding, the through-holes 30 and 31 formed in the base substrate wafer 40 are completely blocked up by the through-electrodes 32 and 33, and therefore, the airtightness inside the cavity C is not broken by the through-holes 30 and 31. In particular, the paste P to constitute the through-electrodes 32 and 33 firmly sticks to the inner face of the through-holes 30 and 31, and therefore the airtightness inside the cavity C can be surely secured.

After the above-mentioned anodic bonding is finished, an external electrode forming step is attained for forming a plurality of pairs of external electrodes 38 and 39 electrically connected to the pairs of through-electrodes 32 and 33, respectively, by patterning an electroconductive material on the lower face of the base substrate wafer 40 (S80). As a result of this step, the piezoelectric vibration member 4 sealed up in the cavity C can be operated by utilizing the external electrodes 38 and 39.

In particular, also in attaining this step, the through-electrodes 32 and 33 are kept substantially in a flat condition relative to the lower face of the base substrate wafer 40, like in the case of forming the routing electrodes 36 and 37, and therefore the patterned external electrodes 38 and 39 can be kept in airtight contact with the through-electrodes 32 and 33 with no space therebetween. Accordingly, the electric connection between the external electrodes 38 and 39 with the through-electrodes 32 and 33 is secured.

Next, a fine-tuning step is attained for finely tuning the frequency of the individual piezoelectric vibrators 1 sealed up in the cavities C in the state of the wafer body 60 to make it fall within a predetermined range (S90). Concretely, a voltage is applied to the pair of external electrodes 38 and 39 formed on the lower face of the base substrate wafer 40 to thereby vibrate the piezoelectric vibration member 4. Then, with monitoring the frequency, this is irradiated with a laser light from the outside through the lid substrate wafer 50, to thereby evaporate the fine-tuning film 21b of the weight metal film 21. As a result, the weight of the top side of the pair of vibration arms 10 and 11 changes, and therefore the frequency of the piezoelectric vibration member 4 can be finely tuned so as to fall within a predetermined range of a nominal frequency.

After the fine-tuning of frequency is finished, a cutting step is attained for cutting the bonded wafer body 60 to thereby shred it into the individual pieces along the section line M shown in FIG. 21 (S100). As a result, a plurality of two-layer structure-type, surface-mount piezoelectric vibrators 1 as in FIG. 1 can be produced all at once, in which the piezoelectric vibration member 4 is sealed up in the cavity C formed between the base substrate 2 and the lid substrate 3 anodically bonded to each other.

The process sequence may be in an order of the cutting step (S100) of shredding into the individual piezoelectric vibrators 1 followed by the fine-tuning step (S90). However, as so mentioned in the above, in case where the fine-tuning step (S90) is attained previously, then the tuning can be effected in the state of the wafer body 60 and therefore a plurality of piezoelectric vibrators 1 can be finely tuned more efficiently. Accordingly, it is favorable as increasing the throughput.

After this, the internal electric characteristics are inspected (S110). Specifically, the piezoelectric vibration member 4 is checked for the resonance frequency, the resonance resistance, the drive level characteristic (excitation power dependence of the resonance frequency and the resonance resistance), etc. In addition, it is checked also for the insulation resistance characteristic, etc. Finally, the piezoelectric vibrator 1 is checked for the appearance thereof in point of the dimension and the quality, etc. With that, the manufacture of the piezoelectric vibrator 1 is finished.

In particular, in the piezoelectric vibrator 1 of this embodiment, the through-electrodes 32 and 33 can be formed substantially in a flat condition relative to the base substrate 2, and therefore the through-electrodes 32 and 33 can be surely kept in airtight contact with the routing electrodes 36 and 37 and the external electrodes 38 and 39. As a result, stable electric connection between the piezoelectric vibration member 4 with the external electrodes 38 and 39 can be secured, and the operation performance reliability of the piezoelectric vibrator can be enhanced and the quality thereof can be increased. Further, the airtightness inside the cavity C can be secured, and in this point, the quality of the device can be increased. In addition, since the through-holes 32 and 33 can be formed according to a simple method of using the paste P, the working process can be simplified.

According to the manufacturing method of this embodiment, a plurality of the above-mentioned piezoelectric vibrators 1 can be manufactured all at once, and therefore the manufacturing cost can be reduced.

Further, in the polishing step, especially in the lower face polishing step, the amount to be polished may be determined based on the thickness of the base substrate wafer 40 and the depth of the holding holes 30a and 31a, not depending on the volume of the paste P that decreases in firing. In other words, the polishing may be attained until it reaches the bottom of the holding holes 30a and 31a. Accordingly, the polishing does not require the confirmation of the condition of the paste P before polishing, and in the step, the predetermined amount may be polished. Accordingly, under-polishing or over-polishing may be prevented.

After pre-firing, the paste P is added and the final firing is attained, and therefore, the surface depression of the paste P can be reduced. Accordingly, in the polishing step, especially in the upper face polishing step, the amount to be abraded of the base substrate wafer 40 is extremely small. Therefore, the time necessary for the polishing step may be shortened, and the efficiency in the production process of the piezoelectric vibrator 1 can be enhanced.

In addition, the polishing step is attained after the final firing, the surface of the base substrate wafer 40 that is substantially in a flat condition relative to the surface of the hardened paste P is further polished. Accordingly, the surface of the base substrate wafer 40 and the surface of the hardened paste P can be in a flatter condition to each other.

### Second Embodiment

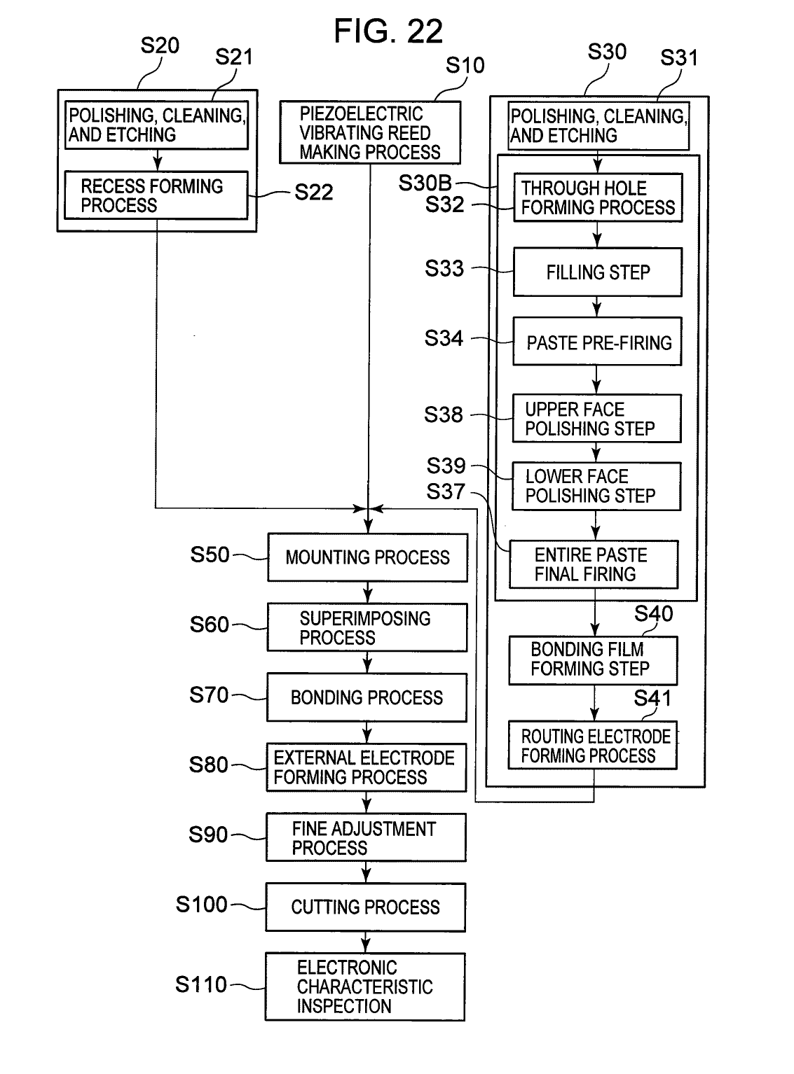

The second embodiment of the invention is described below with reference to FIG. 22 to FIG. 25. In the second embodiment, the same constitutive elements as those in the first embodiment are given the same reference numerals or signs, and their description is omitted.

The second embodiment differs from the first embodiment in the process sequence of the through-hole forming step in the manufacturing method. Specifically, in the first embodiment, the paste P implanted in the filling step is pre-fired, then immediately a fresh paste P is added and again pre-fired, and thereafter this is finally fired, and then the polishing step is attained; however, in the second embodiment, the paste P implanted in the filling step is pre-fired and then immediately the polishing step is attained, and thereafter this is finally fired. Hereinafter with reference to the flow chart of the manufacturing method of the second embodiment of the invention shown in FIG. 22, the through-hole forming step (S30B) in this embodiment is described.

For the through-hole forming step in this embodiment, the process up to the pre-firing of the paste P implanted in the filling step is the same as in the first embodiment.

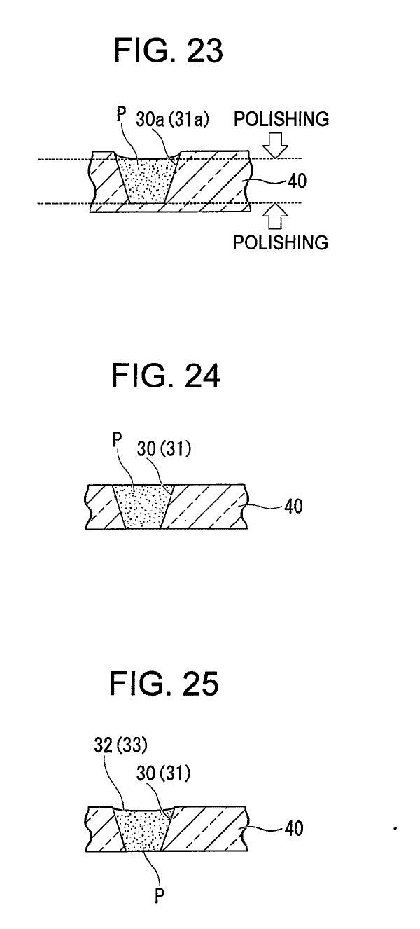

After the paste P implanted in the filling step is pre-fired, the surface of the paste P may have depressions. Therefore, immediately after the pre-firing, a polishing step is attained for polishing the two faces of the base substrate wafer 40 by a predetermined thickness. Specifically, as shown in FIG. 23, an upper face polishing step of polishing the upper face of the base substrate wafer 40 by a predetermined thickness, and a lower face polishing step of polishing the lower face of the base substrate wafer 40 to reach the bottom of the holding holes 30a and 31a are attained. Accordingly, as shown in FIG. 24, the holding holes 30a and 31a become through-holes 30 and 31. In addition, since the peripheries around the depressions of the paste P can be cut off, the surface of the base substrate wafer 40 and the surface of the pre-fired paste P can be substantially in a flat condition to each other.

The reduction in the volume of the paste P in the pre-firing is small as compared with that in a case of one final firing with no pre-firing. Accordingly, the surface depressions of the paste P formed by the pre-firing are smaller than those to be formed in a case where the same amount of the paste P is finally fired once with no pre-firing. Therefore, by attaining the polishing step immediately after the pre-firing of the paste P, the amount to be abraded may be reduced, and in particular, the time necessary for polishing the upper face can be shortened.

After the upper face polishing step and the lower face polishing step, the polishing step is finished.

After the polishing step, the paste P is finally fired and is thereby hardened. Accordingly, the paste P firmly sticks to the inner face of the through-holes 30 and 31, and the paste P functions as the through-electrodes 32 and 33. In addition, since most organic matter in the paste P has already evaporated away in the pre-firing, the volume reduction in the final firing is extremely small. Accordingly, the surface of the base substrate wafer 40 and the surface of the hardened paste P keep a substantially flat condition to each other like that before the final firing. After the final firing, the through-electrode forming step is finished.

The manufacturing method of this embodiment exhibits the same effect and advantage as in the first embodiment, and in addition, since the upper polishing step is attained just after the pre-firing of the paste P implanted in the filling step, the time necessary for the polishing step may be shortened as compared with a case where the polishing step is attained immediately after direct one final firing with no pre-firing.

### Third Embodiment

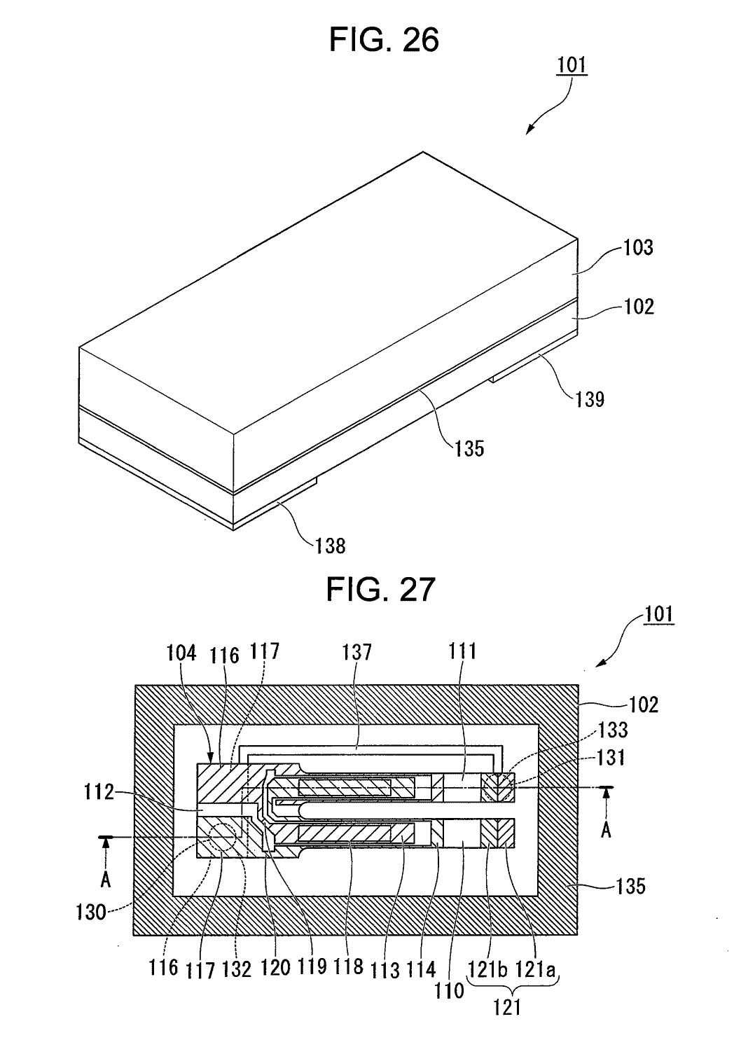

The third embodiment of the invention is described below with reference to FIG. 26 to FIG. 44.

The piezoelectric vibrator 101 of this embodiment is, as shown in FIG. 26 to FIG. 29, a surface-mount piezoelectric vibrator 101 that is formed to have a two-layer laminate boxy shape composed of a base substrate 102 and a lid substrate 103, in which a piezoelectric vibration member 104 is housed in the cavity C inside it.

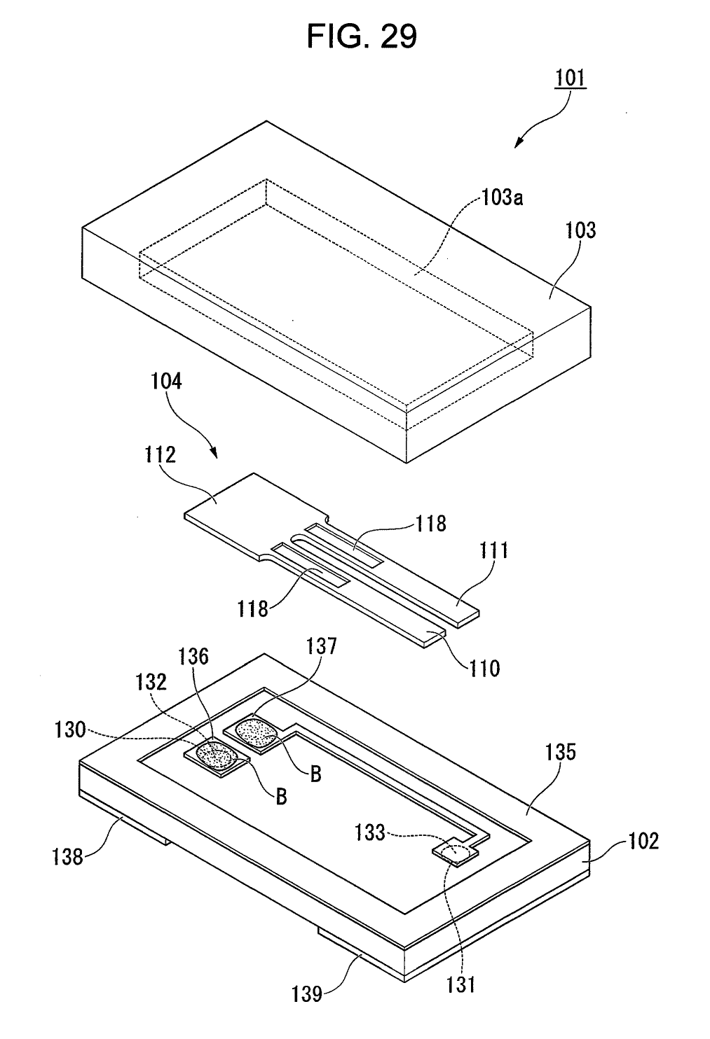

In FIG. 29, an excitation electrode 115, routing electrodes 119 and 120, mount electrodes 116 and 117, and a weight metal film 121 to be mentioned below are omitted for facilitating the understating of the view.

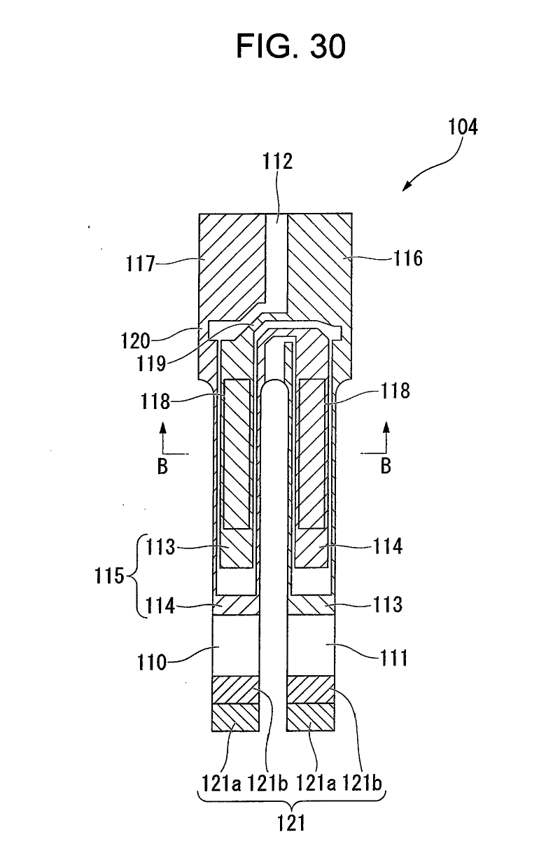

As shown in FIG. 30 to FIG. 32, the piezoelectric vibration member 104 is a tuning fork-like vibration member formed of a piezoelectric material such as crystal, lithium tantalate, lithium niobate or the like, and this vibrates when a predetermined voltage is applied thereto.

The piezoelectric vibration member 104 has a pair of vibration arms 110 and 111 disposed in parallel to each other, a base 112 to integrally fix the base side of the pair of vibration arms 110 and 111, an excitation electrode 115 composed of a first excitation electrode 113 and a second excitation electrode 114 for vibrating the pair of the vibration arms 110 and 111, as formed on the outer surface of the pair of the vibration arms 110 and 111, and mount electrodes 116 and 117 electrically connected with the first excitation electrode 113 and the second excitation electrode 114.

The piezoelectric vibration member 104 in this embodiment comprises, on both the two main faces of the pair of vibration arms 110 and 111, a groove 118 formed along the longitudinal direction of the vibration arms 110 and 111. The groove 118 is formed from the base side to around the intermediate part of the vibration arms 110 and 111.

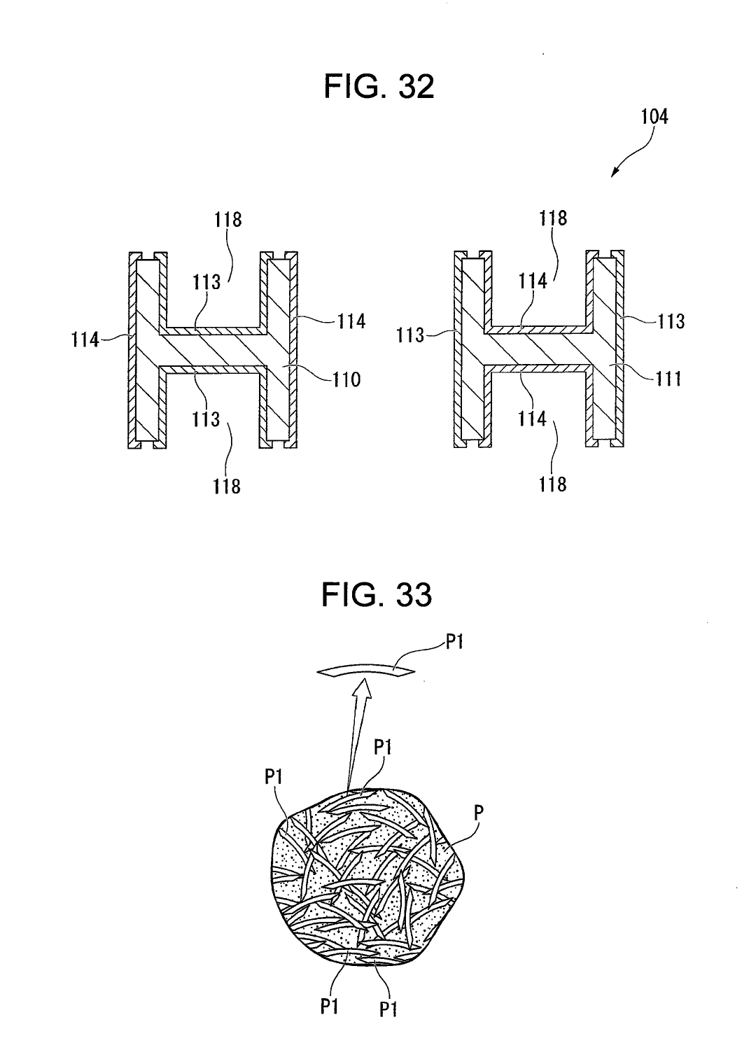

The excitation electrode 115 composed of the first excitation electrode 113 and the second excitation electrode 114 is an electrode to vibrate the pair of vibration arms 110 and 111 in the direction in which they come near to and get away from each other, at a predetermined resonance frequency, and this is patterned on the outer surface of the pair of vibration arms 110 and 111, as electrically insulated from each other. Concretely, as shown in FIG. 32, the first excitation electrode 113 is formed mainly on the groove 118 of one vibration arm 110 and on the two side faces of the other vibration arm 111; while the second excitation electrode 114 is formed mainly on the two side faces of one vibration arm 110 and on the groove 118 of the other vibration arm 111.

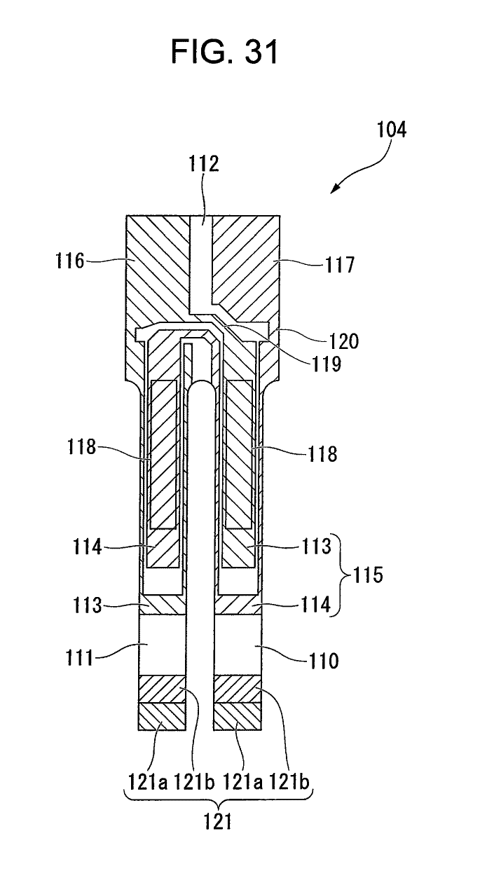

The first excitation electrode 113 and the second excitation electrode 114 are electrically connected to the mount electrodes 116 and 117 via the routing electrodes 119 and 120, respectively, on the two main faces of the base 112, as shown in FIG. 30 and FIG. 31. The piezoelectric vibration member 104 is given a voltage via the mount electrodes 116 and 117.

The above-mentioned excitation electrode 115, mount electrodes 116 and 117 and routing electrodes 119 and 120 are, for example, formed of a coating film of an electroconductive film of chromium (Cr), nickel (Ni), aluminum (Al), titanium (Ti) or the like.

The top of the pair of vibration arms 110 and 111 is coated with a weight metal film 121 for tuning the vibration condition of the arms themselves within a predetermined frequency range (frequency tuning). The weight metal film 121 is divided into two, a rough-tuning film 121a for use in roughly tuning the frequency and a fine-tuning film 121b for use in finely tuning it. With these rough-tuning film 121a and fine-tuning film 121b, the frequency is tuned, whereby the frequency of the pair of vibration arms 110 and 111 can be controlled to fall within a range of the nominal frequency of the device.

The thus-constituted piezoelectric vibration member 104 is, as shown in FIG. 27 and FIG. 29, bump-bonded to the upper face of the base substrate 102 with a bump B of gold or the like. More concretely, on the two bumps B formed on the routing electrodes 136 and 137, as patterned on the upper face of the base substrate 102, a pair of mount electrodes 116 and 117 are bump-bonded as kept in contact with each other. Accordingly, the piezoelectric vibration member 104 is supported as spaced above from the upper face of the base substrate 102, and the mount electrodes 116 and 117 are electrically connected to the routing electrodes 136 and 137, respectively.

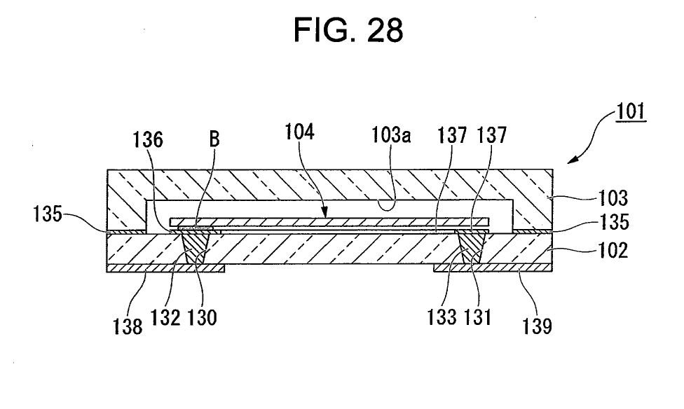

The lid substrate 103 is a transparent insulating substrate formed of a glass material, for example, soda lime glass; and as shown in FIG. 26, FIG. 28 and FIG. 29, this is shaped to be tabular. On the bonding face side to which the base substrate 102 is bonded, formed is a rectangular recess 103a in which the piezoelectric vibration member 104 is housed. The recess 103a is a cavity recess to be a cavity C to house the piezoelectric vibration member 104 therein when the two substrates 102 and 103 are overlaid. The lid substrate 103 is anodically bonded to the base substrate 102 with the recess 103a kept facing the side of the base substrate 102.

The base substrate 102 is, like the lid substrate 103, a transparent insulating substrate formed of a glass substrate, for example, soda lime glass; and as shown in FIG. 26 to FIG. 29, this is formed to be tabular and have a size capable of being overlaid on the lid substrate 103.

The base substrate 102 is formed to have a pair of through-holes 130 and 131 in and through the base substrate 102. In this case, the pair of through-holes 130 and 131 are so formed as to be housed inside the cavity C. More precisely, the through-holes 130 and 131 in this embodiment are so formed that one through-hole 130 is positioned on the side of the base 112 of the mounted piezoelectric vibration member 104 and the other through-hole 131 is positioned on the top side of the vibration arms 110 and 111.

In this embodiment, a tapered through-hole of which the diameter of the cross section gradually decreases toward the lower face of the base substrate 102 is described as one example; but not limited to this case, the through-hole may also be a straight through-hole that runs straightly through the base substrate 102. Anyhow, the through-hole may be any one that runs through the base substrate 102.

In the pair of through-holes 130 and 131, formed are a pair of through-electrodes 132 and 133 that fill up the through-holes 130 and 131. These through-electrodes 132 and 133 are, as shown in FIG. 33, formed by hardening of the paste P containing plural metal fine particles P1, and play a role of completely blocking up the through-holes 130 and 131 and keeping the airtightness inside the cavity C, and electrically connecting the external electrodes 138 and 139 with the routing electrodes 136 and 137 as described below.

The through-electrodes 132 and 133 secure the electroconductivity thereof as the plural metal fine particles P1 in the paste P are kept in contact with each other. The metal fine particles P1 in this embodiment are described with reference to a case where the particles are in the form of thin and long fibrous (non-spherical) particles of copper or the like.

On the upper face side of the base substrate 102 (the bonding face side thereof to which a lid substrate 103 is bonded), an anodic-bonding film 135 and a pair of routing electrodes 136 and 137 are patterned with an electroconductive material (for example, aluminum), as shown in FIG. 26 to FIG. 29. Of those, the bonding film 135 is formed along the peripheral edge of the base substrate 102 so as to surround the periphery of the recess 103a formed in the lid substrate 103.

The pair of routing electrodes 136 and 137 are so patterned as to electrically connect one through-hole 132 of the pair of through-holes 132 and 133, with one mount electrode 116 of the piezoelectric vibration member 104, and to electrically connect the other through-electrode 133 with the other mount electrode 117 of the piezoelectric vibration member 104. More precisely, one routing electrode 136 is formed just above one through-electrode 132 so as to be positioned just below the base 112 of the piezoelectric vibration member 104; and the other routing electrode 137 is so formed as to be positioned just above the other through-electrode 133 after drawn from the position adjacent to one routing electrode 136 to the top of the vibration arms 110 and 111 along the vibration arms 110 and 111.

A bump B is formed on the pair of routing electrodes 136 and 137, and via the bump B, the piezoelectric vibration member 104 is mounted. Accordingly, one mount electrode 116 of the piezoelectric vibration member 104 is electrically connected to one through-electrode 132 via one routing electrode 136, and the other mount electrode 117 is electrically connected to the other through-electrode 133 via the other routing electrode 137.

On the lower face of the base substrate 102, formed are external electrodes 138 and 139 to be electrically connected to the pair of through-electrodes 132 and 133, respectively, as shown in FIG. 26, FIG. 28 and FIG. 29. In other words, one external electrode 138 is electrically connected to the first excitation 113 of the piezoelectric vibration member 104 via one through-electrode 132 and one routing electrode 136. The other external electrode 139 is electrically connected to the second excitation electrode 114 of the piezoelectric vibration member 104 via the other through-electrode 133 and the other routing electrode 137.

To operate the thus-constituted piezoelectric vibrator 101, a predetermined driving voltage is applied to the external electrodes 138 and 139 formed on the base substrate 102. Accordingly, a current is applied to the excitation electrode 115 composed of the first excitation electrode 113 and the second excitation electrode 114 of the piezoelectric vibration member 104, whereby the pair of vibration arms 110 and 111 are vibrated at a predetermined frequency in the direction in which they come near to and get away from each other. Based on the vibration of the pair of vibration arms 110 and 111, the vibrator can be used as a time source, a timing source of control signals or the like, a reference signal source, etc.

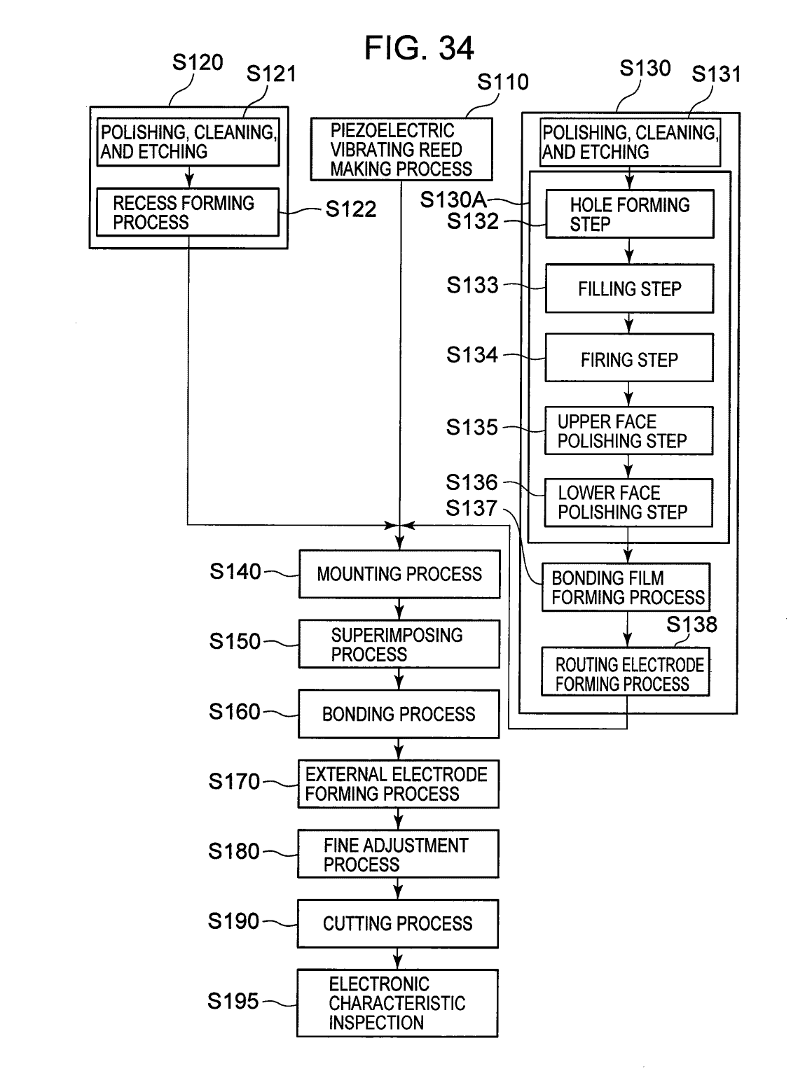

Next described is a method for manufacturing a plurality of piezoelectric vibrators 101 mentioned above all at once, by utilizing the base substrate wafer 140 and the lid substrate wafer 150, with reference to the flowchart shown in FIG. 34.

First, a piezoelectric vibration member forming step is attained to form the piezoelectric vibration member 104 shown in FIG. 30 to FIG. 32 (S110). Concretely, first, a rough Lambertian quartz is sliced at a predetermined angle to give a wafer having a predetermined thickness. Subsequently, the wafer is roughly worked by lapping, then the work-affected layer is removed by etching, and thereafter this is mirror-finished by polishing or the like to give a wafer having a predetermined thickness. Subsequently, the wafer is suitably processed by washing or the like, and then the wafer is patterned into an external shape of the piezoelectric vibration member 104 through photolithography, and a metal film is formed and patterned to thereby form the excitation electrode 115, the routing electrodes 119 and 120, the mount electrodes 116 and 117, and the weight metal film 121. Accordingly, a plurality of piezoelectric vibration members 104 are formed.

After the piezoelectric vibration members 104 are formed, they are processed for rough-tuning of resonance frequency. This is attained by irradiating the rough-tuning film 121a of the weight metal film 121 with a laser light to partly evaporate it, thereby changing the weight thereof. Regarding the fine tuning for resonance frequency, the members are processed after mounting. This is described later.

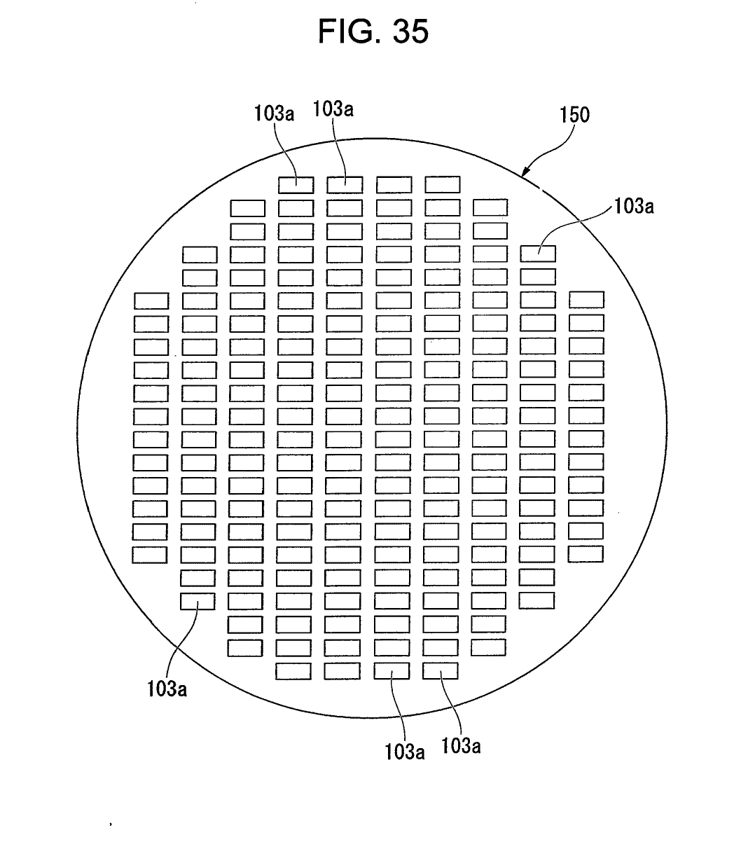

Next, a first wafer forming step is attained for forming a lid substrate wafer 150 to be the lid substrate 103 later up to the state just before anodic bonding (S120). First, soda lime glass is polished to have a predetermined thickness and washed, and then, as shown in FIG. 35, the work-affected layer of the outermost surface is removed by etching or the like to give a disc-like lid substrate wafer 150 (S121). Next, a recess forming step is attained for forming a plurality of cavity recesses 103a in the line direction by etching or the like in the bonding face of the lid substrate wafer 150 (S122). At this stage, the first wafer forming step is finished.

Next, at the same time or in a timing of before or after the above step, a second wafer forming step is attained for forming a base substrate wafer 140 to be the base substrate 102 later up to the state just before anodic bonding (S130). First, soda lime glass is polished to have a predetermined thickness and washed, and then, the work-affected layer of the outermost surface is removed by etching or the like to give a disc-like base substrate wafer 140 (S131). Next, a through-electrode forming step is attained for forming a plurality of pairs of through-electrodes 132 and 133 in the base substrate wafer 140, using a paste P containing plural metal fine particles P1 (S130A). Here, the through-electrode forming step is described in detail.

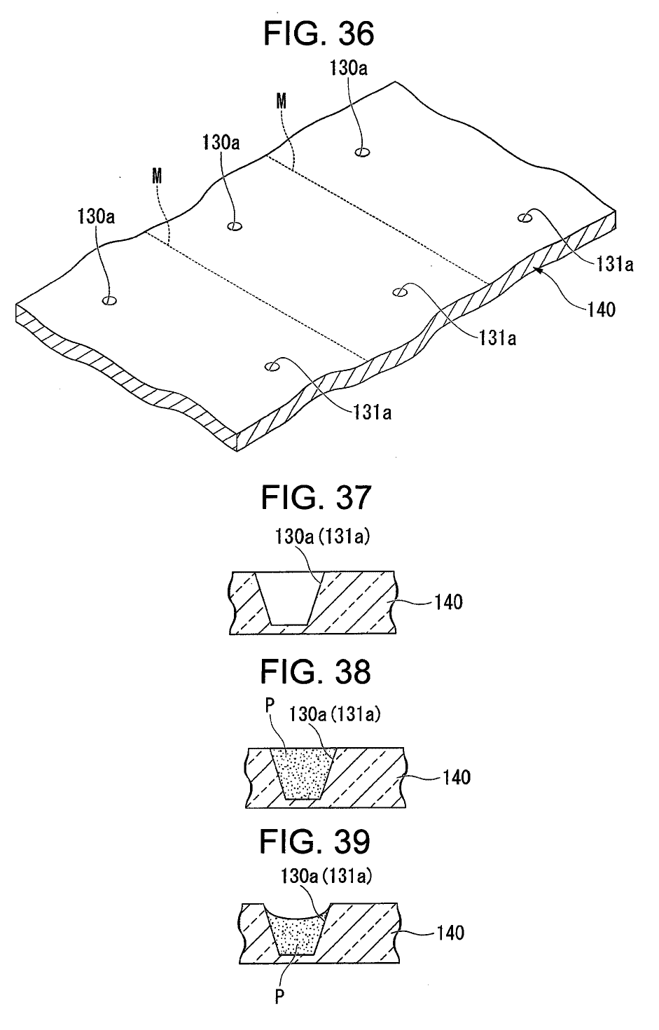

First, as shown in FIG. 36, a hole forming step (S132) is attained for forming a plurality of pairs of holes 130a and 131a in the upper face of the base substrate wafer 140. The dotted line M shown in FIG. 36 means a section line for cutting in the subsequent cutting step. In this step, the upper face of the base substrate wafer 140 is processed, for example, according to a sand-blasting method. Accordingly, as shown in FIG. 37, tapered holes 130a and 131a are formed, which are bottomed on the lower face side and of which the hole diameter of the cross section gradually decreases toward the lower face of the base substrate wafer 140. A plurality of pairs of holes 130a and 131a are so formed as to be housed in the recesses 103a formed in the lid substrate wafer 150, when the two wafers 140 and 150 are overlaid later. Further, they are so positioned that one hole 130a can be positioned on the side of the base 112 of the piezoelectric vibration member 104 and the other hole 131a can be on the top side of the vibration arms 110 and 111.

In this embodiment, an illustrative case is referred to, in which the hole diameter of the tapered holes decreases toward the lower face of the base substrate wafer 140; however, not limited to this case, the holes may have a uniform hole diameter. Anyhow, the bottomed holes may be any ones having a bottom on the lower face side of the base substrate wafer 140.

Subsequently, as shown in FIG. 38, a filling step is attained for implanting a paste P into these plural holes 130a and 131a with no space left therein to block up the holes 130a and 131a (S133). In FIG. 38 to FIG. 41, the metal fine particles P1 are not shown.

Subsequently, a firing step is attained for firing and hardening the filled paste P at a predetermined temperature (S134). Accordingly, the paste P is kept firmly fixing to the inner face of the holes 130a and 131a. Regarding the hardened paste P, the organic matter in the paste P (not shown) evaporates away during the firing, and therefore, the volume of the hardened paste decreases as compared with the volume thereof in the filling step as shown in FIG. 39. Accordingly, the surface of the paste P inevitably has depressions.

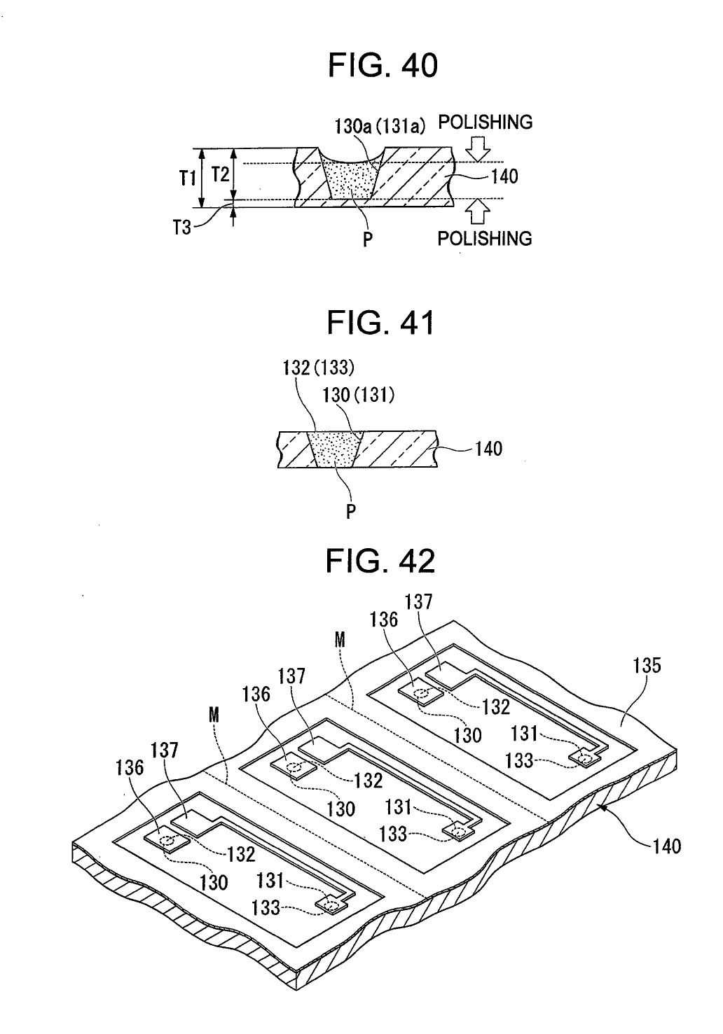

Therefore, after the firing, an upper face polishing step (S135) for polishing the upper face of the base substrate wafer 140 by a predetermined thickness is attained, as shown in FIG. 40. As a result of the step, on the upper face of the base substrate wafer 140, the paste P hardened by firing can also be polished simultaneously, and therefore the peripheries of the depressions can be cut off. In other words, the surface of the hardened paste P can be planarized. Accordingly, on the upper face of the base substrate wafer 140, the surface of the base substrate wafer 140 and the surface of the hardened paste P can be substantially in a flat condition, as shown in FIG. 41.

At the same time or in a timing of before or after the upper face polishing step, as shown in FIG. 40, a lower face polishing step is attained for polishing the lower face of the base substrate wafer 140 until the holes 130a and 131a run through the wafer and the hardened paste P is at least exposed out (S136). In the lower face polishing step in this embodiment, the polishing is attained until it reaches the bottom of the holes 130a and 131a. Accordingly, as shown in FIG. 41, the paste P hardened in the holes 130a and 131a is exposed out through the lower face. As a result of the lower face polishing step, the pair of holds 130a and 131a formed in the base substrate wafer 140 become, after this, through-holes 130 and 131 running through the base substrate wafer 140, and the hardened paste P becomes a pair of through-electrodes 132 and 133. In addition, on the lower face of the base substrate wafer 140, the surface of the base substrate wafer 140 can be substantially in a flat condition relative to the surface of the hardened paste P, like in the above-mentioned upper face polishing step.

After the upper face polishing step and the lower face polishing step, the through-electrode forming step is finished.

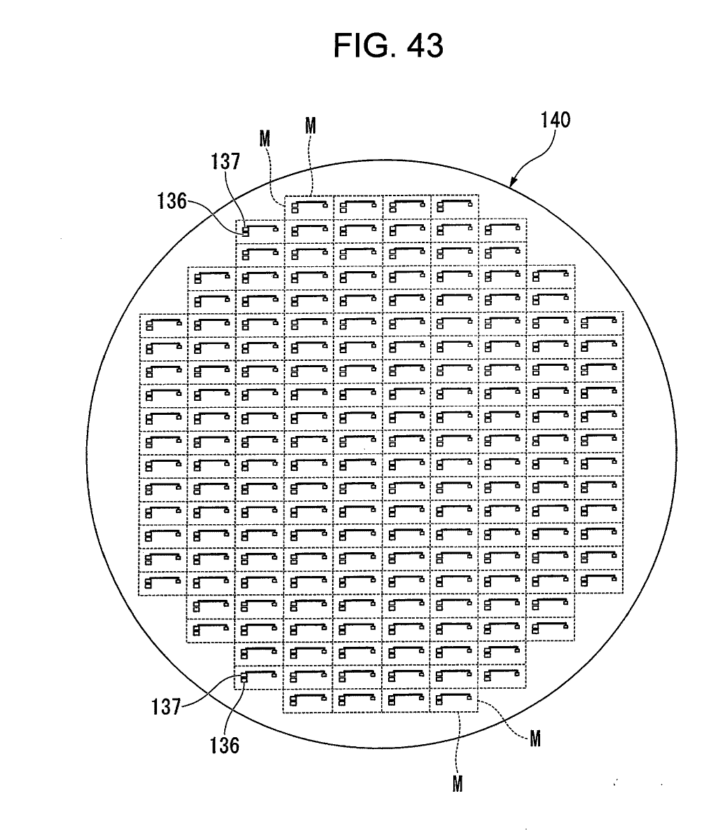

Next, a bonding film forming step is attained for forming a bonding film 135 by patterning an electroconductive material on the upper face of the base substrate wafer 140, as shown in FIG. 42 and FIG. 43 (S137); and at the same time, a routing electrode forming step is attained for forming a plurality of routing electrodes 136 and 137 connected electrically with the pair of through-electrodes 132 and 133 (S138). The dotted line M shown in FIG. 42 and FIG. 43 means a section line for cutting in the subsequent cutting step.

In particular, as so mentioned in the above, the through-electrodes 132 and 133 have no surface depressions and are substantially in a flat condition relative to the upper face of the base substrate wafer 140. Accordingly, the routing electrodes 136 and 137 as patterned on the upper face of the base substrate wafer 140 are kept in airtight contact with the through-electrodes 132 and 133 with no space therebetween. This secures the electric connection between one routing electrode 136 and one through-electrode 132 and the electric connection between the other routing electrode 137 and the other through-electrode 133. At this time, the second wafer forming step is finished.

In FIG. 34, the bonding film forming step (S137) is followed by the routing electrode forming step (S138) as the process sequence; however, in an opposite manner, the routing electrode forming step (S138) may be followed by the bonding film forming step (S137), or the two steps may be attained at the same time. In any process sequence, the same advantage and effect can be exhibited. Accordingly, the process sequence may be optionally changed or modified in any desired order.

Next, a mounting step is attained for bonding the formed, plural piezoelectric vibration members 104 onto the upper face of the base substrate wafer 140 via the routing electrodes 136 and 137 (S140). First, a bump B of gold or the like is formed on the pair of routing electrodes 136 and 137. After the base 112 of the piezoelectric vibration member 104 is put on the bump B, the piezoelectric vibration member 104 is pressed against the bump B while the bump B is heated at a predetermined temperature. Accordingly, the piezoelectric vibration member 104 is mechanically supported by the bump B, and the mount electrodes 116 and 117 are electrically connected with the routing electrodes 136 and 137. Therefore, at this time, the pair of excitation electrodes 115 of the piezoelectric vibration member 104 are electrically connected to the pair of through-electrodes 132 and 133, respectively.

In particular, the piezoelectric vibration member 104 is bump-bonded, and therefore it is supported as spaced above from the upper face of the base substrate wafer 140.

After the mounting of the piezoelectric vibration member 104 is finished, an overlaying step is attained for overlaying the base substrate wafer 140 and the lid substrate wafer 150 (S150). Concretely, the two wafers 140 and 150 are aligned in a correct position based on a reference mark or the like (not shown) as an index. Accordingly, the mounted piezoelectric vibration member 104 is kept housed in the cavity C surrounded by the recess 103a formed in the base substrate wafer 140 and the two wafers 140 and 150.

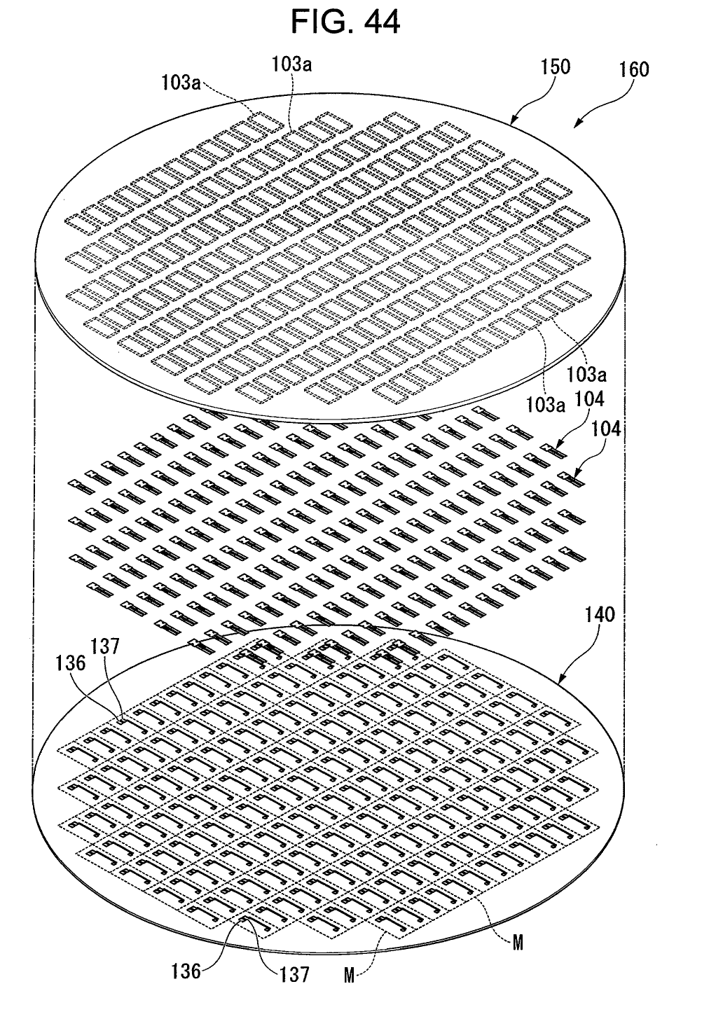

After the overlaying step, a bonding step is attained for anodically bonding the overlaid two wafers 140 and 150 by putting them in an anodic bonding apparatus (not shown) and applying a predetermined voltage thereto in a predetermined temperature atmosphere (S160). Concretely, a predetermined voltage is applied between the bonding film 135 and the lid substrate wafer 150. With that, there occurs electrochemical reaction in the interface between the bonding film 135 and the lid substrate wafer 150, whereby the two firmly stick to each other to attain anodic bonding therebetween. Accordingly, the piezoelectric vibration member 104 can be sealed up in the cavity C, and a wafer body 160 as shown in FIG. 44 can be obtained in which the base substrate wafer 140 and the lid substrate wafer 150 are bonded to each other. FIG. 44 illustrates an exploded state of the wafer body 160 for facilitating the understating of the view, in which the illustrative constitution of from the base substrate wafer 140 to the bonding film 135 is omitted. The dotted line M shown in FIG. 44 means a section line for cutting in the subsequent cutting step.

In anodic bonding, the through-holes 130 and 131 formed in the base substrate wafer 140 are completely blocked up by the through-electrodes 132 and 133, and therefore, the airtightness inside the cavity C is not broken by the through-holes 130 and 131. In particular, the paste P to constitute the through-electrodes 132 and 133 firmly sticks to the inner face of the through-holes 130 and 131, and therefore the airtightness inside the cavity C can be surely secured.

After the above-mentioned anodic bonding is finished, an external electrode forming step is attained for forming a plurality of pairs of external electrodes 138 and 139 electrically connected to the pairs of through-electrodes 132 and 133, respectively, by patterning an electroconductive material on the lower face of the base substrate wafer 140 (S170). As a result of this step, the piezoelectric vibration member 104 sealed up in the cavity C can be operated by utilizing the external electrodes 138 and 139.

In particular, also in attaining this step, the through-electrodes 132 and 133 are kept substantially in a flat condition relative to the lower face of the base substrate wafer 140, like in the case of forming the routing electrodes 136 and 137, and therefore the patterned external electrodes 138 and 139 can be kept in airtight contact with the through-electrodes 132 and 133 with no space therebetween. Accordingly, the electric connection between the external electrodes 138 and 139 with the through-electrodes 132 and 133 is secured.

Next, a fine-tuning step is attained for finely tuning the frequency of the individual piezoelectric vibrators 101 sealed up in the cavities C in the state of the wafer body 160 to make it fall within a predetermined range (S180). Concretely, a voltage is applied to the pair of external electrodes 138 and 139 formed on the lower face of the base substrate wafer 140 to thereby vibrate the piezoelectric vibration member 104. Then, with monitoring the frequency, this is irradiated with a laser light from the outside through the lid substrate wafer 150, to thereby evaporate the fine-tuning film 121b of the weight metal film 121. As a result, the weight of the top side of the pair of vibration arms 110 and 111 changes, and therefore the frequency of the piezoelectric vibration member 104 can be finely tuned so as to fall within a predetermined range of a nominal frequency.

After the fine-tuning of frequency is finished, a cutting step is attained for cutting the bonded wafer body 160 to thereby shred it into the individual pieces along the section line M shown in FIG. 44 (S190). As a result, a plurality of two-layer structure-type, surface-mount piezoelectric vibrators 101 as in FIG. 26 can be manufactured all at once, in which the piezoelectric vibration member 104 is sealed up in the cavity C formed between the base substrate 102 and the lid substrate 103 anodically bonded to each other.

The process sequence may be in an order of the cutting step (S190) of shredding into the individual piezoelectric vibrators 101 followed by the fine-tuning step (S180). However, as so mentioned in the above, in case where the fine-tuning step (S180) is attained previously, then the tuning can be effected in the state of the wafer body 160 and therefore a plurality of piezoelectric vibrators 101 can be finely tuned more efficiently. Accordingly, it is favorable as increasing the throughput.

After this, the internal electric characteristics are inspected (S195). Specifically, the piezoelectric vibration member 104 is checked for the resonance frequency, the resonance resistance, the drive level characteristic (excitation power dependence of the resonance frequency and the resonance resistance), etc. In addition, it is checked also for the insulation resistance characteristic, etc. Finally, the piezoelectric vibrator 101 is checked for the appearance thereof in point of the dimension and the quality, etc. With that, the manufacture of the piezoelectric vibrator 101 is finished.

In particular, in the piezoelectric vibrator 101 of this embodiment, the through-electrodes 132 and 133 can be formed substantially in a flat condition relative to the base substrate 102, not having surface depressions, and therefore the through-electrodes 132 and 133 can be surely kept in airtight contact with the routing electrodes 136 and 137 and the external electrodes 138 and 139. As a result, stable electric connection between the piezoelectric vibration member 104 with the external electrodes 138 and 139 can be secured, and the operation performance reliability of the piezoelectric vibrator can be enhanced and the quality thereof can be increased. Further, the airtightness inside the cavity C can be secured, and in this point, the quality of the device can be increased.

Further, in the lower face polishing step, the amount to be polished may be determined based on the thickness of the base substrate wafer 140 and the depth of the holes 130a and 131a, not depending on the volume of the paste P to be reduced in firing. In other words, as shown in FIG. 40, the amount to be polished, T3 can be readily determined from the thickness T1 of the base substrate wafer 140 and the depth T2 of the holes 130a and 131a. Accordingly, the lower face polishing step does not require confirming the condition of the paste P, and the lower face may be polished by a predetermined amount. Therefore, under-polishing or over-polishing may be prevented.

In addition, the through-electrodes 132 and 133 can be formed according to the simple method of using the paste P, and therefore, the process can be simplified. Further, since the bottomed holes 130a and 131a are used in implantation of the paste P therein, the operation of implanting the paste P is easy, and the process is simplified. In addition, there is no risk of wasting the paste P.

According to the manufacturing method of this embodiment, a plurality of the above-mentioned piezoelectric vibrators 101 can be manufactured all at once, and the manufacture cost can be reduced.

### Fourth Embodiment

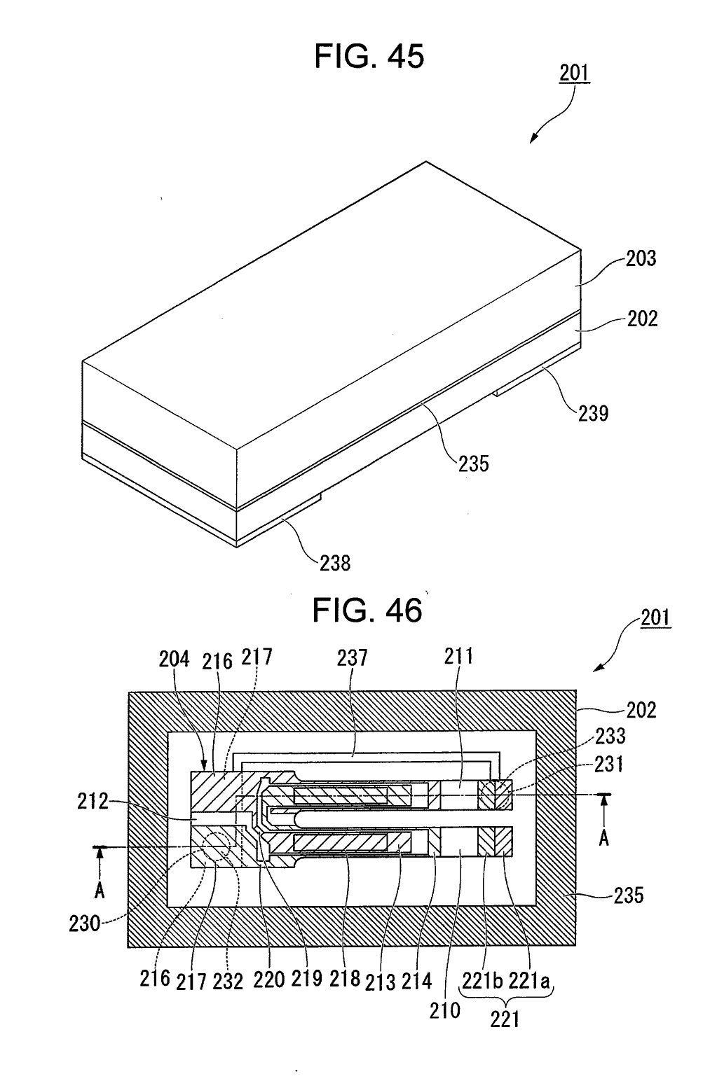

The fourth embodiment of the invention is described below with reference to FIG. 45 to FIG. 63.

The piezoelectric vibrator 201 of this embodiment is, as shown in FIG. 45 to FIG. 48, a surface-mount piezoelectric vibrator that is formed to have a two-layer laminate boxy shape composed of a base substrate 202 and a lid substrate 203, in which a piezoelectric vibration member 204 is housed in the cavity C inside it.

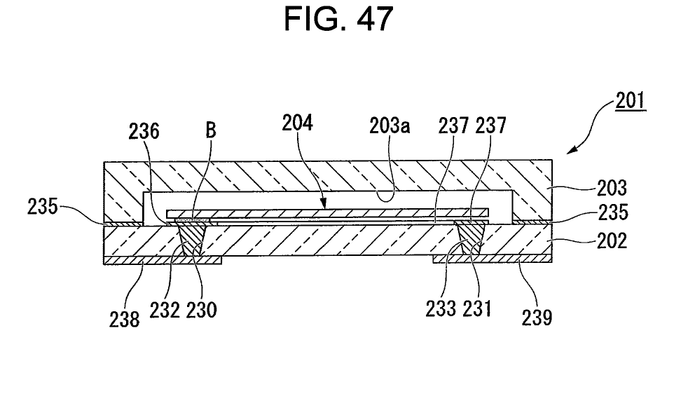

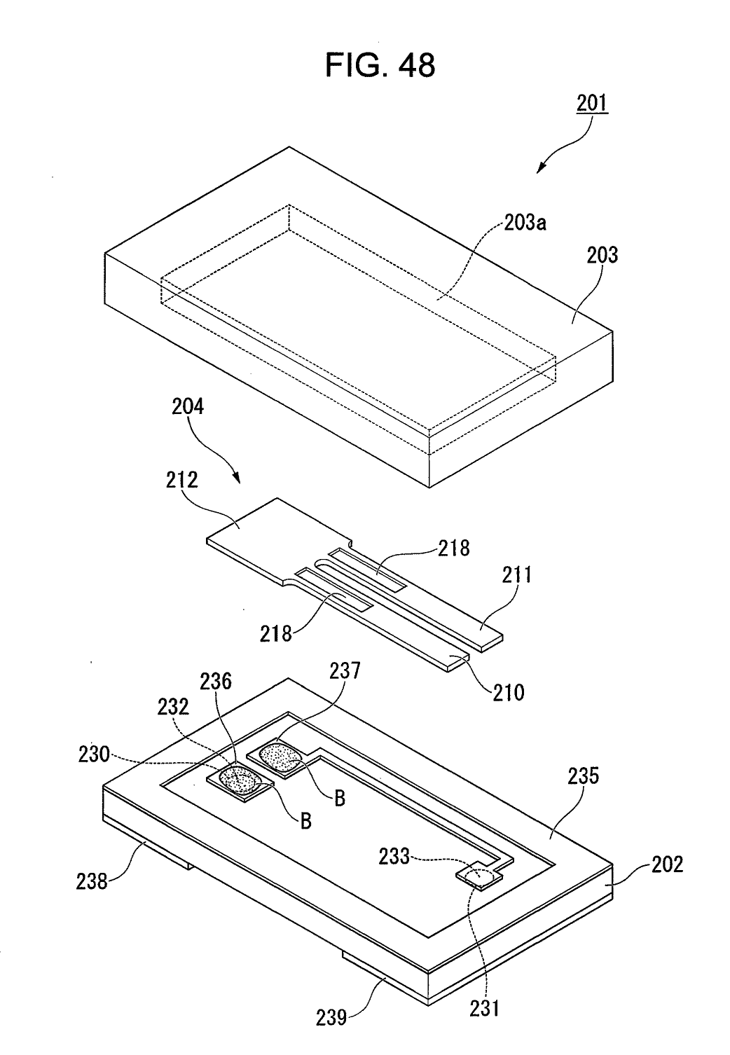

In FIG. 48, an excitation electrode 215, routing electrodes 219 and 220, mount electrodes 216 and 217, and a weight metal film 221 to be mentioned below are omitted for facilitating the understating of the view.

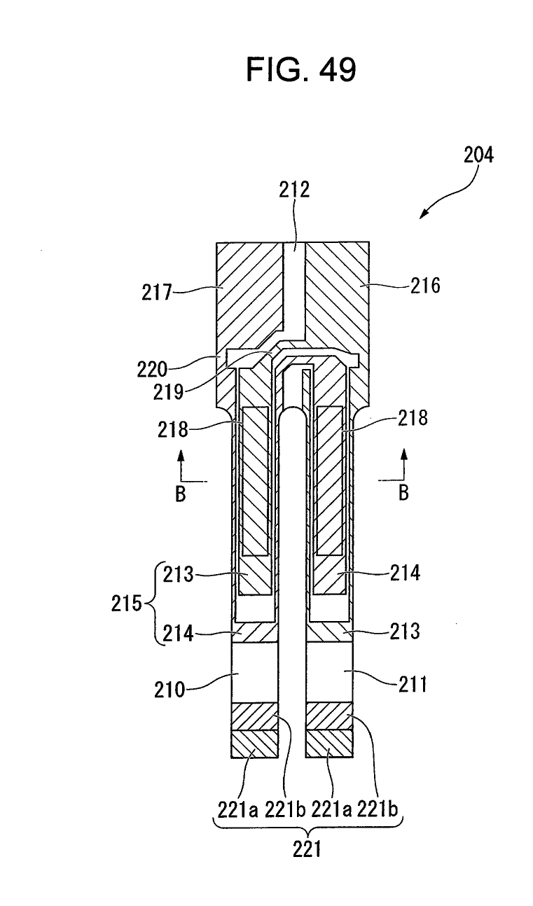

As shown in FIG. 49 to FIG. 51, the piezoelectric vibration member 204 is a tuning fork-like vibration member formed of a piezoelectric material such as crystal, lithium tantalate, lithium niobate or the like, and this vibrates when a predetermined voltage is applied thereto.

The piezoelectric vibration member 204 has a pair of vibration arms 210 and 211 disposed in parallel to each other, a base 212 to integrally fix the base side of the pair of vibration arms 210 and 211, an excitation electrode 215 composed of a first excitation electrode 213 and a second excitation electrode 214 for vibrating the pair of the vibration arms 210 and 211, as formed on the outer surface of the pair of the vibration arms 210 and 211, and mount electrodes 216 and 217 electrically connected with the first excitation electrode 213 and the second excitation electrode 214.

The piezoelectric vibration member 204 in this embodiment comprises, on both the two main faces of the pair of vibration arms 210 and 211, a groove 218 formed along the longitudinal direction of the vibration arms 210 and 211. The groove 218 is formed from the base side to around the intermediate part of the vibration arms 210 and 211.

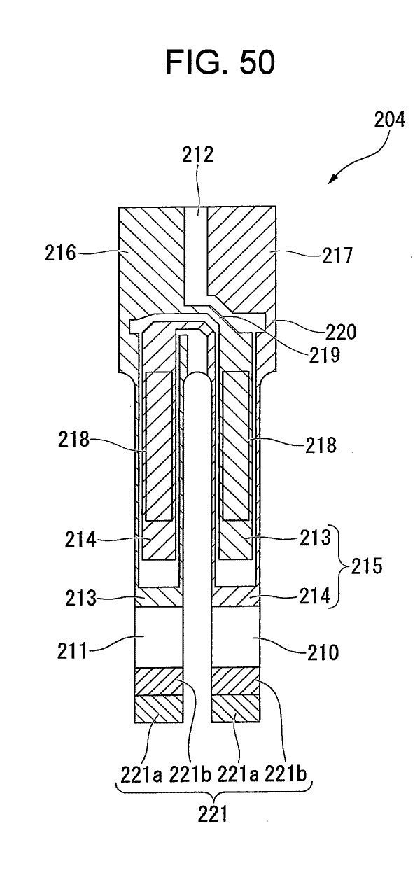

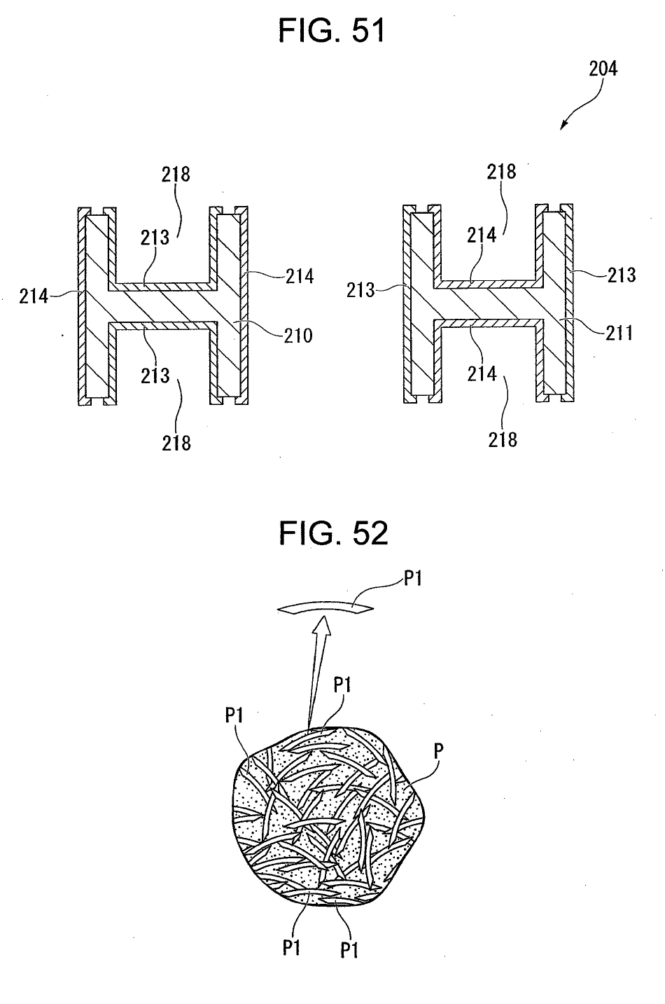

The excitation electrode 215 composed of the first excitation electrode 213 and the second excitation electrode 214 is an electrode to vibrate the pair of vibration arms 210 and 211 in the direction in which they come near to and get away from each other, at a predetermined resonance frequency, and this is patterned on the outer surface of the pair of vibration arms 210 and 211, as electrically insulated from each other. Concretely, as shown in FIG. 51, the first excitation electrode 213 is formed mainly on the groove 218 of one vibration arm 210 and on the two side faces of the other vibration arm 211; while the second excitation electrode 214 is formed mainly on the two side faces of one vibration arm 210 and on the groove 218 of the other vibration arm 211.

The first excitation electrode 213 and the second excitation electrode 214 are electrically connected to the mount electrodes 216 and 217 via the routing electrodes 219 and 220, respectively, on the two main faces of the base 212, as shown in FIG. 49 and FIG. 50. The piezoelectric vibration member 204 is given a voltage via the mount electrodes 216 and 217.

The above-mentioned excitation electrode 215, mount electrodes 216 and 217 and routing electrodes 219 and 220 are, for example, formed of a coating film of an electroconductive film of chromium (Cr), nickel (Ni), aluminum (Al), titanium (Ti) or the like.

The top of the pair of vibration arms 210 and 211 is coated with a weight metal film 221 for tuning the vibration condition of the arms themselves within a predetermined frequency range (frequency tuning). The weight metal film 221 is divided into two, a rough-tuning film 221a for use in roughly tuning the frequency and a fine-tuning film 221b for use in finely tuning it. With these rough-tuning film 221a and fine-tuning film 221b, the frequency is tuned, whereby the frequency of the pair of vibration arms 210 and 211 can be controlled to fall within a range of the nominal frequency of the device.

The thus-constituted piezoelectric vibration member 204 is, as shown in FIG. 46 and FIG. 48, bump-bonded to the upper face of the base substrate 202 with a bump B of gold or the like. More concretely, on the two bumps B formed on the routing electrodes 236 and 237 to be mentioned below, as patterned on the upper face of the base substrate 202, a pair of mount electrodes 216 and 217 are bump-bonded as kept in contact with each other. Accordingly, the piezoelectric vibration member 204 is supported as spaced above from the upper face of the base substrate 202, and the mount electrodes 216 and 217 are electrically connected to the routing electrodes 236 and 237, respectively.

The lid substrate 203 is a transparent insulating substrate formed of a glass material, for example, soda lime glass; and as shown in FIG. 45, FIG. 47 and FIG. 48, this is shaped to be tabular. On the bonding face side to which the base substrate 202 is bonded, formed is a rectangular recess 203a in which the piezoelectric vibration member 204 is housed. The recess 203a is a cavity recess to be a cavity C to house the piezoelectric vibration member 204 therein when the two substrates 202 and 203 are overlaid. The lid substrate 203 is anodically bonded to the base substrate 202 with the recess 203a kept facing the side of the base substrate 202.

The base substrate 202 is, like the lid substrate 203, a transparent insulating substrate formed of a glass substrate, for example, soda lime glass; and as shown in FIG. 45 to FIG. 48, this is formed to be tabular and have a size capable of being overlaid on the lid substrate 203.

The base substrate 202 is formed to have a pair of through-holes 230 and 231 in and through the base substrate 202. In this case, the pair of through-holes 230 and 231 are so formed as to be housed inside the cavity C. More precisely, the through-holes 230 and 231 in this embodiment are so formed that one through-hole 230 is positioned on the side of the base 212 of the mounted piezoelectric vibration member 204 and the other through-hole 231 is positioned on the top side of the vibration arms 210 and 211. In this embodiment, a tapered through-hole of which the diameter of the cross section gradually decreases toward the lower face of the base substrate 202 is described as one example; but not limited to this case, the through-hole may also be a straight through-hole that runs straightly through the base substrate 202. Anyhow, the through-hole may be any one that runs through the base substrate 202.

In the pair of through-holes 230 and 231, formed are a pair of through-electrodes 232 and 233 that fill up the through-holes 230 and 231. These through-electrodes 232 and 233 are, as shown in FIG. 52, formed by hardening of the paste P containing plural metal fine particles P1, and play a role of completely blocking up the through-holes 230 and 231 and keeping the airtightness inside the cavity C, and electrically connecting the external electrodes 238 and 239 with the routing electrodes 236 and 237 as described below.

The through-electrodes 232 and 233 secure the electroconductivity thereof as the plural metal fine particles P1 in the paste P are kept in contact with each other. The metal fine particles P1 in this embodiment are described with reference to a case where the particles are in the form of thin and long fibrous (non-spherical) particles of copper or the like.

On the upper face side of the base substrate 202 (the bonding face side thereof to which a lid substrate 203 is bonded), an anodic-bonding film 235 and a pair of routing electrodes 236 and 237 are patterned with an electroconductive material (for example, aluminum), as shown in FIG. 45 to FIG. 48. Of those, the bonding film 235 is formed along the peripheral edge of the base substrate 202 so as to surround the periphery of the recess 203a formed in the lid substrate 203.

The pair of routing electrodes 236 and 237 are so patterned as to electrically connect one through-hole 232 of the pair of through-holes 232 and 233, with one mount electrode 216 of the piezoelectric vibration member 204, and to electrically connect the other through-electrode 233 with the other mount electrode 217 of the piezoelectric vibration member 204. More precisely, one routing electrode 236 is formed just above one through-electrode 232 so as to be positioned just below the base 212 of the piezoelectric vibration member 204; and the other routing electrode 237 is so formed as to be positioned just above the other through-electrode 233 after drawn from the position adjacent to one routing electrode 236 to the top of the vibration arms 210 and 211 along the vibration arms 210 and 211.

A bump B is formed on the pair of routing electrodes 236 and 237, and via the bump B, the piezoelectric vibration member 204 is mounted. Accordingly, one mount electrode 216 of the piezoelectric vibration member 204 is electrically connected to one through-electrode 232 via one routing electrode 236, and the other mount electrode 217 is electrically connected to the other through-electrode 233 via the other routing electrode 237.

On the lower face of the base substrate 202, formed are external electrodes 238 and 239 to be electrically connected to the pair of through-electrodes 232 and 233, respectively, as shown in FIG. 45, FIG. 47 and FIG. 48. In other words, one external electrode 238 is electrically connected to the first excitation 213 of the piezoelectric vibration member 204 via one through-electrode 232 and one routing electrode 236. The other external electrode 239 is electrically connected to the second excitation electrode 214 of the piezoelectric vibration member 204 via the other through-electrode 233 and the other routing electrode 237.

To operate the thus-constituted piezoelectric vibrator 201, a predetermined driving voltage is applied to the external electrodes 238 and 239 formed on the base substrate 202. Accordingly, a current is applied to the excitation electrode 215 composed of the first excitation electrode 213 and the second excitation electrode 214 of the piezoelectric vibration member 204, whereby the pair of vibration arms 210 and 211 are vibrated at a predetermined frequency in the direction in which they come near to and get away from each other. Based on the vibration of the pair of vibration arms 210 and 211, the vibrator can be used as a time source, a timing source of control signals or the like, a reference signal source, etc.

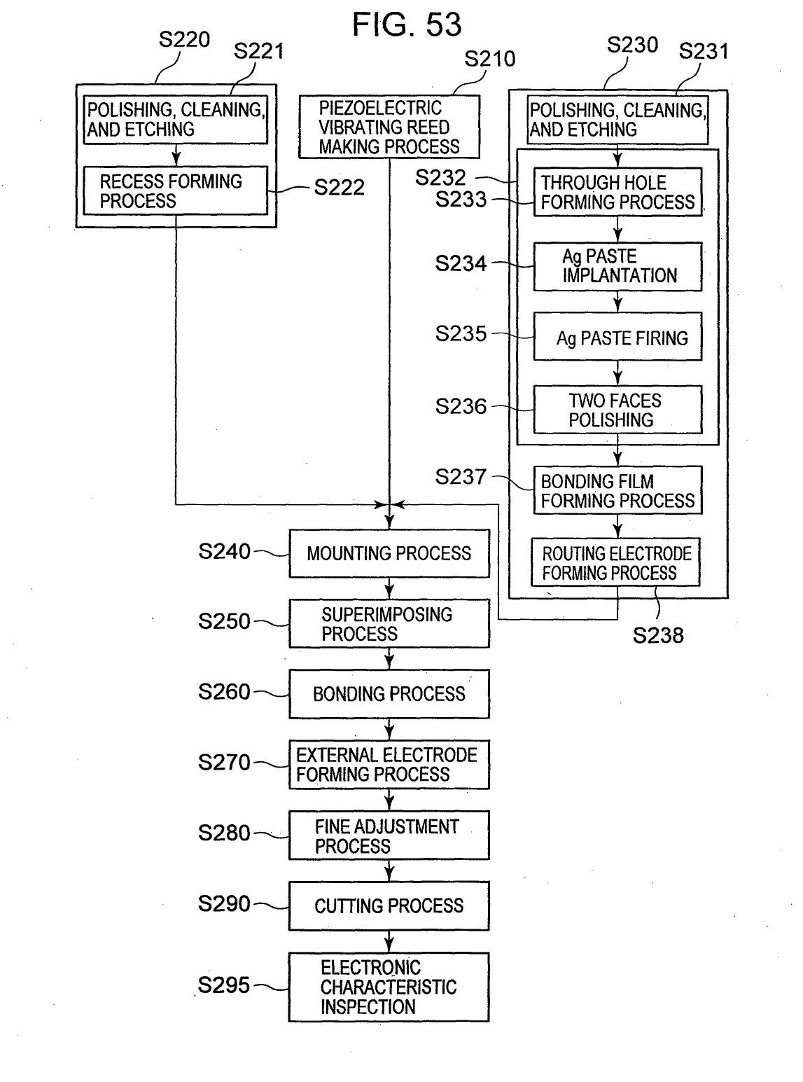

Next described is a method for manufacturing a plurality of piezoelectric vibrators 201 mentioned above all at once, by utilizing the base substrate wafer 240 and the lid substrate wafer 250, with reference to the flowchart shown in FIG. 53.

First, a piezoelectric vibration member forming step is attained to form the piezoelectric vibration member 204, as shown in FIG. 49 to FIG. 51 (S210). Concretely, first, a rough Lambertian quartz is sliced at a predetermined angle to give a wafer having a predetermined thickness. Subsequently, the wafer is roughly worked by lapping, then the work-affected layer is removed by etching, and thereafter this is mirror-finished by polishing or the like to give a wafer having a predetermined thickness. Subsequently, the wafer is suitably processed by washing or the like, and then the wafer is patterned into an external shape of the piezoelectric vibration member 204 through photolithography, and a metal film is formed and patterned to thereby form the excitation electrode 215, the routing electrodes 219 and 220, the mount electrodes 216 and 217, and the weight metal film 221. Accordingly, a plurality of piezoelectric vibration members 204 are formed.

After the piezoelectric vibration members 204 are formed, they are processed for rough-tuning of resonance frequency. This is attained by irradiating the rough-tuning film 221a of the weight metal film 221 with a laser light to partly evaporate it, thereby changing the weight thereof. Regarding the fine tuning for resonance frequency, the members are processed after mounting. This is described later.

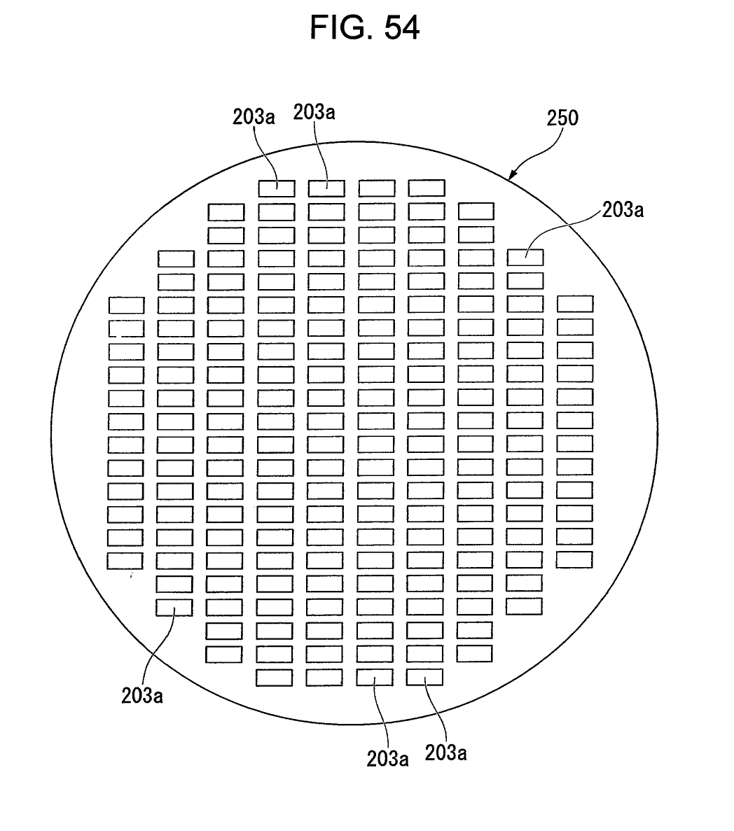

Next, a first wafer forming step is attained for forming a lid substrate wafer 250 to be the lid substrate 203 later up to the state just before anodic bonding (S220). First, soda lime glass is polished to have a predetermined thickness and washed, and then, as shown in FIG. 54, the work-affected layer of the outermost surface is removed by etching or the like to give a disc-like lid substrate wafer 250 (S221). Next, a recess forming step is attained for forming a plurality of cavity recesses 203a in the line direction by etching or the like in the bonding face of the lid substrate wafer 250 (S222). At this stage, the first wafer forming step is finished.

Next, at the same time or in a timing of before or after the above step, a second wafer forming step is attained for forming a base substrate wafer 240 to be the base substrate 202 later up to the state just before anodic bonding (S230). First, soda lime glass is polished to have a predetermined thickness and washed, and then, the work-affected layer of the outermost surface is removed by etching or the like to give a disc-like base substrate wafer 240 (S231). Next, a through-electrode forming step is attained for forming a plurality of pairs of through-electrodes 232 and 233 in the base substrate wafer 240 (S232). Here, the through-electrode forming step is described in detail.

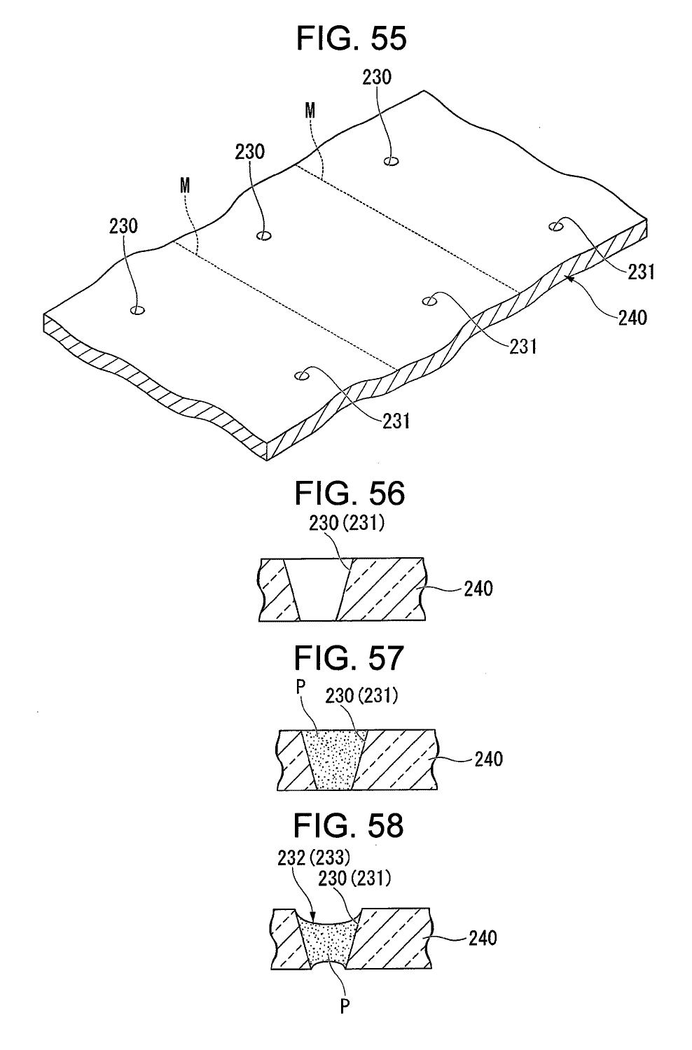

First, as shown in FIG. 55, a hole forming step (S233) is attained for forming a plurality of pairs of through-holes 230 and 231 in and through the base substrate wafer 240. The dotted line M shown in FIG. 55 means a section line for cutting in the subsequent cutting step. In this step, the upper face of the base substrate wafer 240 is processed, for example, according to a sand-blasting method. Accordingly, as shown in FIG. 56, tapered through-holes 230 and 231 are formed, of which the hole diameter of the cross section gradually decreases toward the lower face of the base substrate wafer 240. A plurality of pairs of through-holes 230 and 231 are so formed as to be housed in the recesses 203a formed in the lid substrate wafer 250, when the two wafers 240 and 250 are overlaid later. Further, they are so positioned that one through-hole 230 can be positioned on the side of the base 212 of the piezoelectric vibration member 204 and the other through-hole 231 can be on the top side of the vibration arms 210 and 211.

Subsequently, as shown in FIG. 57, a filling step is attained for implanting the paste P containing fine metal particles P1, into these plural through-holes 230 and 231 with no space left therein to block up the through-holes 230 and 231 (S234). In FIG. 57 to FIG. 60, the metal fine particles P1 are not shown.

Subsequently, a firing step is attained for firing and hardening the filled paste P at a predetermined temperature (S235). Accordingly, the paste P is kept firmly fixing to the inner face of the through-holes 230 and 231. Regarding the hardened paste P, the organic matter in the paste P (not shown) evaporates away during the firing, and therefore, the volume of the hardened paste decreases as compared with the volume thereof in the filling step as shown in FIG. 58. Accordingly, the surface of the paste P inevitably has depressions.

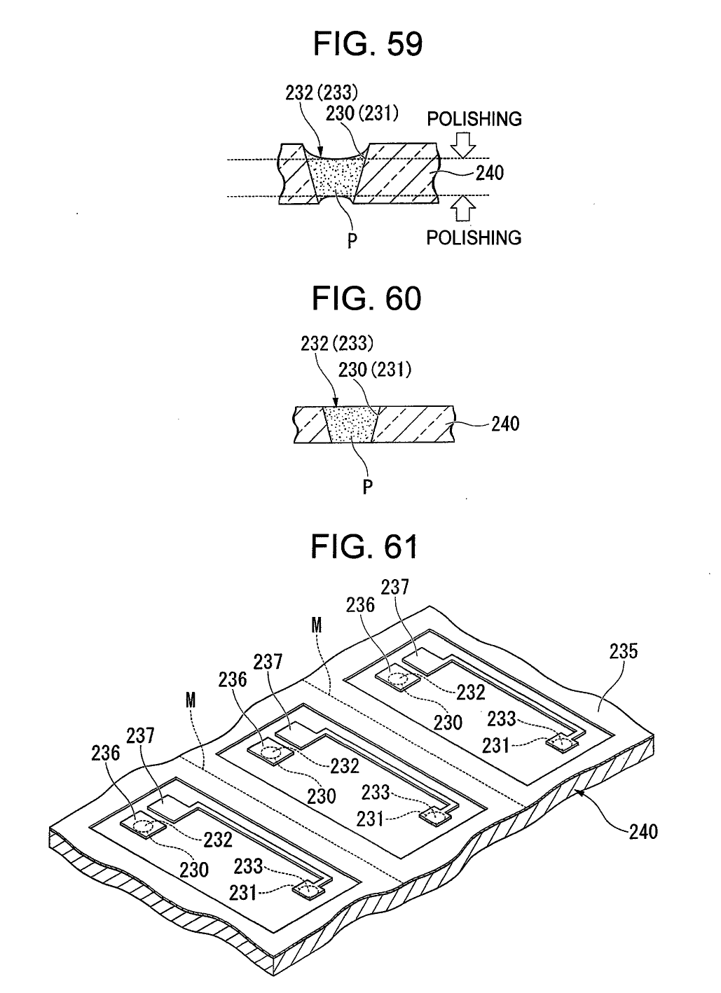

Therefore, after the firing, a polishing step (S236) for polishing the two faces of the base substrate wafer 240 each by a predetermined thickness is attained, as shown in FIG. 59. As a result of the step, the two faces of the paste P hardened by firing can be polished at the same time, and therefore, the peripheries of the depressions can be cut off. In other words, the surface of the hardened paste P can be planarized.

Accordingly, the surface of the base substrate wafer 240 and the surface of through-electrodes 232 and 233 can be substantially in a flat condition, as shown in FIG. 60. After the polishing step, the through-electrode forming step is finished.

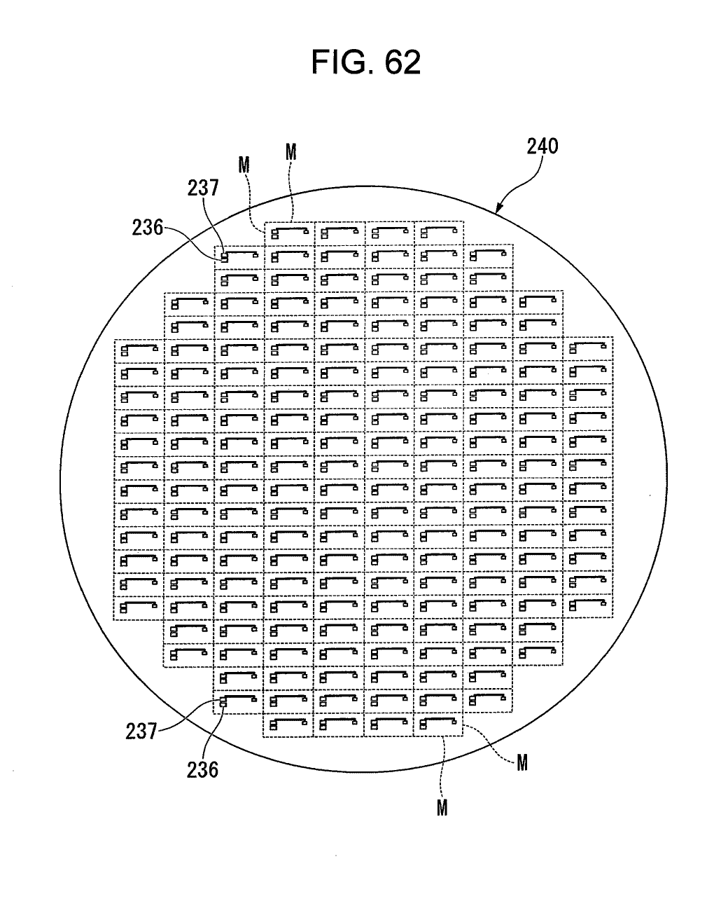

Next, a bonding film forming step is attained for forming a bonding film 235 by patterning an electroconductive material on the upper face of the base substrate wafer 240, as shown in FIG. 61 and FIG. 62 (S237); and at the same time, a routing electrode forming step is attained for forming a plurality of routing electrodes 236 and 237 connected electrically with the pair of through-electrodes 232 and 233 (S238). The dotted line M shown in FIG. 61 and FIG. 62 means a section line for cutting in the subsequent cutting step.

In particular, as so mentioned in the above, the through-electrodes 232 and 233 have no surface depressions and are substantially in a flat condition relative to the upper face of the base substrate wafer 240. Accordingly, the routing electrodes 236 and 237 as patterned on the upper face of the base substrate wafer 240 are kept in airtight contact with the through-electrodes 232 and 233 with no space therebetween. This secures the electric connection between one routing electrode 236 and one through-electrode 232 and the electric connection between the other routing electrode 237 and the other through-electrode 233. At this time, the second wafer forming step is finished.

In FIG. 53, the bonding film forming step (S237) is followed by the routing electrode forming step (S238) as the process sequence; however, in an opposite manner, the routing electrode forming step (S238) may be followed by the bonding film forming step (S237), or the two steps may be attained at the same time. In any process sequence, the same advantage and effect can be exhibited. Accordingly, the process sequence may be optionally changed or modified in any desired order.

Next, a mounting step is attained for bonding the formed, plural piezoelectric vibration members 204 onto the upper face of the base substrate wafer 240 via the routing electrodes 236 and 237 (S240). First, a bump B of gold or the like is formed on the pair of routing electrodes 236 and 237. After the base 212 of the piezoelectric vibration member 204 is put on the bump B, the piezoelectric vibration member 204 is pressed against the bump B while the bump B is heated at a predetermined temperature. Accordingly, the piezoelectric vibration member 204 is mechanically supported by the bump B, and the mount electrodes 216 and 217 are electrically connected with the routing electrodes 236 and 237. Therefore, at this time, the pair of excitation electrodes 215 of the piezoelectric vibration member 204 are electrically connected to the pair of through-electrodes 232 and 233, respectively.

In particular, the piezoelectric vibration member 204 is bump-bonded, and therefore it is supported as spaced above from the upper face of the base substrate wafer 240.

After the mounting of the piezoelectric vibration member 204 is finished, an overlaying step is attained for overlaying the base substrate wafer 240 and the lid substrate wafer 250 (S250). Concretely, the two wafers 240 and 250 are aligned in a correct position based on a reference mark or the like (not shown) as an index. Accordingly, the mounted piezoelectric vibration member 204 is kept housed in the cavity C surrounded by the recess 203a formed in the base substrate wafer 240 and the two wafers 240 and 250.

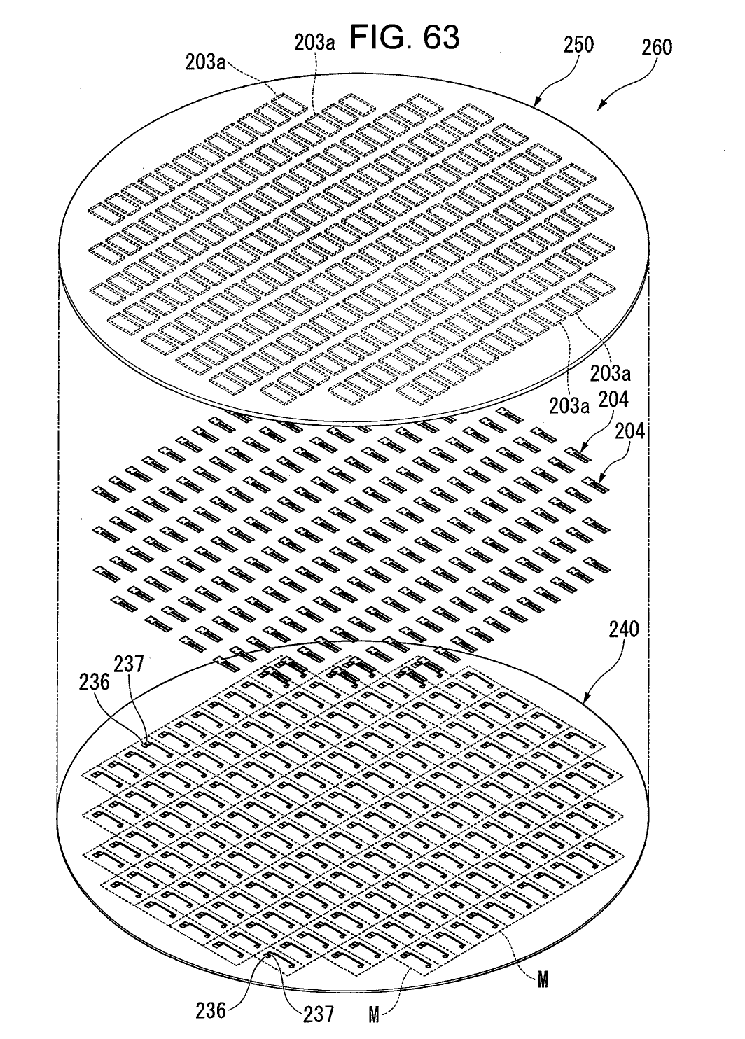

After the overlaying step, a bonding step is attained for anodically bonding the overlaid two wafers 240 and 250 by putting them in an anodic bonding apparatus (not shown) and applying a predetermined voltage thereto in a predetermined temperature atmosphere (S260). Concretely, a predetermined voltage is applied between the bonding film 235 and the lid substrate wafer 250. With that, there occurs electrochemical reaction in the interface between the bonding film 235 and the lid substrate wafer 250, whereby the two firmly stick to each other to attain anodic bonding therebetween. Accordingly, the piezoelectric vibration member 204 can be sealed up in the cavity C, and a wafer body 260 as shown in FIG. 63 can be obtained in which the base substrate wafer 240 and the lid substrate wafer 250 are bonded to each other. FIG. 63 illustrates an exploded state of the wafer body 260 for facilitating the understating of the view, in which the illustrative constitution of from the base substrate wafer 240 to the bonding film 235 is omitted. The dotted line M shown in FIG. 63 means a section line for cutting in the subsequent cutting step.

In anodic bonding, the through-holes 230 and 231 formed in the base substrate wafer 240 are completely blocked up by the through-electrodes 232 and 233, and therefore, the airtightness inside the cavity C is not broken by the through-holes 230 and 231. In particular, the paste P to constitute the through-electrodes 232 and 233 firmly sticks to the inner face of the through-holes 230 and 231, and therefore the airtightness inside the cavity C can be surely secured.

After the above-mentioned anodic bonding is finished, an external electrode forming step is attained for forming a plurality of pairs of external electrodes 238 and 239 electrically connected to the pairs of through-electrodes 232 and 233, respectively, by patterning an electroconductive material on the lower face of the base substrate wafer 240 (S270). As a result of this step, the piezoelectric vibration member 204 sealed up in the cavity C can be operated by utilizing the external electrodes 238 and 239.

In particular, also in attaining this step, the through-electrodes 232 and 233 are kept substantially in a flat condition relative to the lower face of the base substrate wafer 240, like in the case of forming the routing electrodes 236 and 237, and therefore the patterned external electrodes 238 and 239 can be kept in airtight contact with the through-electrodes 232 and 233 with no space therebetween. Accordingly, the electric connection between the external electrodes 238 and 239 with the through-electrodes 232 and 233 is secured.

Next, a fine-tuning step is attained for finely tuning the frequency of the individual piezoelectric vibrators 201 sealed up in the cavities C in the state of the wafer body 260 to make it fall within a predetermined range (S280). Concretely, a voltage is applied to the pair of external electrodes 238 and 239 formed on the lower face of the base substrate wafer 240 to thereby vibrate the piezoelectric vibration member 204. Then, with monitoring the frequency, this is irradiated with a laser light from the outside through the lid substrate wafer 250, to thereby evaporate the fine-tuning film 221b of the weight metal film 221. As a result, the weight of the top side of the pair of vibration arms 210 and 211 changes, and therefore the frequency of the piezoelectric vibration member 204 can be finely tuned so as to fall within a predetermined range of a nominal frequency.

After the fine-tuning of frequency is finished, a cutting step is attained for cutting the bonded wafer body 260 to thereby shred it into the individual pieces along the section line M shown in FIG. 63 (S290). As a result, a plurality of two-layer structure-type, surface-mount piezoelectric vibrators 201 as in FIG. 45 can be manufactured all at once, in which the piezoelectric vibration member 204 is sealed up in the cavity C formed between the base substrate 202 and the lid substrate 203 anodically bonded to each other.

The process sequence may be in an order of the cutting step (S290) of shredding into the individual piezoelectric vibrators 201 followed by the fine-tuning step (S280). However, as so mentioned in the above, in case where the fine-tuning step (S280) is attained previously, then the tuning can be effected in the state of the wafer body 260 and therefore a plurality of piezoelectric vibrators 201 can be finely tuned more efficiently. Accordingly, it is favorable as increasing the throughput.

After this, the internal electric characteristics are inspected (S295). Specifically, the piezoelectric vibration member 204 is checked for the resonance frequency, the resonance resistance, the drive level characteristic (excitation power dependence of the resonance frequency and the resonance resistance), etc. In addition, it is checked also for the insulation resistance characteristic, etc. Finally, the piezoelectric vibrator 201 is checked for the appearance thereof in point of the dimension and the quality, etc. With that, the manufacture of the piezoelectric vibrator 201 is finished.

In particular, in the piezoelectric vibrator 201 of this embodiment, the through-electrodes 232 and 233 can be formed substantially in a flat condition relative to the base substrate 202, not having surface depressions, and therefore the through-electrodes 232 and 233 can be surely kept in airtight contact with the routing electrodes 236 and 237 and the external electrodes 238 and 239. As a result, stable electric connection between the piezoelectric vibration member 204 with the external electrodes 238 and 239 can be secured, and the operation performance reliability of the piezoelectric vibrator can be enhanced and the quality thereof can be increased. Further, the airtightness inside the cavity C can be secured, and in this point, the quality of the device can be increased. In addition, the through-electrodes 232 and 233 can be formed according to the simple method of using the paste P, and therefore, the process can be simplified.

According to the manufacturing method of this embodiment, a plurality of the above-mentioned piezoelectric vibrators 201 can be manufactured all at once, and the manufacture cost can be reduced.

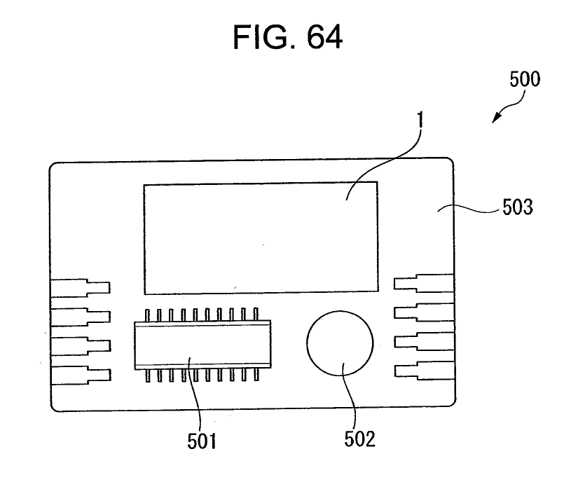

Next described is one embodiment of the oscillator of the invention, with reference to FIG. 64. In this embodiment, an example of an oscillator provided with the piezoelectric vibrator 1 of the first embodiment is described.

The oscillator 500 of this embodiment comprises the piezoelectric vibrator 1 electrically connected to an integrated circuit 501 to be an oscillation member therein, as shown in FIG. 64. The oscillator 500 is provided with a substrate 503 on which an electronic part 502 such as a capacitor or the like is mounted. On the substrate 503, mounted is the above-mentioned integrated circuit 501 for oscillator, and in the vicinity of the integrated circuit 501, the piezoelectric vibrator 1 is mounted thereon. These electronic part 502, integrated circuit 501 and piezoelectric vibrator 1 are electrically connected to each other with a wiring pattern (not shown). The constitutive parts each are molded with a resin (not shown).

In the thus-constituted oscillator 500, when a voltage is applied to the piezoelectric vibrator 1, then the piezoelectric vibration member 4 in the piezoelectric vibrator 1 is vibrated. The vibration is converted into an electric signal owing to the piezoelectric characteristic that the piezoelectric vibration member 4 has, and the electric signal is inputted into the integrated circuit 501. The thus-inputted electric signal is processed variously in the integrated circuit 501, and is outputted as a frequency signal. Accordingly, the piezoelectric vibrator 1 functions as an oscillation member.

In case where the integrated circuit 501 is, for example, so constituted that an RTC (real time clock) module or the like is defined therein selectively on demand, then the oscillator may act as a single-function oscillator for clocks or the like, or a function of controlling the operation date or time of the device or its external devices or providing a time, a calendar or the like may be added to the oscillator.

The oscillator 500 of this embodiment comprises the high-quality piezoelectric vibrator 1, in which the airtightness inside the cavity C is secured and of which the operation reliability has been improved, and therefore, the operation reliability of the oscillator 500 itself can also be enhanced and the quality thereof can be increased. In addition, the oscillator may give stable and precision frequency signals for a long period of time.

An example comprising the piezoelectric vibrator 1 of the first embodiment is described in the above; however, the piezoelectric vibrators of the other embodiments can also exhibit the same advantage and effect.

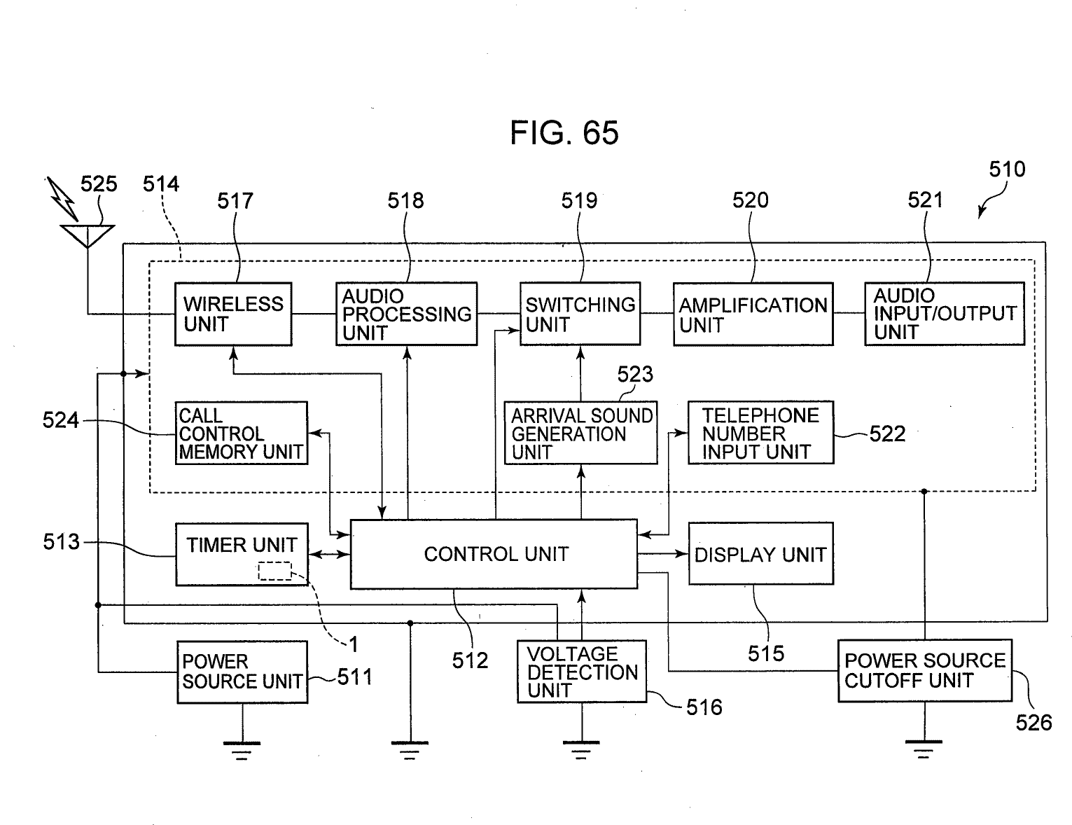

Next described is one embodiment of the electronic device of the invention, with reference to FIG. 65. As the electronic device, a portable information device 110 having the above-mentioned piezoelectric vibrator 1 of the first embodiment is illustrated below.

First, the portable information device 510 of this embodiment is, for example, typically a portable telephone, which is developed and improved from a prior-art wristwatch. Its appearance is similar to a wristwatch, and a liquid-crystal display is disposed in the part corresponding to the dial plate, and the current time or the like can be displayed on the panel. In case where it is utilized as a communication device, then it is taken off from the wrist, and via the speaker or the microphone built in the inside part of the band, communication can be attained like in the case of prior-art portable telephones. However, as compared with conventional portable telephones, the device of the invention is remarkably down-sized and weight-saved.

Next described is the constitution of the portable information device 510 of this embodiment. The portable information device 510 is provided with the piezoelectric vibrator 1 and a power source part 511 for power supply, as shown in FIG. 65. The power source part 511 comprises, for example, a lithium secondary battery. To the power source part 511, connected are a control part 512 for various control, a timer part 513 for counting time and the like, a communication part 514 for external communication, a display part 515 for displaying various information, and an voltage detection part 516 for detecting the voltage of the individual functional parts, all in parallel to each other. Via the power source part 511, power is supplied to the respective functional parts.

The control part 512 controls the individual functional parts, transmits and receives voice data, and counts and displays the current time, therefore controlling the operation of the entire system. The control part 512 is provided with ROM where a program is previously written, CPU for reading out the program written in ROM and executing it, and RAM to be used as a work area of CPU, etc.

The timer part 513 is provided with an integrated circuit that comprises an oscillation circuit, a register circuit, a counter circuit, an interface circuit and the like all built therein, and the piezoelectric vibrator 1. When a voltage is applied to the piezoelectric vibrator 1, then the piezoelectric vibration member 4 is vibrated and the vibration is converted into an electric signal owing to the piezoelectric characteristic that the quartz crystal has, and the electric signal is inputted into the oscillation circuit. The output from the oscillation circuit is binarized and counted by the resistor circuit and the counter circuit. Then, two-way signal transmission to the control part 512 is attained via the interface circuit, and the current time, the current date, the calendar information and the like are displayed in the display part 515.

The communication part 514 has the same function as that of a conventional portable telephone, and is provided with a wireless part 517, a voice processing part 518, a switch part 519, an amplification part 520, a voice input/output part 521, a telephone number input part 522, a ring alert generation part 523, and a call control memory part 524.

The wireless part 517 undergoes two-way transmission of various data such as voice data and the like to the base station via an antenna 525. The voice processing part 518 codes and decodes the voice signal inputted from the wireless part 517 or the amplification part 520. The amplification part 520 amplifies the signal inputted from the voice processing part 518 or the voice input/output part 521 up to a predetermined level. The voice input/output part 521 comprises a speaker, a microphone or the like, and this amplifies the ring alert or the received voice, or collects the voice.

The ring alert generation part 523 generates a ring alert in accordance with the call from the base station. The switch part 519 turns the amplification part 520 connected to the sound processing part 518 to the ring alert generation part 523 only in calling whereby the ring alert generated in the ring alert generation part 523 is outputted to the voice input/output part 521 via the amplification part 520.

The call control memory part 524 houses a program relating to communication incoming/outgoing call control. The telephone number input part 522 is provided with number keys of, for example, from 0 to 9 and other keys, and by pushing these number keys and others, the calling telephone number or the like is inputted.

The voltage detection part 516 detects the voltage depression and notifies it to the control part 512, when the voltage applied to the various functional parts such as the control part 512 and others from the power source part 511 has fallen below the predetermined level. The predetermined voltage is a value previously set as the minimum voltage necessary for stable operation of the communication part 514, and is, for example, around 3 V. The control part 512 that has received the notice of voltage depression from the voltage detection part 516 inhibits the operation of the wireless part 517, the voice processing part 518, the switch part 519 and the ring alert generation part 523. In particular, the operation stopping of the wireless part 517 that consumes much power is indispensable. Further, the display part 515 displays the unavailability of the communication part 514 owing to the shortage of the battery residue.

Specifically, the voltage detection part 516 and the control part 512 inhibit the operation of the communication part 514, which may be displayed on the display part 515. The display may be a letter message, or for more intuitive expression, a mark (x) (unavailability mark) may be given to the telephone icon to be displayed in the upper part of the display panel of the display part 515.

A power shutdown part 526 capable of selectively shutting down the power relating to the function of the communication part 514 may be provided whereby the function of the communication part 514 may be more surely stopped.

The portable information device 510 of this embodiment comprises the high-quality piezoelectric vibrator 1, in which the airtightness inside the cavity C is secured and of which the operation reliability has been improved, and therefore, the operation reliability of the portable information device itself can also be enhanced and the quality thereof can be increased. In addition, the device can exhibit stable and precision time information for a long period of time.

An example comprising the piezoelectric vibrator 1 of the first embodiment is described in the above; however, the piezoelectric vibrators of the other embodiments can also exhibit the same advantage and effect.

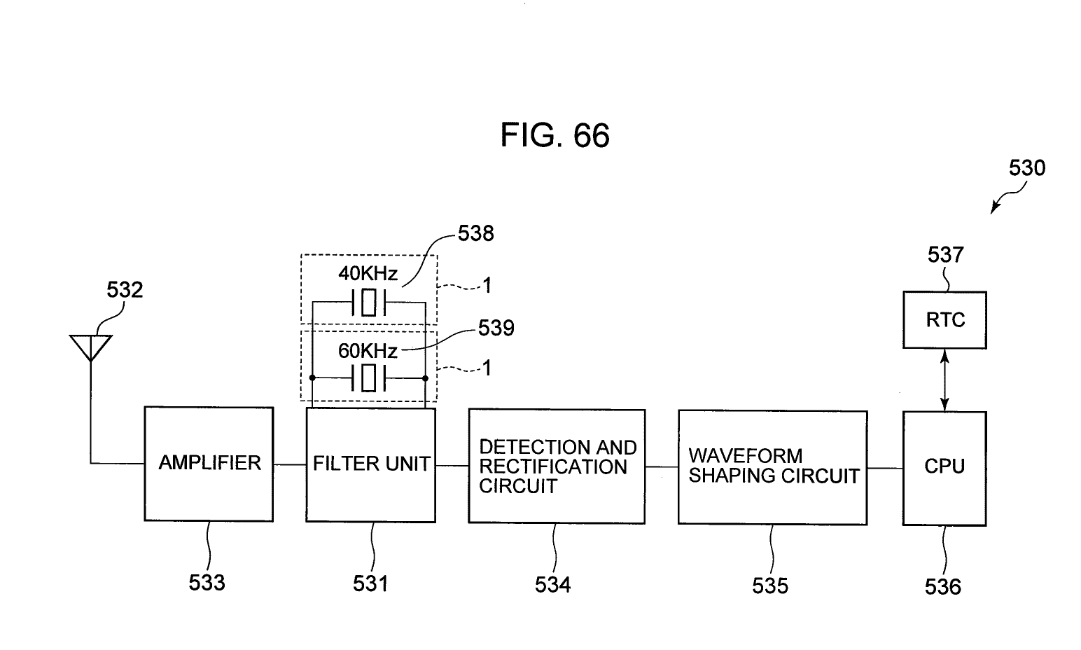

Next described is one embodiment of the radio-controlled watch of the invention, with reference to FIG. 66. In this embodiment, an example of a radio-controlled watch comprising the piezoelectric vibrator 1 of the first embodiment is described.

The radio-controlled watch 530 of this embodiment comprises the piezoelectric vibrator 1 electrically connected to a filter part 531, as shown in FIG. 66, and this is a watch having the function of receiving standard waves that include time information, automatically correcting it to a correct time and displaying the time.

In Japan, there are transmitter stations for transmitting standard waves in Fukushima prefecture (40 kHz) and Saga prefecture (60 kHz), and they transmit standard waves. The long wave of 40 kHz or 60 kHz has both the property or passing on the land surface and the property of reflecting on the ionosphere and the land surface and passing thereon; and therefore, its passing region is broad, and the above-mentioned two transmitter stations cover everywhere in Japan.

The details of the functional constitution of the radio-controlled watch 530 are described below.

The antenna 532 receives a long standard wave of 40 kHz or 60 kHz. For the long standard wave, a carrier wave of 40 kHz or 60 kHz is processed for AM modulation with a time information referred to as a time code. The received long standard wave is amplified by the amplifier 533, and filtered and synchronized by the filter part 531 paving a plurality of piezoelectric vibrators 1.

The piezoelectric vibrators 1 in this embodiment each are provided with a quartz crystal vibration member 538 or 539 having the same resonance frequency of 40 kHz or 60 kHz as the above-mentioned carrier frequency.

Further, the filtered signal having a predetermined frequency is detected and demodulated by the detection/rectification circuit 534. Subsequently, via the waveform shaper circuit 535, the time code is taken out, and counted in CPU 536. In CPU 536, information such as the current year, the accumulated date, the week day, the time and the like is read out. The read-out information is reflected by RTC 537, and the accurate time information is thereby displayed.

The carrier wave is 40 kHz or 60 kHz, and therefore, the quartz crystal vibration members 538 and 539 are preferably the above-mentioned, tuning fork-like vibrators.

The above explanation is for an example in Japan; however, the frequency of the long standard wave differs in foreign countries. For example, in Germany, a standard wave of 77.5 kHz is employed. Accordingly, in case where a radio-controlled watch 530 applicable to foreign use is built in a portable device, it further requires the piezoelectric vibrator 1 of which the frequency differs from that in Japan.

The radio-controlled watch 530 of this embodiment comprises the high-quality piezoelectric vibrator 1, in which the airtightness inside the cavity C is secured and of which the operation reliability has been improved, and therefore, the operation reliability of the radio-controlled watch itself can also be enhanced and the quality thereof can be increased. In addition, the watch can count time stably with accuracy for a long period of time.

An example comprising the piezoelectric vibrator 1 of the first embodiment is described in the above; however, the piezoelectric vibrators of the other embodiments can also exhibit the same advantage and effect.

The technical scope of the invention is not limited to the above-mentioned embodiments, and various changes may be given thereto not overstepping the scope and the spirit of the invention.

For example, in the above-mentioned embodiments, an example of a grooved piezoelectric vibration member having a groove formed in both faces of the vibration arms is illustrated as one example of the piezoelectric vibration member; however, a piezoelectric vibration member not having the groove may also be employed herein. However, forming the groove may increase the field effect efficiency between a pair of excitation electrodes when a predetermined voltage is applied to the pair of excitation electrodes, and therefore the vibration loss may be reduced and the vibration characteristics may be further enhanced. In other words, the CI value (crystal impedance) may be further reduced, and the performance of the piezoelectric vibration member can be further enhanced. In this respect, forming the groove is preferred.

In the above-mentioned embodiments, an example of a tuning folk-type piezoelectric vibration member is illustrated; however, the vibration member is not limited to the tuning folk-type one. For example, it may be a thickness-shear vibration member.

In the above-mentioned embodiments, the base substrate and the lid substrate are anodically bonded via a bonding film; but the bonding mode is not limited to anodic bonding. However, anodic bonding is preferred as capable of firmly bonding the two substrates.

In the above-mentioned embodiments, the piezoelectric vibration member is bump-bonded, but the bonding mode is not limited to bump-bonding. For example, the piezoelectric vibration member may be bonded with an electroconductive adhesive. However, bump-bonding makes it possible to space the piezoelectric vibration member from the upper face of the base substrate, and naturally ensures the minimum vibration gap necessary for vibration. Accordingly, bump-bonding is preferred.

In the above-mentioned embodiments, the through-holes are formed to have a pair of through-electrodes; however, the number of the through-electrode formed in the manner as above may be one, or may be 3 or more.

In the filling step in the above-mentioned embodiments, the paste may be defoamed (for example, by centrifugal defoaming or vacuuming), and then the paste may be implanted. Through the pre-defoaming treatment of the paste, the paste containing few bubbles may be implanted. Accordingly, the reduction in the volume of the paste in the firing step may be reduced as much as possible. Therefore, the amount to be polished later may be reduced, and the time for polishing may be reduced, thereby enabling more efficient manufacture of piezoelectric vibrators.

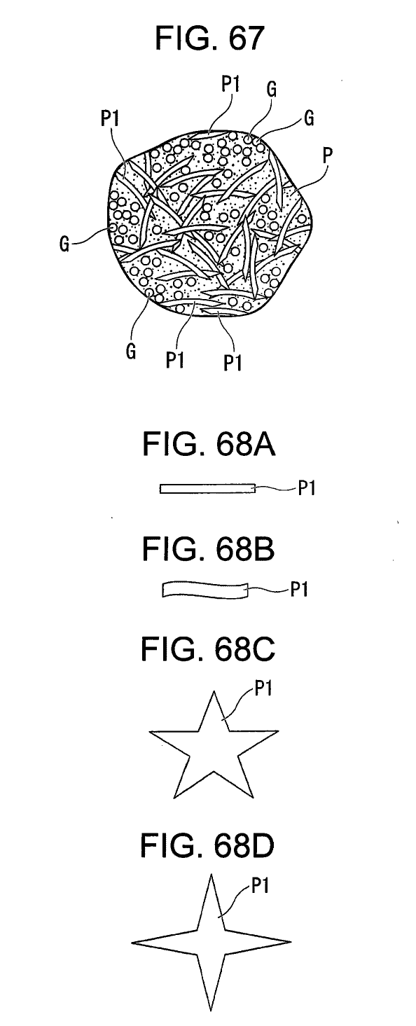

In the above-mentioned embodiments, a paste P mixed with a glass frit (granular material) G having the same thermal expansion coefficient as that of the base substrate (base substrate wafer) may be used, as shown in FIG. 67. In that manner, the thermal expansion of the paste P can be near to the thermal expansion of the base substrate wafer in firing. Accordingly, there hardly occurs a space between the two owing to the difference in the thermal expansion therebetween, and the two can be kept in more tight contact with each other. As a result, the airtightness in the through-electrodes formed may be increased more, and the long-term airtightness reliability can be enhanced. The proportion of the glass frit G to be mixed is preferably as large as possible within a range not detracting from the electroconductivity of the metal fine particles P1.

In the above-mentioned embodiments, a paste containing thin and long fibrous metal fine particles is used as one example; however, the shape of the metal fine particles may be any other one. For example, they may be spherical. Also in this case, when the metal fine particles are brought into contact with each other, they may be in a point contact state and can therefore also secure the electric conductivity. However, in case where thin and long fibrous, non-spherical metal fine particles are used, then they may be readily in a linear contact state but not in a point contact stage when they are brought into contact with each other. Accordingly, preferred is use of the paste containing non-spherical metal fine particles rather than spherical ones, as more readily increasing the electric conductivity of the through-electrodes.

In case where the metal fine particles P1 are non-spherical, for example, they may be strip-like ones as shown in FIG. 68A, or may be waved ones as shown in FIG. 68B, or may be those having a star-shaped cross section as shown in FIG. 68C, or may be those having a crisscross section as shown in FIG. 68D.

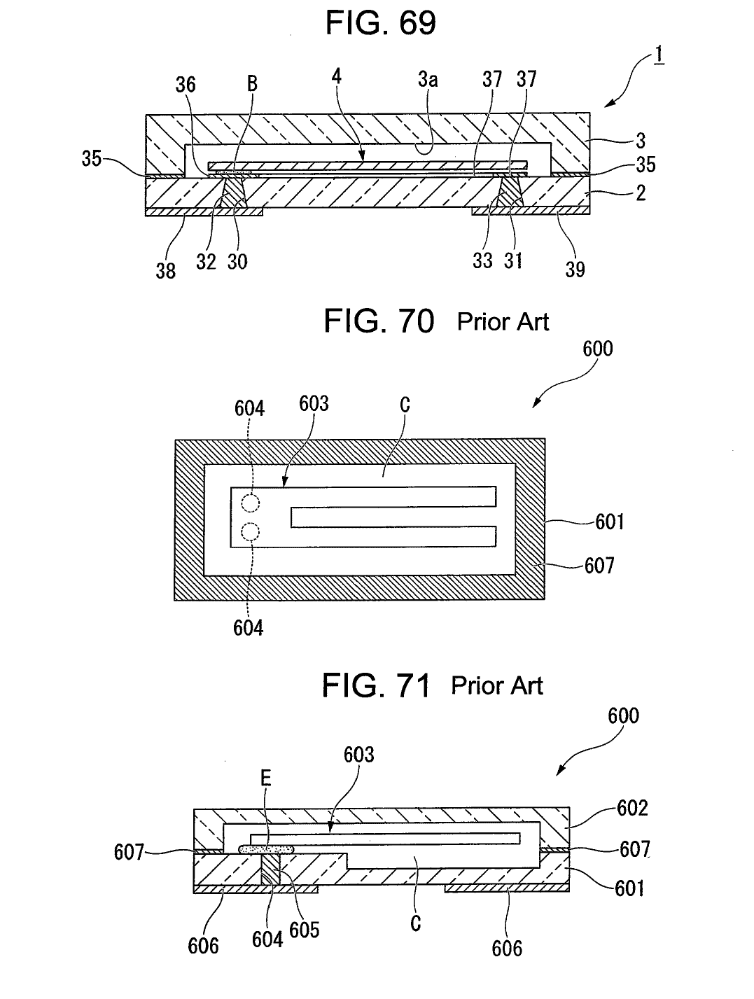

In the above-mentioned embodiments, the through-electrodes are so designed that their diameter gradually increases toward the external electrodes; but on the contrary, the through-electrodes 32 and 33 may be provided of which the diameter gradually decreases toward the external electrodes 38 and 39, as shown in FIG. 69. This case also exhibits the same effect and advantage.

In the above-mentioned first and second embodiments, the lower face of the base substrate wafer is polished until it reaches the bottom of the holding holes in the lower face polishing step; however, not limited to the case, the base substrate wafer may be polished to a further upper face side thereof.

In the holding hole forming step in the above-mentioned first and second embodiments, the holding holes are formed to be bottomed holes, of which the bottom is on the lower face side of the base substrate wafer; however, they may have any other shape. For example, they may be through-holes formed in the thickness direction of the base substrate wafer. However, in this case, the amount to be polished in the lower face polishing step may be varied depending on the paste volume reduction in firing, and in addition, in the filling step, the paste implantation operation is troublesome; and therefore, the holding holes are preferably bottomed holes.

In the above-mentioned third embodiment, the lower face of the base substrate wafer is polished to the position that reaches the bottom of the hole in the lower face polishing step; however, not limited to the case, the wafer may be polished to the polishing level, T3 or more.

What is claimed is:

1. A method for manufacturing a plurality of piezoelectric vibrators in which a piezoelectric vibration member is sealed up in a cavity formed between a base substrate and a lid substrate bonded to each other, all at once by utilizing a base substrate wafer and a lid substrate wafer, the method comprising:
a recess forming step of forming, in the lid substrate wafer, a plurality of cavity recesses for forming cavities when the two wafers are overlaid;
a through-electrode forming step of forming a plurality of through-electrodes in and through the base substrate wafer by utilizing a paste containing a plurality of metal fine particles;
a routing electrode forming step of forming a plurality of routing electrodes connected electrically with the through-electrodes, on the upper face of the base substrate wafer;
a mounting step of bonding the plural piezoelectric vibration members to the upper face of the base substrate wafer via the routing electrodes;
an overlaying step of overlaying the base substrate wafer and the lid substrate wafer thereby to house the piezoelectric vibration members in the cavities surrounded by the recesses and the two wafers;
a bonding step of bonding the base substrate wafer and the lid substrate wafer thereby to seal up the piezoelectric vibration members in the cavities;
an external electrode forming step of forming a plurality of external electrodes connected electrically with the through-electrodes, on the lower face of the base substrate wafer; and
a cutting step of cutting the two bonded wafers thereby to shred them into the plural piezoelectric vibrators;
wherein the through-electrode forming step includes a holding hole forming step of forming a plurality of holding holes for holding the paste, in the base substrate water; a filling step of implanting the paste in the plural holding holes to block up the holding holes; a firing step of pre-firing the implanted paste and finally firing and hardening it; and a polishing step of, after the pre-firing or the final firing, polishing the two faces of the base substrate wafer by a predetermined thickness;
and in case where the polishing step is attained after the final firing, the pre-fired paste is supplemented with a fresh paste in an amount corresponding to the paste amount reduced by the pre-firing, in the firing step, and thereafter the entire paste is again pre-fired and then finally fired.

2. The method for manufacturing piezoelectric vibrators as claimed in claim 1,
wherein the paste is defoamed and then implanted in the holding hole.

3. The method for manufacturing piezoelectric vibrators as claimed in claim 1,
wherein in the holding hole forming step, the holding hole is formed to be a bottomed hole from the upper face side of the base substrate wafer;
and the polishing step includes an upper face polishing step of polishing the upper face of the base substrate wafer by a predetermined thickness; and a lower face polishing step of polishing the lower face of the base substrate wafer until the holding hole runs through the wafer and the hardened paste is at least exposed out.

4. A method for manufacturing a plurality of piezoelectric vibrators in which a piezoelectric vibration member is sealed up in a cavity formed between a base substrate and a lid substrate bonded to each other, all at once by utilizing a base substrate wafer and a lid substrate wafer, the method comprising:
a recess forming step of forming, in the lid substrate wafer, a plurality of cavity recesses for forming cavities when the two wafers are overlaid;
a through-electrode forming step of forming a plurality of through-electrodes in and through the base substrate wafer by utilizing a paste containing a plurality of metal fine particles;
a routing electrode forming step of forming a plurality of routing electrodes connected electrically with the through-electrodes, on the upper face of the base substrate wafer;
a mounting step of bonding the plural piezoelectric vibration members to the upper face of the base substrate wafer via the routing electrodes;
an overlaying step of overlaying the base substrate wafer and the lid substrate wafer thereby to house the piezoelectric vibration members in the cavities surrounded by the recesses and the two wafers;
a bonding step of bonding the base substrate wafer and the lid substrate wafer thereby to seal up the piezoelectric vibration members in the cavities;
an external electrode forming step of forming a plurality of external electrodes connected electrically with the through-electrodes, on the lower face of the base substrate wafer; and
a cutting step of cutting the two bonded wafers thereby to shred them into the plural piezoelectric vibrators;
wherein the through-electrode forming step includes a hole forming step of forming a plurality of holes in the upper face of the base substrate wafer; a filling step of implanting the paste in these plural holes to block up the holes, and a firing step of firing the implanted paste at a predetermined temperature to harden the paste; an upper face polishing step of polishing, after the firing, the upper face of the base substrate wafer by a predetermined thickness; and a lower face polishing step of polishing, after the firing, the lower face of the base substrate wafer until the holes run through the wafer and the hardened paste is at least exposed out.

5. The method for manufacturing piezoelectric vibrators as claimed in claim 4,
wherein in the filling step, the paste is defoamed and then implanted in the hole.

6. A method for manufacturing a plurality of piezoelectric vibrators in which a piezoelectric vibration member is sealed up in a cavity formed between a base substrate and a lid substrate bonded to each other, all at once by utilizing a base substrate wafer and a lid substrate wafer, the method comprising:
a recess forming step of forming, in the lid substrate wafer, a plurality of cavity recesses for forming cavities when the two wafers are overlaid;
a through-electrode forming step of forming a plurality of through-electrodes in and through the base substrate wafer by utilizing a paste containing a plurality of metal fine particles;
a routing electrode forming step of forming a plurality of routing electrodes connected electrically with the through-electrodes, on the upper face of the base substrate wafer;
a mounting step of bonding the plural piezoelectric vibration members to the upper face of the base substrate wafer via the routing electrodes;
an overlaying step of overlaying the base substrate wafer and the lid substrate wafer thereby to house the piezoelectric vibration members in the cavities surrounded by the recesses and the two wafers;
a bonding step of bonding the base substrate wafer and the lid substrate wafer thereby to seal up the piezoelectric vibration members in the cavities;
an external electrode forming step of forming a plurality of external electrodes connected electrically with the through-electrodes, on the lower face of the base substrate wafer; and
a cutting step of cutting the two bonded wafers thereby to shred them into the plural piezoelectric vibrators;
wherein the through-electrode forming step includes a through-hole forming step of forming a plurality of through-holes in and through the base substrate water; a filling step of implanting the paste in the plural through-holes to block up the through-holes; a firing step of firing the implanted paste at a predetermined temperature to harden it; and a polishing step of polishing, after the firing, the two faces of the base substrate wafer each by a predetermined thickness.

7. The method for manufacturing piezoelectric vibrators as claimed in claim 6,
wherein in the filling step, the paste is defoamed and then implanted in the through-hole.

8. The method for manufacturing piezoelectric vibrators as claimed in claim 1;
which includes, prior to the mounting step, a bonding film forming step of forming, on the upper face of the base substrate wafer, a bonding film to surround the periphery of the recesses when the base substrate wafer and the lid substrate wafer are overlaid;
and wherein the two wafers are anodically bonded via the bonding film in the bonding step.

9. The method for manufacturing piezoelectric vibrators as claimed in claim 1;
wherein the piezoelectric vibration members are bump-bonded with an electroconductive bump in the mounting step.

10. The method for manufacturing piezoelectric vibrators as claimed in claim 1;
wherein a paste containing non-spherical metal fine particles is implanted in the filling step.

11. The method for manufacturing piezoelectric vibrators as claimed in claim 1;
wherein a paste mixed with a granular material of which the thermal expansion coefficient is substantially equal to that of the base substrate wafer is implanted in the filling step.

12. A piezoelectric vibrator comprising:
a base substrate of which the two faces are polished;
a lid substrate in which cavity recesses are formed and which is bonded to the base substrate in such a state that the recesses face the base substrate;
a piezoelectric vibration member bonded to the upper face of the base substrate in such a state that it is housed in the cavity formed of the recess between the base substrate and the lid substrate;
an external electrode formed on the lower face of the base substrate;
a through-electrode formed in and through the base substrate and electrically connected with the external electrode with keeping the airtightness inside the cavity; and
a routing electrode formed on the upper face of the base substrate to electrically connect the through-electrode to the bonded piezoelectric vibration member;
wherein the through-electrode is formed by hardening of a paste containing a plurality of metal fine particles.

13. The piezoelectric vibrator as claimed in claim 12;
wherein the base substrate and the lid substrate are anodically bonded via a bonding film formed between the two substrates to surround the periphery of the recesses.

14. The piezoelectric vibrator as claimed in claim 12;
wherein the piezoelectric vibration member is bump-bonded with an electroconductive bump.

15. The piezoelectric vibrator as claimed in claim 12;
wherein the metal fine particles are non-spherical.

16. The piezoelectric vibrator as claimed in claim 12;
wherein the paste is mixed with a granular material of which the thermal expansion coefficient is substantially equal to that of the base substrate.

17. An oscillator comprising, as the oscillation member therein, the piezoelectric vibrator of claim 12 as electrically connected to the integrated circuit therein.

18. An electronic device comprising the piezoelectric vibrator of claim 12 as electrically connected to the timer part therein.

19. A radio-controlled watch comprising the piezoelectric vibrator of claim 12 as electrically connected to the filter part therein.
